(19) United States
(12) Patent Application Publication
(10) Pub. No.: US 2026/0293583 A1
(43) Pub. Date: Sep. 24, 2026

(54) MULTIPLE-CHAMBER SEMICONDUCTOR SERIAL CONSTRUCTING APPARATUS

(71) Applicant: ADVANCED ION BEAM TECHNOLOGY, INC., HsinChu City (TW)

(72) Inventors: Chen-Hsien Ku, HsinChu City (TW); Sheng-Bo Hsu, HsinChu City (TW); Chung-Chih Chen, HsinChu City (TW); Chao-Che Tsai, HsinChu City (TW); Chyi-Shyuan Chern, HsinChu City (TW)

(73) Assignee: ADVANCED ION BEAM TECHNOLOGY, INC., HsinChu City (TW)

(21) Appl. No.: 19/558,045

(22) Filed: Mar. 5, 2026

Related U.S. Application Data
(60) Provisional application No. 63/771,676, filed on Mar. 14, 2025.

(30) Foreign Application Priority Data
Feb. 24, 2026 (TW) 115106675

(51) Int. Cl. H10P 72/00; H10P 30/20; H10P 72/10; H10P 72/30

(52) U.S. Cl. CPC H10P 72/0461; H10P 72/0456; H10P 72/0471; H10P 72/10; H10P 72/3202; H10P 72/3214; H10P 30/20

(57) ABSTRACT

A multiple-chamber semiconductor serial constructing apparatus includes a first vacuum-transfer module (VTM1), a first to a third load-lock module (LLM1-LLM3), and a first to a third process-transfer module (PTM1-PTM3). The VTM1 has a first and a second side opposite to each other, a third side adjacent to the first side and a fourth side, and the fourth side adjacent to the second and the third side. The LLM1 includes two first load-lock chambers coupled with the first side. The LLM2 includes two second load-lock chambers coupled with the second side. The PTM1 includes a second vacuum-transfer chamber coupled with the second load-lock chambers, and a first process-transfer chamber diagonally coupled with the second vacuum-transfer chamber and coupled with an ion implantation assembly. The LLM3 includes a third load-lock chamber coupled with the fourth side, and a connecting chamber coupled with the third load-lock chamber. The PTM2 is coupled with the third load-lock chamber. The PTM3 is coupled with the third load-lock chamber and the third side.

### BACKGROUND

### Technical Field

The instant disclosure relates to a multiple-chamber semiconductor serial constructing apparatus.

### Related Art

In traditional multiple-chamber semiconductor manufacturing equipment, ion implanters are used to ionize a specific number of dopants to generate ion beamlines in the ion implanters. These ion beamlines are directed to the surface of a semiconductor component or a wafer to implant ions into the semiconductor component or the wafer.

However, conventional ion implantation systems are typically provided with only a single ion implanter that generates ion beamlines. Therefore, at one given time, the conventional system can only perform one set of ion implantation manufacturing processes but cannot adjust the system according to the process requirements of ion implantation, nor can it perform multiple sets of ion implantation manufacturing processes simultaneously and independently.

In addition, conventional chemical vapor deposition (CVD) equipment typically only has a single plasma treatment chamber and corresponding plasma treatment equipment. Therefore, if there is a CVD process requirement after (or before) executing the ion implantation process, the wafer should be moved from the conventional ion implantation system to the CVD machine (or from the conventional CVD machine to the conventional ion implantation system) in order to subsequently perform the two processes (i.e., the ion implantation process and the CVD process). However, the transfer of wafers between the ion implantation system and CVD machine involves so-called vacuum breaking (i.e., restoring the system pressure from high vacuum or ultra-high vacuum to atmospheric pressure) and vacuum pumping (i.e., reducing the system pressure from atmospheric pressure to high vacuum or ultra-high vacuum), both of which consume considerable processing time; and if the system volume is relatively larger, the required processing time will be significantly extended as a result. Therefore, how to combine multiple processes while still avoiding a significant extension in processing time is one of the technical problems to be solved in the art.

Moreover, exposing wafers to ambient pressure (e.g., the atmosphere) increases the risk of surface contaminants being introduced into the wafer, which can adversely affect the wafers (e.g., the structure, purity, and uniformity of the wafers). Therefore, how to combine multiple processes while still avoiding introducing surface contaminants into the wafer and causing adverse effects on the wafer is also one of the technical problems to be solved in the art.

### SUMMARY

In view of this, according to some embodiments, a multiple-chamber semiconductor serial constructing apparatus is provided according to some embodiments, which comprises a first vacuum-transfer module (VTM1), a first load-lock module (LLM1), a second load-lock module (LLM2), a first process-transfer module (PTM1), a third load-lock module (LLM3), a second process-transfer module (PTM2), and a third process-transfer module (PTM3). The first vacuum-transfer module (VTM1) has a first side, a second side, a third side, and a fourth side, wherein the first side and the second side are opposite to each other, the third side is adjacent to the first side and the fourth side, and the fourth side is adjacent to the second side and the third side. The first load-lock module (LLM1) comprises two first load-lock chambers adjacent to each other and coupled with the first side of the first vacuum-transfer module (VTM1). The second load-lock module (LLM2) comprises two second load-lock chambers adjacent to each other and coupled with the second side of the first vacuum-transfer module (VTM1). The first process-transfer module (PTM1) comprises a second vacuum-transfer chamber and a first process-transfer chamber. The second vacuum-transfer chamber is coupled with the two second load-lock chambers. The first process-transfer chamber is diagonally coupled with the second vacuum-transfer chamber, and the first process-transfer chamber is configured to be coupled with an ion implantation assembly. The third load-lock module (LLM3) comprises a third load-lock chamber and a third vacuum-transfer chamber. The third load-lock chamber is coupled with the fourth side of the first vacuum-transfer module (VTM1). The third vacuum-transfer chamber is coupled with the third load-lock chamber. The second process-transfer module (PTM2) is coupled with the third vacuum-transfer chamber. The third process-transfer module (PTM3) is coupled with the third vacuum-transfer chamber and the third side of the first vacuum-transfer module (VTM1).

In some embodiments, the first process-transfer module (PTM1) further comprises a heating chamber coupled with the second vacuum-transfer chamber; and the second process-transfer module (PTM2) comprises two second process-transfer chambers, and the two second process-transfer chambers are respectively coupled with two opposite sides of the third vacuum-transfer chamber.

In some embodiments, the multiple-chamber semiconductor serial constructing apparatus further comprises an ion implantation assembly coupled with the first process-transfer chamber.

### BRIEF DESCRIPTION OF THE DRAWINGS

FIG. 1A to FIG. 1D illustrate schematic views of a multiple-chamber semiconductor serial constructing apparatus according to a first embodiment.

FIG. 2 illustrates a schematic view of a multiple-chamber semiconductor serial constructing apparatus according to a second embodiment.

FIG. 3 to FIG. 39 illustrate schematic views of a multiple-chamber semiconductor serial constructing apparatus as shown in FIG. 1A in transfer states according to some embodiments. FIG. 40A to FIG. 40D illustrate schematic views of a multiple-chamber semiconductor serial constructing apparatus according to a third embodiment.

FIG. 41 to FIG. 145 illustrate schematic views of a multiple-chamber semiconductor serial constructing apparatus as shown in FIG. 40A in transfer states according to some embodiments.

### DETAILED DESCRIPTION

The detailed features and advantages of the present invention will be described in detail in the following embodiments. The content is sufficient to enable any person of ordinary skill in the art to understand the technical aspects of the instant disclosure and to implement the same. Based on the specification, claims, and drawings of the instant disclosure, any person of ordinary skill in the art can readily understand the objectives and advantages of the instant disclosure.

The term “coupled” as used herein may be employed to describe a functional or structural relationship between components. In certain embodiments, “coupled” may refer to two or more components being in direct or indirect (i.e., with one or more intervening components therebetween) physical or electrical contact, and/or two or more components operating in cooperation with or interacting with each other.

The term “robotic arm” as used herein may be employed to describe a robotic arm having an end effector (also referred to as a terminal effector, end tool, or robot fork) disposed at its distal end according to process requirements. The number of end effectors may be adjusted to one or more depending on process requirements; for example, a single robotic arm may have a single end effector, or alternatively, a single robotic arm may have a plurality of end effectors (e.g., five end effectors).

The term “pick” in “pick and place,” or the term “pick” per se, as used herein, may be used to describe temporarily securing a component (e.g., a component to be transferred) to another component (e.g., an end effector of a robotic arm) by any physical means, such that the component can be detached from the other component when needed. Such physical means comprise, but are not limited to, clamping, holding (supporting), suction, or adhesion.

The term “place” in “pick and place,” or the term “place” per se, as used herein, may be used to describe temporarily separating a component (e.g., a component to be transferred) from another component (e.g., an end effector of a robotic arm) by any physical means, and the component does not suffer significant damage after being released.

The terms “a range from . . . to . . . ” and “within a range from . . . to . . . ” as used herein refer to a range that includes the upper limit value, the lower limit value, and any value between the upper limit value and the lower limit value. For example, the term “within a range from 1×10⁻⁶ torr to 760 torr” refers to any value greater than or equal to 1×10⁻⁶ torr (i.e., ≥1×10⁻⁶ torr) and less than or equal to 760 torr (i.e., ≤760 torr).

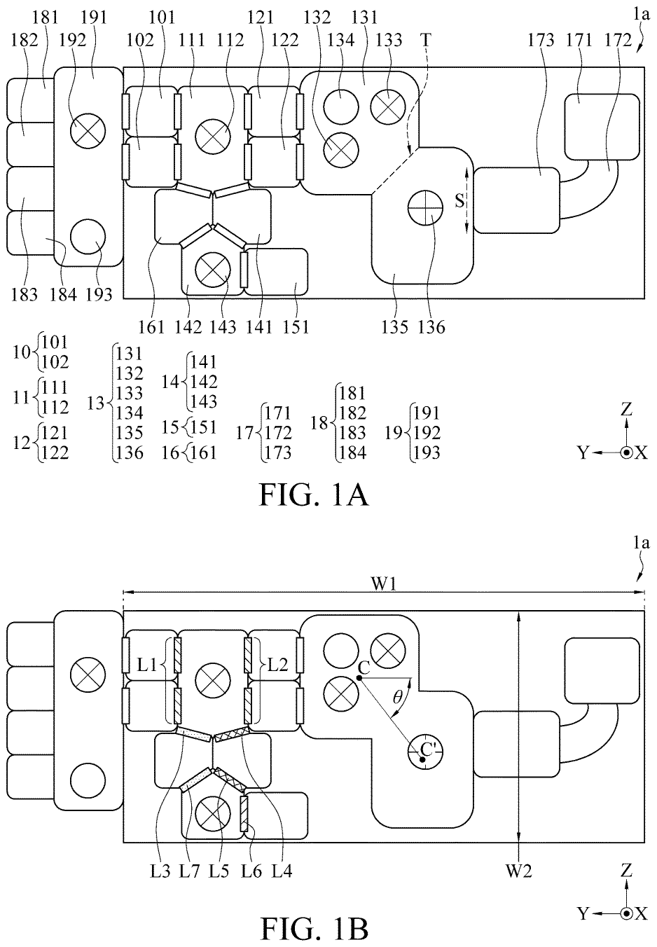

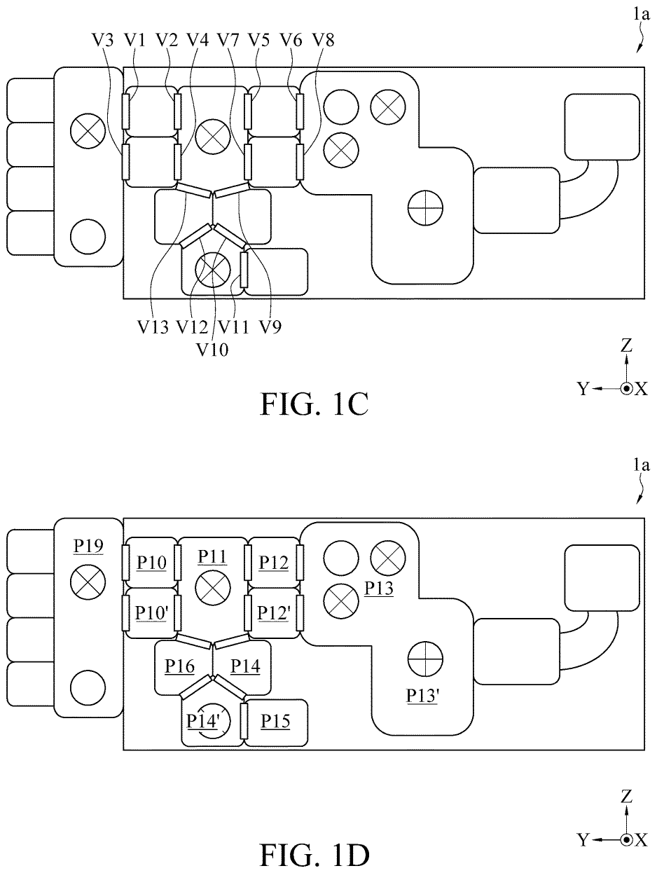

Please refer to FIG. 1A and FIG. 1B. FIG. 1A and FIG. 1B illustrate schematic views of a multiple-chamber semiconductor serial constructing apparatus 1a according to a first embodiment. In FIG. 1A and FIG. 1B, a multiple-chamber semiconductor serial constructing apparatus 1a comprises a first vacuum-transfer module (VTM1) 11, a first load-lock module (LLM1) 10, a second load-lock module (LLM2) 12, a first process-transfer module (PTM1) 13, a third load-lock module (LLM3) 14, a second process-transfer module (PTM2) 15, and a third process-transfer module (PTM3) 16.

The first vacuum-transfer module 11 may comprise a first vacuum-transfer chamber 111, and the first vacuum-transfer module 11 (or its first vacuum-transfer chamber 111) has, as shown in FIG. 1B, a first side L1, a second side L2, a third side L3, and a fourth side L4, wherein the first side L1 and the second side L2 are opposite to each other, the third side L3 is adjacent to the first side L1 and the fourth side L4, and the fourth side L4 is adjacent to the second side L2 and the third side L3. An angle (not additionally denoted) can be formed at the connection of the third side L3 and the fourth side LA, and the angle may be less than or equal to 180 degrees; in case that the angle is equal to 180 degrees, the four sides L1-L4 may form a first vacuum-transfer chamber 111 having at least three sides (e.g., a triangle shape or a quadrilateral shape); in case that the angle is greater than 180 degrees, the four sides L1-L4 may form a first vacuum-transfer chamber 111 having at least four sides (e.g., a quadrilateral shape or a pentagonal shape). The first load-lock module 10 comprises two first load-lock chambers 101, 102 adjacent to each other and coupled with the first side L1 of the first vacuum-transfer module 11. The second load-lock module 12 comprises two second load-lock chambers 121, 122 adjacent to each other and coupled with the second side L2 of the first vacuum-transfer module 11. The first process-transfer module 13 comprises a second vacuum-transfer chamber 131 and a first process-transfer chamber 135. The second vacuum-transfer chamber 131 is coupled with the two second load-lock chambers 121, 122. The first process-transfer chamber 135 is diagonally coupled with the second vacuum-transfer chamber 131, and the first process-transfer chamber 135 is configured to be coupled with an ion implantation assembly 17. The third load-lock module 14 comprises a third load-lock chamber 141 and a third vacuum-transfer chamber 142. The third load-lock chamber 141 is coupled with the fourth side L4 of the first vacuum-transfer module 11. The third vacuum-transfer chamber 142 is coupled with the third load-lock chamber 141. The second process-transfer module 15 may comprise is a second process-transfer chamber 151, and the second process-transfer module 15 (or its second process-transfer chamber 151) is coupled with the third vacuum-transfer chamber 142. The third process-transfer module 16 may comprise a third process-transfer chamber 161, and the third process-transfer module 16 (or its third process-transfer chamber 161) is coupled with the third vacuum-transfer chamber 142 and the third side L3 of the first vacuum-transfer module 11. The first process-transfer module 13 (or its first process-transfer chamber 135) may perform the process comprising the ion implantation process through being coupled with an ion implantation assembly 17, for example; meanwhile, the second process-transfer module 15 (or the second process-transfer chamber 151) and the third process-transfer module 16 (or the third process-transfer chamber 161) may respectively and selectively comprise any one or more of the following processes: a plasma processing, an etching processes, and other post-treatment processes (which will be described in detail later).

Therefore, in some embodiments, the component to be transferred (e.g., the component(s) to be transferred 2 as shown in FIG. 3, such as wafers 21-23; which will be described in detail later) can be rapidly processed in the same multiple-chamber semiconductor serial constructing apparatus 1a for more than two processes (e.g., an ion implantation process and a plasma treatment process; or e.g., an ion implantation process, a plasma treatment process, and a post-treatment process) without being moved to the exterior of the conventional ion implantation system (or e.g., a conventional CVD machine) to perform subsequent steps (e.g., a CVD process (or e.g., an ion implantation process)). Hence, in some embodiments, the component(s) to be transferred 2 can avoid being contaminated by surface contaminants due to the transfer among multiple systems or devices, thereby reducing the adverse effects on the component(s) to be transferred 2 (e.g., the structure, purity and uniformity of wafers 21-23), and thus improving the process efficiency and yield of the component(s) to be transferred 2.

In addition, in some embodiments, since the volumes of the first load-lock chambers 101, 102, the second load-lock chambers 121, 122, the third load-lock chamber 141, and/or the third vacuum-transfer chamber 142 can be minimized as much as possible, the time required for the pressurization and/or depressurization (e.g., vacuum breaking and/or vacuum pumping) corresponding to different processes of the first load-lock chambers 101, 102, the second load-lock chambers 121, 122, the third load-lock chamber 141, and/or the third vacuum-transfer chamber 142 can be significantly reduced, thereby reducing the overall process time, improving the process efficiency, and reducing the process costs.

Moreover, in some embodiments, since the volume of the second load-lock chambers 121, 122 can be minimized as much as possible, the second load-lock chambers 121, 122 can be maintained at certain pressure more uniformly, thereby avoiding a significant pressure difference due to the position of the component(s) to be transferred 2 (as shown in FIG. 3, e.g., wafers 21-23) in the second load-lock chambers 121, 122 and the components coupled with the second load-lock chambers 121, 122, and thus reducing the adverse effects on the component(s) to be transferred 2.

In some embodiments, the second load-lock chambers 121, 122 are also configured to cool the component(s) to be transferred 2 (as shown in FIG. 3, e.g., wafers 21-23). Therefore, in addition to serving as a relay between the two chambers, the second load-lock chambers 121, 122 can also achieve the effect of cooling the component(s) to be transferred 2 while waiting for the processes to be performed, thereby reducing the time and cost required for the entire process.

In some embodiments, the second load-lock chamber 121, 122 further comprises a monitoring equipment, which is arranged according to the movement trajectory of the component(s) to be transferred 2 accommodated in the second load-lock chamber 121, 122, so as to acquire the alignment status of the component(s) to be transferred 2 in real time, thereby rapidly eliminating the misalignment of the component(s) to be transferred 2 by manual or machine means. The monitoring equipment may be, for example, various image-capturing components and image processors. Therefore, in some embodiments, the ion implantation process or other processes of the component(s) to be transferred 2 can be performed more precisely, thereby improving the process efficiency and yield of the component(s) to be transferred 2.

The following are illustrative examples of specific embodiments of the first load-lock module (LLM1) 10, but the instant disclosure is not limited to these embodiments.

The first load-lock module 10 may accommodate one or more components to be transferred 2 (as shown in FIG. 3, e.g., wafers 21-23); for example, the first load-lock module 10 has a plurality of first load-lock chambers 101, 102 to respectively provide a space for accommodating the component(s) to be transferred 2. The component(s) to be transferred 2 may be a semi-finished product that has not undergone any of the expected processes, a semi-finished product that has only undergone part of the expected processes, or a finished product that has undergone all of the expected processes, which is not particularly limited herein. Therefore, regardless of whether each of the components has undergone all the expected processes or not, for ease of understanding and explanation, the component is referred to as “component to be transferred” herein, without any intention to distinguish or limit the component. Furthermore, each wafer 21-23 may refer to a single wafer or multiple wafers (e.g., five wafers as a unit of a wafer set), which is not particularly limited.

Please refer to FIG. 1A and FIG. 1C. FIG. 1C illustrates a schematic view of a multiple-chamber semiconductor serial constructing apparatus 1a according to a first embodiment. In FIG. 1A, the first load-lock module 10 (or its first load-lock chambers 101, 102) may be selectively in communication with or not in communication with the first vacuum-transfer module 11 (or its first vacuum-transfer chamber 111) through one or more valves V2, V4 (as shown in FIG. 1C). Hence, the first load-lock module 10 may be selectively in communication with the atmosphere of the first vacuum-transfer module 11 in case that the communication is needed, and not in communication with the atmosphere of the first vacuum-transfer module 11 in case that the communication is not needed.

In some embodiments, the first load-lock module 10 (or its first load-lock chambers 101, 102) is further coupled with other components, such as an equipment front end module (EFEM, or referred to as wafer transfer equipment) 19 and/or a front opening unified pod (FOUP) 18 (which will be described in detail later) as shown in FIG. 1A. The equipment front end module 19 may be a device or equipment for receiving the component(s) to be transferred 2 (as shown in FIG. 3; e.g., the semiconductor substrate or the wafers 21-23) from the exterior of the system, and for transferring the component(s) to be transferred 2 to or from the first load-lock module 10 (which will be described in detail later). The front opening unified pod 18 may be a device or apparatus for receiving one or more semiconductor substrates or wafers (e.g., the wafers 21-23 as shown in FIG. 3), for example, accommodating 5, 10, 25 or more wafers (which will be described in detail later).

The first load-lock module 10 (or its first load-lock chambers 101, 102) may be selectively in communication with or not in communication with the equipment front end module 19 and/or the front opening unified pod 18 through one or more valves V1, V3 (as shown in FIG. 1C). Therefore, in some embodiments, as shown in FIG. 1D, even though the pressure P19 of the device front-end module 19 may be set to be apparently different from the pressure P11 of the first vacuum-transfer module 11 (or its first vacuum-transfer chamber 111), only the pressure of the first load-lock module 10 with a relatively smaller volume (e.g., the pressures P10, P10′ of the first load-lock chambers 101, 102) needs to be adjusted, which avoids the conventional process time and cost of adjusting the pressure P11 of the first vacuum-transfer module 11 with a relatively larger volume to be the same as the pressure P19 of the equipment front end module 19 with also a relatively larger volume.

For example, in FIG. 1A and FIG. 1D, in accordance with different process requirements, the pressure P19 of the equipment front end module 19 may be maintained at a first pressure (e.g., 760 torr) or within the tolerable range thereof (e.g., within ±5% of the first pressure). The pressure P11 of the first vacuum-transfer module 11 may be maintained at a second pressure; for example, the second pressure may be any pressure less than or equal to 1×10⁻² torr, or any pressure within a range from 5×10⁻⁴ torr to 1×10⁻² torr or within the tolerable range thereof (e.g., within ±5% of the second pressure). The pressures P10, P10′ of the first load-lock chambers 101, 102 may be independently maintained between the first pressure and the second pressure (e.g., within a range from 5×10⁻⁴ torr to 760 torr). For example, the first load-lock chambers 101, 102 may be in communication with the equipment front end module 19 respectively through the control of valves V1, V3 (as shown in FIG. 1C), and thus in case that the valves V2, V4 (as shown in FIG. 1C) are closed (i.e., the first load-lock chambers 101, 102 and the first vacuum-transfer chamber 111 are not in communication with each other at this moment), the pressures P10, P10′ of the first load-lock chambers 101, 102 may be thus equal to the pressure P19 of the equipment front end module 19 (or its equipment front end chamber 191), for example, all are 760 torr. For another example, the first load-lock chambers 101, 102 may be in communication with the first vacuum-transfer module 11 respectively through the control of valves V2, V4, and thus in case that the valves V1, V3 are closed (i.e., the first load-lock chambers 101, 102 and the equipment front end module 19 are not in communication with each other at this moment), the pressures P10, P10′ of the first load-lock chambers 101, 102 may be thus equal to the pressure P11 of the first vacuum-transfer module 11 (or its first vacuum-transfer chamber 111), for example, all are less than or equal to 760 torr. In other words, in some embodiments, the pressures P10, P10′ of the first load-lock chambers 101, 102 may independently be any pressure within a range from 5×10⁻⁴ torr to 1×10⁻² torr, or within a range from 5×10⁻⁴ torr to 760 torr; the pressure P11 of the first vacuum-transfer module 11 (or its first vacuum-transfer chamber 111) may be any pressure within a range from 5×10⁻⁴ torr to 1×10⁻² torr. Therefore, in some embodiments, even though the pressure P19 of the device front-end module 19 is set to be apparently different from a pressure P11 of the first vacuum-transfer module 11, only the pressures P10, P10′ of the first load-lock chambers 101, 102 with volumes that can be reduced as much as possible need to be subsequently adjusted to be the same as the pressure P11 and the pressure P19, which reduces the time previously required for the two chambers with apparently greater volumes (e.g., the equipment front end chamber 191 and the first vacuum-transfer chamber 111 as shown in FIG. 1A) to reach pressure balance, thereby reducing the process time and cost.

The following examples illustrate specific embodiments of the first vacuum-transfer module (VTM1) 11, but the instant disclosure is not particularly limited to these embodiments.

In some embodiments, the first vacuum-transfer module 11 has a first vacuum-transfer chamber 111 configured as a polygonal chamber, such as the pentagonal chamber as shown in FIG. 1A. In FIG. 1B, the pentagonal chamber may be a chamber enclosed by, in sequence, the first side L1, the third side L3, the fourth side L4, the second side L2, and another side (not additionally denoted) that are adjacent to each other with the another side adjacent to the first side L1. At least four sides of the pentagonal chamber may be used to couple with the first vacuum-transfer chamber 111 and the chambers of other modules. For example, as shown in FIG. 1A to FIG. 1C, the first vacuum-transfer chamber 111 and the first load-lock module 10 (or its first load-lock chambers 101, 102) are selectively in communication with or not in communication with each other through the first side L1 and the valves V2, V4; the first vacuum-transfer chamber 111 and the second load-lock module 12 (or its second load-lock chambers 121, 122) are selectively in communication with or not in communication with each other through the second side L2 and the valves V5, V7; the first vacuum-transfer chamber 111 and the third process-transfer module 16 (or its third process-transfer chamber 161) are selectively in communication with or not in communication with each other through the third side L3 and the valve V13; and the first vacuum-transfer chamber 111 and the third load-lock module 14 (or its third load-lock chamber 141) are selectively in communication with or not in communication with each other through the fourth side LA and the valve V9.

For example, in FIG. FIG. 1D, in accordance with different process requirements, the pressure P11 of the first vacuum-transfer chamber 111 may be maintained at a certain pressure or within the tolerable range thereof (e.g., within ±5% of the certain pressure); for example, the pressure P11 may be any pressure within a range from 5×10⁻⁴ torr to 1×10⁻² torr.

In some embodiments, the first vacuum-transfer module 11 further comprises a first vacuum-transfer robot 112 disposed in the first vacuum-transfer chamber 111 and configured to transfer one or more components to be transferred 2 (as shown in FIG. 3, such as the wafers 21-23) among the first vacuum-transfer chamber 111 and other chambers coupled with the first vacuum-transfer chamber 111. For example, as shown in FIG. 1A, the first vacuum-transfer robot 112 may be configured to transfer the component(s) to be transferred 2 from the first load-lock chambers 101, 102 to the interior of the first vacuum-transfer chamber 111 (or from the first vacuum-transfer chamber 111 to the interior of the first load-lock chambers 101, 102), from the first vacuum-transfer chamber 111 to the interior of the second load-lock chambers 121, 122 (or from the second load-lock chambers 121, 122 to the interior of the first vacuum-transfer chamber 111), from the first vacuum-transfer chamber 111 to the interior of the third load-lock chamber 141 (or from the third load-lock chamber 141 to the interior of the first vacuum-transfer chamber 111), or from the third process-transfer chamber 161 to the interior of the first vacuum-transfer chamber 111 (or from the first vacuum-transfer chamber 111 to the interior of the third process-transfer chamber 161).

In some embodiments, the first vacuum-transfer robot 112 has one or more robotic arms, each of the robotic arms may comprise one or more end effectors (not additionally denoted), and each of the end effectors is configured to pick and place as well as hold wafers (e.g., the wafers 21-23 as shown in FIG. 3). For example, the first vacuum-transfer robot 112 has one robotic arm, the robotic arm comprises five end effectors, and each of the end effectors may be configured to pick and place as well as hold wafers 21-23.

The following examples illustrate specific embodiments of the second load-lock module (LLM2) 12, but the instant disclosure is not particularly limited to these embodiments.

The second load-lock module 12 may accommodate one or more components to be transferred 2 (as shown in FIG. 3, e.g., the wafers 21-23); for example, the second load-lock module 12 has second load-lock chambers 121, 122 to respectively provide a space for accommodating the component(s) to be transferred 2. In FIG. 1A, the second load-lock module 12 (or its second load-lock chambers 121, 122) may be selectively in communication with or not in communication with the first vacuum-transfer module 11 (or its first vacuum-transfer chamber 111) through one of more valves V5, V7 (as shown in FIG. 1C), and the second load-lock module 12 (or its second load-lock chambers 121, 122) may be selectively in communication with or not in communication with the first process-transfer module 13 (or its second vacuum-transfer chamber 131) through one of more valves V6, V8 (as shown in FIG. 1C). Hence, the second load-lock module 12 may be selectively in communication with the atmosphere of the first vacuum-transfer module 11 and/or the first process-transfer module 13 in case that the communication is needed, and not in communication with the atmosphere of the first vacuum-transfer module 11 and/or the first process-transfer module 13 in case that the communication is not needed.

In some embodiments, as shown in FIG. 1A and FIG. 1D, in accordance with different process requirements, the pressures P12, P12′ of the second load-lock chambers 121, 122 may be maintained at a certain pressure or within the tolerable range thereof (e.g., within ±5% of the certain pressure), for example, both are maintained at any pressure within a range from 1×10⁻⁷ torr to 1×10⁻² torr.

In some embodiments, as shown in FIG. 1A and FIG. 1D, the pressure P11 of the first vacuum-transfer module 11 (or its first vacuum-transfer chamber 111) may be arranged to be the same as the pressures P13, P13′ of the first process-transfer module 13 (or its second vacuum-transfer chamber 131 and first process-transfer chamber 135), and the pressures P12, P12′ of the second load-lock module 12 (or its second load-lock chambers 121, 122) may be arranged to be the same as the pressure P11 and the pressures P13, P13′.

For example, in FIG. 1D, the pressure P11 of the first vacuum-transfer module 11 (or its first vacuum-transfer chamber 111), the pressures P12, P12′ of the second load-lock module 12 (or its second load-lock chambers 121, 122), and the pressures P13, P13′ of the first process-transfer module 13 (or its second vacuum-transfer chamber 131 and first process-transfer chamber 135) may be maintained close to each other or within the tolerable range thereof (e.g., its pressure difference is maintained within ±5%) in accordance with different process requirements; for example, the pressure P11 of the first vacuum-transfer module 11 is maintained at any pressure within a range from 5×10⁻⁴ torr to 1×10⁻² torr. Therefore, in some embodiments, even though one or more components to be transferred 2 (as shown in FIG. 3; e.g., wafers 21-23) are temporarily placed in the second load-lock module 12 due to the needs of the process, the pressures P12, P12′ of the second load-lock module 12 are substantially similar to the pressure P11 and the pressures P13, P13′ of those chambers that are coupled with the second load-lock module 12, the component(s) to be transferred 2 may be immediately transferred to the chambers coupled with the second load-lock module 12 in accordance with different process requirements (e.g., the first vacuum-transfer chamber 111 or the second vacuum-transfer chamber 131), which avoids the time and cost of the existing process that requires to firstly remove the component(s) to be transferred 2 from the system and then move it back into the system, and also avoids contamination of the component(s) to be transferred 2.

The following examples illustrate specific embodiments of the first process-transfer module (PTM1) 13, but the instant disclosure is not particularly limited to these embodiments.

In some embodiments, the first process-transfer module 13 has a second vacuum-transfer chamber 131 and a first process-transfer chamber 135, and the second vacuum-transfer chamber 131 and the first process-transfer chamber 135 are diagonally coupled with each other and in communication with each other (i.e., the pressure P13 (as shown in FIG. 1D) is usually maintained the same as the pressure P13′ (as shown in FIG. 1D)). The term “diagonally coupled” as used herein refers to that one component is coupled with another component at the diagonal corner of the one component and the diagonal corner of the another component. For example, as referring to FIG. 1A, the second vacuum-transfer chamber 131 is coupled with the first process-transfer chamber 135 at the diagonal corner of the second vacuum-transfer chamber 131 and the diagonal corner of the first process-transfer chamber 135 through an interface T. Therefore, in FIG. 1B, a straight line C-C′ may be formed by connecting the geometric center C of the second vacuum-transfer chamber 131 and the geometric center C′ of the first process-transfer chamber 135, and an angle θ is formed between the vertical and horizontal components of the straight line C-C′ and less than 90°, for example, any angle within a range from 30° to 60°, or any angle within a range from 30° to 75°. The “horizontal” referred to in the above-mentioned horizontal component may be an extension direction along the first vacuum-transfer chamber 111 coupled with the second load-lock chambers 121, 122, and then coupled with the second vacuum-transfer chamber 131 (e.g., a direction parallel to the axis Y of FIG. 1A); and the “vertical” referred to in the above-mentioned vertical component may be a direction perpendicular to the extension direction (e.g., a direction parallel to the axis Z of FIG. 1A). Therefore, in some embodiments, even though the multiple-chamber semiconductor serial constructing apparatus 1a has a second vacuum-transfer chamber 131 and a first process-transfer chamber 135 coupled with each other, the length W1 (as shown in FIG. 1B) and the width W2 (as shown in FIG. 1B) of the multiple-chamber semiconductor serial constructing apparatus 1a can be prevented from increasing (or may be further decreased) as much as possible. Therefore, in some embodiments, the multiple-chamber semiconductor serial constructing apparatus 1a may be assembled and installed without specification limitations; for example, the multiple-chamber semiconductor serial constructing apparatus 1a may be assembled and installed with other equipment with minimal adjustments to the specifications of other equipment, thereby making the applications and fields of the multiple-chamber semiconductor serial constructing apparatus 1a more diversified.

In some embodiments, the interface T may be an upright wall with apertures (not additionally illustrated) to partially separate the second vacuum-transfer chamber 131 from the first process-transfer chamber 135. Each aperture may have a long axis that is parallel to the ground so that the wafers 21-23 (as shown in FIG. 3) can be transferred through the aperture between the second vacuum-transfer chamber 131 and the first process-transfer chamber 135. For example, the extension direction of the long axis of the aperture is, for example, perpendicular to the extension direction of the straight line C-C′ (as shown in FIG. 1B), the size of the long axis of the aperture may be slightly greater than the outer diameter of the wafers 21-23, and the size of the short axis of the aperture may be slightly greater than the thickness of the wafers 21-23, so that the wafers 21-23 can be transferred between the second vacuum-transfer chamber 131 and the first process-transfer chamber 135 along, for example, the extension direction parallel to the straight line C-C′. The aperture may be normally open or selectively openable, or closed; for example, a valve that can be selectively opened or closed may be disposed corresponding to the location of the aperture.

In some embodiments, as shown in FIG. 1D, in accordance with different process requirements, the pressures P13, P13′ of the second vacuum-transfer chamber 131 and the first process-transfer chamber 135 may be maintained at a certain pressure or within the tolerable range thereof (e.g., within ±5% of the certain pressure), for example, both are maintained at any pressure within a range from 1×10⁻⁷ torr to 2×10⁻⁵ torr (e.g., 1×10⁻⁶ torr).

In some embodiments, the second vacuum-transfer chamber 131 may be configured to accommodate one or more components to be transferred 2 (as shown in FIG. 3; e.g., the wafers 21-23) to perform corresponding processes on the component(s) to be transferred 2 in accordance with different process requirements, such as transfer and alignment processes.

For example, in FIG. 1A, the first process-transfer module 13 may further comprise at least one second vacuum-transfer robot (e.g., 132); the second vacuum-transfer robot 132 may be disposed in the second vacuum-transfer chamber 131 and configured to transfer one or more components to be transferred 2 (as shown in FIG. 3; e.g., the wafers 21-23); and the second vacuum-transfer robot 132 may be disposed adjacent to the second load-lock chambers 121, 122 in the second vacuum-transfer chamber 131 to transfer the component(s) to be transferred 2 between the second load-lock chambers 121, 122 and the second vacuum-transfer chamber 131.

For another example, as shown in FIG. 1A, the first process-transfer module 13 may further comprise at least two second vacuum-transfer robots (e.g., 132, 133); the second vacuum-transfer robots 132, 133 may be disposed in the second vacuum-transfer chamber 131 and adjacent to each other, and each of the second vacuum-transfer robots 132, 133 is configured to transfer one or more components to be transferred 2 (as shown in FIG. 3; e.g., the wafers 21-23); the second vacuum-transfer robots 132, 133 may be disposed adjacent to the second load-lock chambers 121, 122 in the second vacuum-transfer chamber 131 to transfer the component(s) to be transferred 2 among the second load-lock chambers 121, 122 and the second vacuum-transfer chamber 131; and the second vacuum-transfer robot 133 may be disposed adjacent to the first process-transfer chamber 135 to transfer the component(s) to be transferred 2 between the second vacuum-transfer chamber 131 and the first process-transfer chamber 135.

Each of the second vacuum-transfer robots 132, 133 may have one robotic arm, the robotic arm may comprise one end effector (not additionally denoted), and the end effector is configured to pick and place as well as hold wafers (e.g., the wafers 21-23 as shown in FIG. 3).

In some embodiments, the first process-transfer module 13 further comprises a second vacuum-transfer aligner 134; the second vacuum-transfer aligner 134 may be disposed at any location in the second vacuum-transfer chamber 131, for example, adjacent to the second vacuum-transfer robots 132, 133, to reduce the time that the robotic arm and the end effector of the second vacuum-transfer robot 132 move among, for example, the second vacuum-transfer aligner 134 and the second load-lock chambers 121, 122 (and/or to reduce the time that the robotic arm and the end effector of the second vacuum-transfer robot 133 move between, for example, the second vacuum-transfer aligner 134 and the first process-transfer chamber 135), thereby reducing the transfer time of the component(s) to be transferred 2 (as shown in FIG. 3; e.g., the wafers 21-23), and even reducing the overall process time. The second vacuum-transfer aligner 134 is configured to hold one or more components to be transferred 2; for example, the second vacuum-transfer aligner 134 is a device having the function of being arranged to align the component(s) to be transferred 2. For example, the second vacuum-transfer aligner 134 is an alignment/machine vision system that comprises one or more image sensors and a controlled surface, the component(s) to be transferred 2 may be transferred to a desired location via the controlled surface, and the image sensor(s) may be any suitable imaging sensor/camera for different calibrations; for example, the edges of the substrate or the wafers 21-23 are inspected to confirm one or more predetermined characteristics of the substrate or the wafers 21-23 (e.g., wafer diameter, the location of the alignment reference (i.e., fiducial (FID)) (such as notch or flat, various marks or other features), the location of the wafer centerline, or other relevant information).

In some embodiments, the first process-transfer chamber 135 may be configured to accommodate one or more components to be transferred 2 (as shown in FIG. 3; e.g., the wafers 21-23) to perform corresponding processes on the component(s) to be transferred 2 in accordance with different process requirements, such as an ion implantation process. For example, the first process-transfer chamber 135 may be coupled with the ion implantation assembly 17 to perform the ion implantation process (which will be described in detail later).

In some embodiments, the first process-transfer module 13 may further comprise a first process-transfer robot 136; the first process-transfer robot 136 may be a kind of scan robot that can be movably disposed in the first process-transfer chamber 135 and configured to selectively transfer one or more components to be transferred 2 (as shown in FIG. 3; e.g., the wafers 21-23) along multiple axes and among the first process-transfer chamber 135 and the other chambers coupled with the first process-transfer chamber 135. The multiple axes may be, for example, two, three, four, five, or more axes, which is not particularly limited herein. For example, the first process-transfer robot 136 may move along a route S (as shown in FIG. 1A) along the horizontal direction (e.g., in the direction parallel to the plane YZ as shown in FIG. 1A) in the first process-transfer chamber 135 according to the arrangement position and/or process requirements of the ion implantation assembly 17, and the first process-transfer robot 136 may selectively switch to other planar directions (e.g., in the direction parallel to the plane XY or the plane XZ as shown in FIG. 1A) to transfer the component(s) to be transferred 2 between the first process-transfer chamber 135 and the ion implantation assembly 17 and perform ion implantation processes corresponding to different incident angles (i.e., the angles between the plane where the wafer is disposed and the incident direction of the ion beam). The route S may be a straight line, a curve, or any combination of the straight line and the curve.

In some embodiments, the first process-transfer robot 136 has one robotic arm, the robotic arm may comprise one end effector (not additionally denoted), and the end effector is configured to pick and place as well as hold wafers (e.g., the wafers 21-23 as shown in FIG. 3) and allow the wafers 21-23 held by the end effector to be switched and placed along multiple axes or planes. The multiple axes may be, for example, two, three, four, five, or more axes, which is not particularly limited herein.

The following examples illustrate specific embodiments of the third load-lock module (LLM3) 14, but the instant disclosure is not particularly limited to these embodiments.

In some embodiments, the third load-lock module 14 may accommodate one or more components to be transferred 2 (as shown in FIG. 3; e.g., the wafers 21-23); for example, the third load-lock module 14 has a third load-lock chamber 141 and a third vacuum-transfer chamber 142 to provide a space to accommodate the component(s) to be transferred 2. In FIG. 1A and FIG. 1C, the third load-lock chamber 141 may be selectively in communication with or not in communication with the first vacuum-transfer module 11 (or its first vacuum-transfer chamber 111) through one or more valves V9. Hence, in some embodiments, the third load-lock chamber 141 may be in communication with the atmosphere of the first vacuum-transfer module 11 in case that the communication is needed, and not in communication with the atmosphere of the first vacuum-transfer module 11 in case that the communication is not needed. In addition, in FIG. 1A and FIG. 1C, the third load-lock chamber 141 may be selectively in communication with or not in communication with the third vacuum-transfer chamber 142 through one or more valves V10. Hence, in some embodiments, the third load-lock chamber 141 may be in communication with the atmosphere of the third vacuum-transfer chamber 142 in case that the communication is needed, and not in communication with the atmosphere of the third vacuum-transfer chamber 142 in case that the communication is not needed.

For example, in FIG. 1A and FIG. 1D, in accordance with different process requirements, the pressure P11 of the first vacuum-transfer module 11 may be maintained at a first pressure (e.g., any pressure less than or equal to 1×10⁻² torr) or within the tolerable range thereof (e.g., within +5% of the first pressure); the pressure P14′ of the third vacuum-transfer chamber 142 may be maintained at a second pressure (e.g., any pressure less than or equal to 1×10⁻² torr) or within the tolerable range thereof (e.g., within ±5% of the second pressure); and the pressure P14 of the third load-lock chamber 141 may be maintained within a range less than or equal to 1×10⁻² torr. For example, the third load-lock chamber 141 may be in communication with the first vacuum-transfer chamber 111 through the regulation of the valve V9; and in case that the valve V10 is closed (i.e., the third load-lock chamber 141 is not in communication with the third vacuum-transfer chamber 142 at this time), the pressure P14 of the third load-lock chamber 141 may thus be equal to the pressure P11 of the first vacuum-transfer chamber 111, for example, any pressure less than or equal to 1×10⁻² torr (e.g., 1×10⁻⁶ torr). For another example, the third load-lock chamber 141 may be in communication with the third vacuum-transfer chamber 142 through the valve V10; and in case that the valve V9 is closed (i.e., the third load-lock chamber 141 is not in communication with the first vacuum-transfer chamber 111 at this time), the pressure P14 of the third load-lock chamber 141 may thus be equal to the pressure P14′ of the third vacuum-transfer chamber 142, for example, less than or equal to 1×10⁻² torr (e.g., 5×10⁻⁴ torr). In other words, the pressure P11 of the first vacuum-transfer module 11 (or its first vacuum-transfer chamber 111), the pressure P14 of the third load-lock chamber 141, and the pressure P14′ of the third vacuum-transfer chamber 142 may be less than or equal to 1×10⁻² torr. Hence, in some embodiments, even though the pressure P14′ of the third vacuum-transfer chamber 142 is set to be apparently different from the pressure P11 of the first vacuum-transfer module 11, it is only necessary to regulate the pressure P14 of the third load-lock chamber 141, whose volume can be minimized as much as possible, to firstly be the same as the pressure P11 and then be the same as the pressure P14′, so as to save the time previously required for the two chambers with apparently greater volumes (e.g., the third vacuum-transfer chamber 142 and the first vacuum-transfer chamber 111 as shown in FIG. 1A) to reach a pressure balance, thereby reducing the process time and cost.

In some embodiments, the first vacuum-transfer module 11 has a first vacuum-transfer chamber 111 configured as a polygonal chamber, such as the pentagonal chamber as shown in FIG. 1A. As shown in FIG. 1A and FIG. 1B, the pentagonal chamber may be a chamber enclosed by, in sequence, the seventh side L7, the fifth side L5, the sixth side L6, and the other two sides (not additionally denoted) that are adjacent to each other with the other two sides adjacent to the seventh side L7. At least three sides of the pentagonal chamber may be used to couple with the third vacuum-transfer chamber 142 and the chambers of other modules. For example, as shown in FIG. 1A to FIG. 1C, the third vacuum-transfer chamber 142 and the third load-lock chamber 141 may be selectively in communication with or not in communication with each other through the fifth side L5 and the valve V10; the third vacuum-transfer chamber 142 and the second process-transfer module 15 (or its second process-transfer chamber 151) may be selectively in communication with or not in communication with each other through the sixth side L6 and the valve V11; and the third vacuum-transfer chamber 142 and the third process-transfer module 16 (or its third process-transfer chamber 161) may be selectively in communication with or not in communication with each other through the seventh side L7 and the valve V12.

In some embodiments, as shown in FIG. 1A and FIG. 1D, in accordance with different process requirements, the pressure P14′ of the third vacuum-transfer chamber 142 may be maintained at a certain pressure or within the tolerable range thereof (e.g., within ±5% of the certain pressure), for example, maintained at any pressure less than or equal to 1×10⁻² torr.

In some embodiments, as shown in FIG. 1A and FIG. 1D, the pressure P14′ of the third vacuum-transfer chamber 142 may be arranged to be the same as the pressure P15 of the second process-transfer module 15 (or its second process-transfer chamber 151).

For example, in FIG. 1A and FIG. 1D, in accordance with different process requirements, the pressure P14′ of the third vacuum-transfer module 142 and the pressure P15 of the second process-transfer module 15 (or its second process-transfer chamber 151) may be maintained the same or within the tolerable range thereof (e.g., its pressure difference is maintained within ±5%); for example, both are maintained at any pressure within a range from 5×10⁻⁴ torr to 1×10⁻² torr. Therefore, in some embodiments, even though one or more components to be transferred 2 (as shown in FIG. 3; e.g., the wafers 21-23) are temporarily placed in the third vacuum-transfer chamber 142 due to the needs of the process, the pressure P14′ of the third vacuum-transfer chamber 142 is substantially similar to the pressure P15 of the chamber that is coupled with the third vacuum-transfer chamber 142, the component(s) to be transferred 2 may be immediately transferred to the chamber coupled with the third vacuum-transfer chamber 142 (e.g., the second process-transfer chamber 151 or the third process-transfer chamber 161) in accordance with different process requirements, which avoids the time and cost of the existing process that requires to firstly remove the component(s) to be transferred 2 from the system and then move it back into the system, and also avoids contamination of the component(s) to be transferred 2.

Moreover, as shown in FIG. 1A and FIG. 1C, the third vacuum-transfer chamber 142 may be selectively in communication with or not in communication with the third process-transfer module 16 (or its third process-transfer chamber 161) through one or more valves V12. Hence, in some embodiments, the third vacuum-transfer chamber 142 may be selectively in communication with the atmosphere of the third process-transfer module 16 in case that the communication is needed, and not in communication with the atmosphere of the third process-transfer module 16 in case that the communication is not needed.

In some embodiments, the third load-lock module 14 further comprises a third vacuum-transfer robot 143, and the third vacuum-transfer robot 143 is disposed in the third vacuum-transfer chamber 142 and configured to transfer one or more components to be transferred 2 (as shown in FIG. 3; e.g., the wafers 21-23) among the third vacuum-transfer chamber 142 and the other chambers coupled with the third vacuum-transfer chamber 142. For example, as shown in FIG. 1A, the third vacuum-transfer robot 143 may be configured to transfer the component(s) to be transferred 2 from the third load-lock chamber 141 to the interior of the third vacuum-transfer chamber 142 (or from the third vacuum-transfer chamber 142 to the interior of the third load-lock chamber 141), from the third vacuum-transfer chamber 142 to the interior of the second process-transfer chamber 151 (or from the second process-transfer chamber 151 to the interior of the third vacuum-transfer chamber 142), or from the third vacuum-transfer chamber 142 to the interior of the third process-transfer chamber 161 (or from the third process-transfer chamber 161 to the interior of the third vacuum-transfer chamber 142).

In some embodiments, the third vacuum-transfer robot 143 may have one robotic arm, the robotic arm may comprise one end effector (not additionally denoted), and the end effector is configured to pick and place as well as hold wafers (e.g., the wafers 21-23 as shown in FIG. 3).

The following examples illustrate specific embodiments of the second process-transfer module (PTM2) 15, but the instant disclosure is not particularly limited to these embodiments.

In some embodiments, the second process-transfer module 15 has a second process-transfer chamber 151, and the second process-transfer chamber 151 may be configured to accommodate one or more components to be transferred 2 (as shown in FIG. 3; e.g., the wafers 21-23) to perform the corresponding process on the component(s) to be transferred 2 in accordance with different process requirements, such as a plasma-treatment process, an etching process, a post-treatment process, or a process that comprises at least two of the plasma-treatment process, the etching process, and the post-treatment process. The plasma-treatment process may be any process that generates an ion beam through a remote-end or a near-end plasma source, which may be, for example, a plasma-treatment process that generates an ion beam through at least one of the following ion sources: indirectly heated cathode (IHC) ion source, radio frequency (RF) capacitively coupled plasma (CCP) source, inductively coupled plasma (ICP) source, electron-cyclotron-resonance plasma (ECR) source, microwave-induced (MW) source, helicon wave plasma (HWP) source, surface wave plasma (SWP) source, hollow cathode plasma source, and Bernas source, so that the component(s) to be transferred 2 may be subjected to at least one of the following processes: a plasma pre-cleaning process, a plasma enhanced chemical vapor deposition (PECVD) process, a plasma annealing process, and a preheating process. The etching process may be at least one of various dry etching and wet etching. The post-treatment process may be any heat-treatment process, such as at least one of a heating process and a cooling process.

In some embodiments, as shown in FIG. 1A and FIG. 1D, in accordance with different process requirements, the pressure P15 of the second process-transfer chamber 151 may be maintained at a certain pressure or within the tolerable range thereof (e.g., within ±5% of the certain pressure), for example, the pressure P15 is maintained at any pressure within a range from 5×10⁻⁴ torr to 5 torr. For example, the second process-transfer chamber 151 is configured to perform a plasma-treatment process, and the pressure P15 thereof is maintained at 5 torr; for another example, the second process-transfer chamber 151 is configured to perform an etching process, and the pressure P15 thereof is maintained at 5×10⁻⁴ torr.

The following examples illustrate specific embodiments of the third process-transfer module (PTM3) 16, but the instant disclosure is not particularly limited to these embodiments.

In some embodiments, the third process-transfer module 16 has a third process-transfer chamber 161, and the third process-transfer chamber 161 may be configured to accommodate one or more components to be transferred 2 (as shown in FIG. 3; e.g., the wafer 21-23) to perform the corresponding process on the component(s) to be transferred 2 in accordance with different process requirements, such as a plasma-treatment process, an etching process, a post-treatment process, or a process that comprises at least two of the plasma-treatment process, the etching process, and the post-treatment process. Embodiments of the plasma-treatment process, the etching process, and the post-treatment process may be referred to the aforementioned embodiments, which is thus not further described in detail herein. In some embodiments, the process performed by the third process-transfer chamber 161 may be adjusted in accordance with the process performed by the second process-transfer chamber 151; for example, the second process-transfer chamber 151 is configured to perform the plasma-treatment process, and the third process-transfer chamber 161 is configured to perform the post-treatment process. Hence, in some embodiments, after the corresponding processes are performed in the second process-transfer chamber 151 and the third process-transfer chamber 161, at least the plasma-treatment process and the post-treatment process can be completed.

In some embodiments, as shown in FIG. 1A and FIG. 1C, the third process-transfer chamber 161 may be selectively in communication with or not in communication with the first vacuum-transfer module 11 (or its first vacuum-transfer chamber 111) through one or more valves V13. Hence, in some embodiments, the third process-transfer chamber 161 may be selectively in communication with the atmosphere of the first vacuum-transfer chamber 111 in case that the communication is needed, and not in communication with the atmosphere of the first vacuum-transfer chamber 111 in case that the communication is not needed.

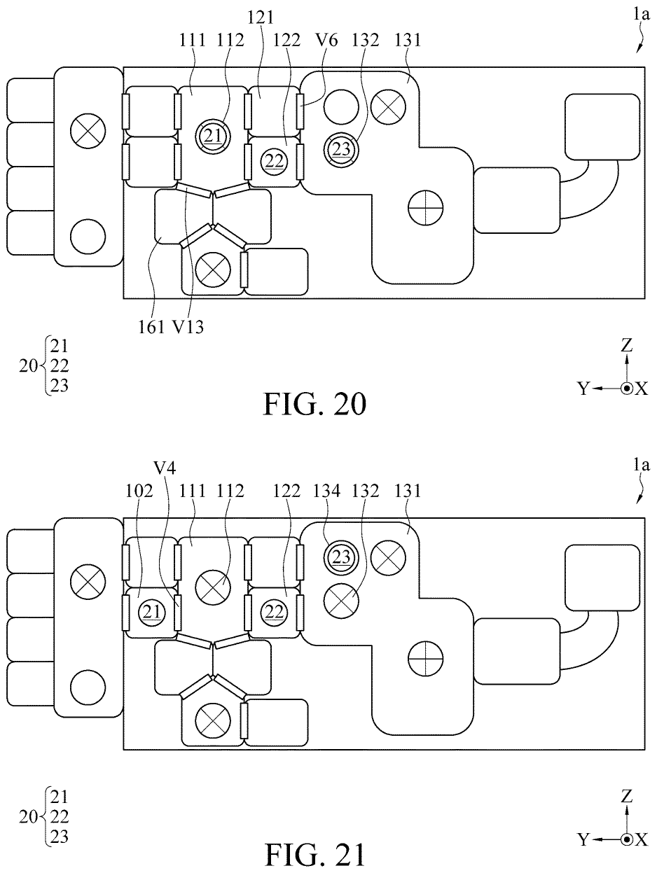

For example, in FIG. 1A and FIG. 1D, in accordance with different process requirements, the pressure P11 of the first vacuum-transfer module 11 may be maintained at a first pressure (e.g., any pressure less than or equal to 1×10⁻² torr) or within the tolerable range thereof (e.g., within ±5% of the first pressure); the pressure P14′ of the third vacuum-transfer chamber 142 may be maintained at a second pressure (e.g., any pressure less than or equal to 1×10⁻² torr) or within the tolerable range thereof (e.g., within +5% of the second pressure); and during the post-treatment process (e.g., the wafer cooling), the valve V12 is usually closed (as shown in FIG. 1C) to introduce gas, and thus the pressure P16 of the third process-transfer chamber 161 may be maintained at any pressure within a range from 1×10⁻² torr to 5 torr. In case that a wafer (e.g., the wafer 21 as shown in FIG. 19 and FIG. 20, which will be described in detail later) needs to be transferred to the first vacuum-transfer chamber 111 through the third process-transfer chamber 161, for example, the third process-transfer chamber 161 may be in communication with the first vacuum-transfer chamber 111 through the regulation of the valve V13 (as shown in FIG. 1C); and in case that the valve V12 is closed (i.e., the third process-transfer chamber 161 is not in communication with the third vacuum-transfer chamber 142 at this time), the pressure P16 of the third process-transfer chamber 161 may thus be equal to the pressure P11 of the first vacuum-transfer chamber 111, for example, any pressure less than or equal to 1×10⁻² torr. For another example, the third process-transfer chamber 161 may be in communication with the third vacuum-transfer chamber 142 through the valve V12 (as shown in FIG. 1C); and in case that the valve V13 is closed (i.e., the third process-transfer chamber 161 is not in communication with the first vacuum-transfer chamber 111 at this time), the pressure P16 of the third process-transfer chamber 161 may thus be equal to the pressure P14′ of the third vacuum-transfer chamber 142, for example, both are maintained at any pressure less than or equal to 1×10⁻² torr. Accordingly, in some embodiments, even though the pressure P14′ of the third vacuum-transfer chamber 142 is set to be apparently different from the pressure P11 of the first vacuum-transfer module 11 (or the first vacuum-transfer chamber 111), it is only necessary to regulate the pressure P16 of the third process-transfer chamber 161, whose volume can be minimized as much as possible, to firstly be the same as the pressure P14′ and then be the same as the pressure P11, so as to save the time previously required for the two chambers with apparently greater volumes (e.g., the third vacuum-transfer chamber 142 and the first vacuum-transfer chamber 111 as shown in FIG. 1A) to reach a pressure balance, thereby reducing the process time and cost.

The following examples illustrate specific embodiments of the equipment front end module 19, but the instant disclosure is not particularly limited to these embodiments.

In some embodiments, as shown in FIG. 1A, the multiple-chamber semiconductor serial constructing apparatus 1a further comprises an equipment front end module 19, the equipment front end module 19 comprises an equipment front end chamber 191 coupled with the first load-lock chambers 101, 102 to accommodate one or more components to be transferred 2 (as shown in FIG. 3; e.g., the wafers 21-23) to allow the component(s) to be transferred 2 to be transferred to the first load-lock chambers 101, 102, or allow the component(s) to be transferred 2 from the first load-lock chambers 101, 102 to be transferred to the other component(s) coupled with the first load-lock chambers 101, 102 (e.g., the front opening unified pod 18).

In some embodiments, as shown in FIG. 1A, the equipment front end module 19 further comprises an equipment front end robot 192; and the equipment front end robot 192 is disposed in the equipment front end chamber 191 and configured to transfer the component(s) to be transferred 2 (as shown in FIG. 3; e.g., the wafers 21-23) between the other component(s) coupled with the equipment front end module 19 (e.g., the front opening unified pod 18) and the first load-lock chambers 101, 102. The equipment front end robot 192 has one or more robotic arms, each of the robotic arms may comprise one or more end effectors (not additionally denoted), and each of the end effectors is configured to pick and place as well as hold wafers (e.g., the wafers 21-23 as shown in FIG. 3); and the robotic arm(s) and the end effector(s) of the equipment front end robot 192 may be referred to the specific embodiments of the robotic arm(s) and the end effector(s) of the first vacuum-transfer robot 112, which is thus not further described in detail herein.

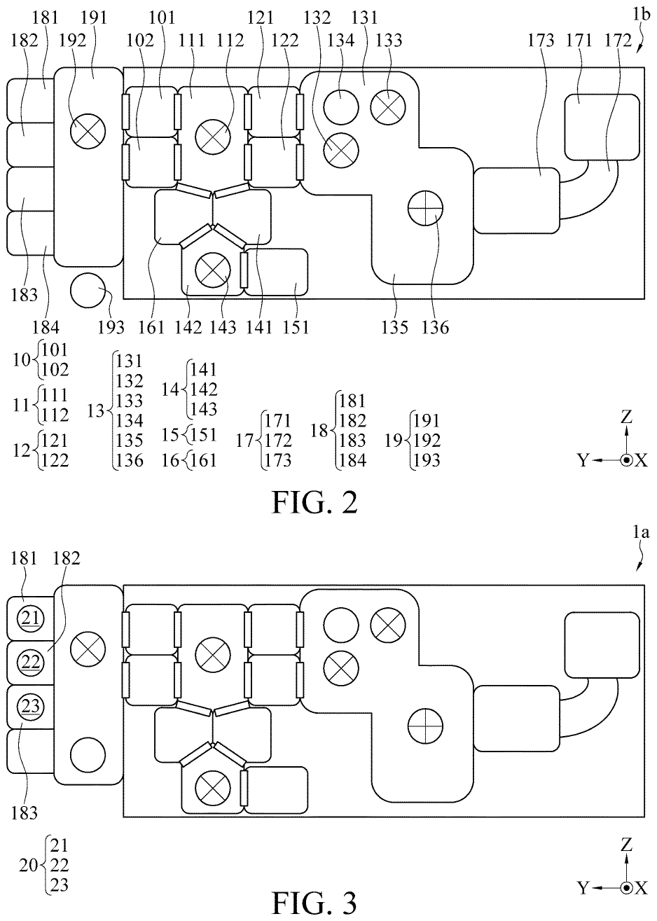

In some embodiments, the equipment front end module 19 further comprises an equipment front end aligner 193; the equipment front end aligner 193 may be disposed at any location in the equipment front end chamber 191 (as shown in the multiple-chamber semiconductor serial constructing apparatus 1a of FIG. 1A) or may be disposed at any location outside the equipment front end chamber 191 (as shown in the multiple-chamber semiconductor serial constructing apparatus 1b of FIG. 2). The equipment front end aligner 193 is configured to hold one or more components to be transferred 2 (as shown in FIG. 3; e.g., the wafers 21-23); for example, the equipment front end aligner 193 is any device having the function of being arranged to align the component(s) to be transferred 2, so as to perform the alignment process on the component(s) to be transferred 2 before the component(s) to be transferred 2 is transferred to the first load-lock chambers 101, 102 (or after the component(s) to be transferred 2 is transferred from the first load-lock chambers 101, 102 to the equipment front end chamber 191). Embodiments of the equipment front end aligner 193 may be referred to the specific embodiments of the second vacuum-transfer aligner 134, which is thus not further described in detail herein.

The following examples illustrate specific embodiments of the front opening unified pod 18, but the instant disclosure is not particularly limited to these embodiments.

In some embodiments, as shown in FIG. 1A, the multiple-chamber semiconductor serial constructing apparatus 1a further comprises a front opening unified pod 18 (e.g., the front opening unified pods 181-184), each of the front opening unified pods 181-184 is coupled with the equipment front end chamber 191, and each of the front opening unified pods 181-184 is configured to hold one or more components to be transferred 2 (as shown in FIG. 3; e.g., the wafers 21-23) to allow the component(s) to be transferred 2 to be transferred to the equipment front end chamber 191 or to accommodate the component(s) to be transferred 2 from the equipment front end chamber 191.

The following examples illustrate specific embodiments of the ion implantation assembly 17, but the instant disclosure is not particularly limited to these embodiments.

In some embodiments, as shown in FIG. 1A, the multiple-chamber semiconductor serial constructing apparatus 1a may further comprise an ion implantation assembly 17; the ion implantation assembly 17 may be any component or device capable of generating an ion beam (beamline), and the ion beam (beamline) may be of various shapes, such as an elongate ribbon beam, a spot beam, a pencil beam, or a scanned beam that is scanned electromagnetically or electrostatically, which is not particularly limited herein.

The ion implantation assembly 17 comprises an ion implantation chamber 173, a mass-spectrometry-analysis unit 172, and an ion-supply unit 171. The ion implantation chamber 173 may be selectively coupled with the first process-transfer chamber 135; the mass-spectrometry-analysis unit 172 may be selectively coupled with the ion implantation chamber 173; and the ion-supply unit 171 may be selectively coupled with the mass-spectrometry-analysis unit 172 to perform the corresponding ion implantation process.

The ion-supply unit 171 may ionize gases from the exterior of the system (such as, but not limited to, diborane (B₂H₆), boron trifluoride (BF₃), phosphine (PH₃) or arsine (AsH₃)) to generate ions, and the ions comprise, for example, cations as dopants (such as, but not limited to, boron (B⁺), phosphorus (P⁺), arsenic (As⁺) or antimony (Sb⁺)).

The mass-spectrometry-analysis unit 172 may select certain ions by utilizing the mass difference between the ions in the ion-supply unit 171. In some embodiments, the mass-spectrometry-analysis unit 172 comprises a spectrometer magnet having a refractive angle (e.g., 90°), and the magnetic field of the spectrometer magnet may be used to deflect an ion beam (beamline) containing impurities or different cations, so that the deflected ion beam (beamline) may follow an arc-shaped trajectory. The ions selected by the mass-spectrometry-analysis unit 172 may be accelerated or decelerated by the control of an acceleration device and the electric field. In case that the cations move relatively faster and have relatively higher kinetic energy, the cations may be implanted into the component(s) to be transferred 2 (e.g., a semiconductor substrate or the wafers 21-23 as shown in FIG. 3) upon collision with the surface of the component(s) to be transferred 2, so as to complete the ion implantation process performed by the ion implantation assembly 17.

The following exemplarily describes specific embodiments of some processes performed by the multiple-chamber semiconductor serial constructing apparatus 1a through FIG. 3 to FIG. 39; however, various parameter conditions (e.g., pressure) and transfer sequences may be adjusted according to actual requirements. Accordingly, it is noted that the instant disclosure encompassed by the present application is not particularly limited to these embodiments.

Additionally, it is noted that the components to be transferred 2 are exemplarily illustrated herein by the wafers 21-23; however, the number of wafers may be increased or decreased according to actual requirements, which is not particularly limited thereto. For ease of identification, each of the wafers 21-23 is labeled according to the order in which it enters the first load-lock module 10, such that a smaller numeral refers to the corresponding wafer entering the first load-lock module 10 earlier.

Moreover, in FIG. 3 to FIG. 39, each of the valves V1-V13 is normally maintained in a closed state, and each of the valves V1-V13 is independently opened only when needed. Therefore, unless specifically described herein, the valves V1-V13 should be understood to be in the closed state; and in such closed state, two independent spaces coupled with each other through any of the valves V1-V13 are not in communication with each other. The valves V1-V13 may be any suitable valves having a function of controlling whether to establish the communication and a function of controlling a flow rate of gas passing therethrough, which is not particularly limited herein.

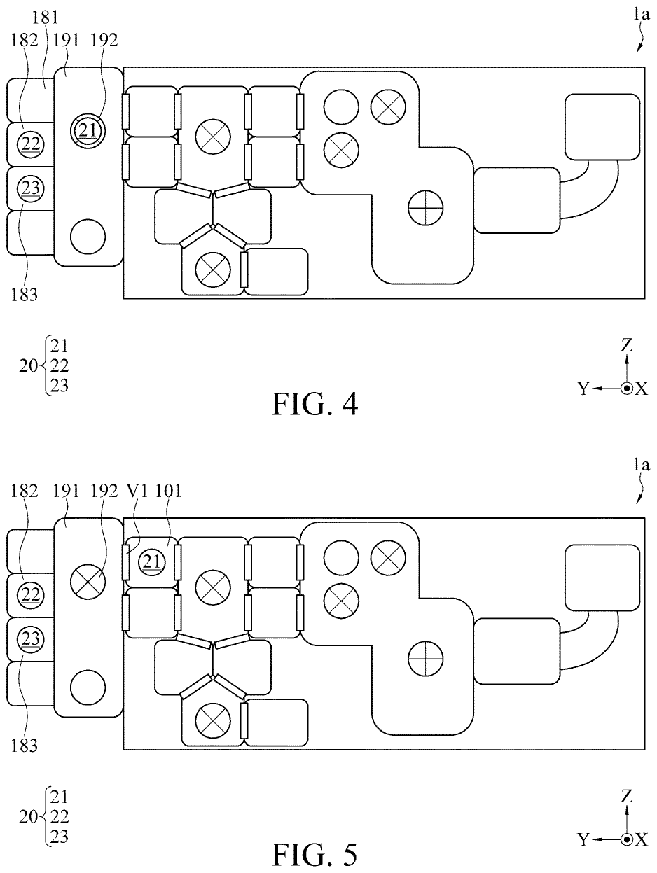

In FIG. 3, a plurality of components to be transferred 2 (exemplarily illustrated as the wafers 21-23) are respectively accommodated in the front opening unified pods 181-183. (It should be noted that, although three wafers 21-23 are illustrated herein, the instant disclosure is not limited thereto; for example, another wafer accommodated in the front opening unified pod 184 may also be included; and each of the wafers 21-23 may respectively represent a single wafer, or a wafer set comprising 5, 10, 25, or more wafers.) In FIG. 4, the equipment front end robot 192 of the equipment front end module 19 is actuated to pick the wafer 21 placed in the front opening unified pod 181 to transfer the wafer 21 to the interior of the equipment front end chamber 191.

In FIG. 5, the valve V1 is opened, and the equipment front end robot 192 is actuated to transfer the wafer 21 to the interior of the first load-lock chamber 101. The valve V1 is closed, and the pressure P10 (as shown in FIG. 1D) of the first load-lock chamber 101 is adjusted from, for example, 760 torr to any pressure less than or equal to 1×10⁻² torr (e.g., 5×10⁻⁴ torr).

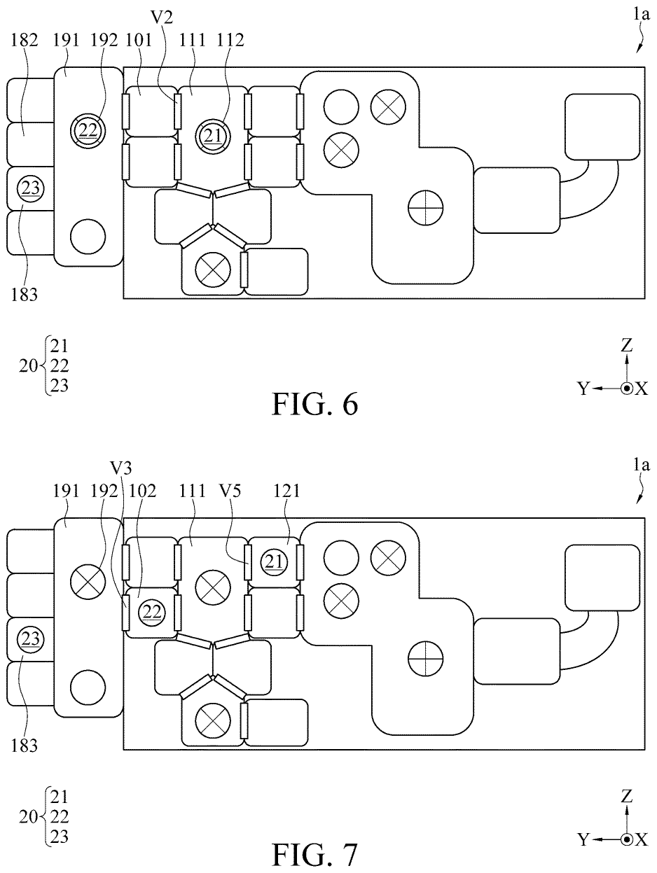

In FIG. 6, the valve V2 is opened, and the first vacuum-transfer robot 112 of the first vacuum-transfer module 11 is actuated to pick the wafer 21 placed in the first load-lock chamber 101 to transfer the wafer 21 to the interior of the first vacuum-transfer chamber 111. The valve V2 is closed. The pressure P11 (as shown in FIG. 1D) of the first vacuum-transfer chamber 111 and the pressure P10 (as shown in FIG. 1D) of the first load-lock chamber 101 may be both maintained at, for example, any pressure less than or equal to 1×10⁻² torr (e.g., 5×10⁻⁴ torr).

In FIG. 6, regardless of the transfer sequence of the wafer 21 (i.e., simultaneously therewith, or before or after the same), the equipment front end robot 192 is actuated to pick the wafer 22 placed in the front opening unified pod 182 to transfer the wafer 22 to the interior of the equipment front end chamber 191.

In FIG. 7, the valve V5 is opened, and the first vacuum-transfer robot 112 is actuated to transfer the wafer 21 to the interior of the second load-lock chamber 121. The valve V5 is closed. The pressure P12 (as shown in FIG. 1D) of the second load-lock chamber 121 may start to be adjusted, and the pressure P12 may be different from the pressure P11 (as shown in FIG. 1D) of the first vacuum-transfer chamber 111; for example, the pressure P12 may be any pressure within a range from 1×10⁻⁷ torr to 1×10⁻² torr.

In FIG. 7, regardless of the transfer sequence of the wafer 21, the valve V3 is opened, and the equipment front end robot 192 is actuated to transfer the wafer 22 to the interior of the first load-lock chamber 102. The valve V3 is closed, and the pressure P10′ (as shown in FIG. 1D) of the first load-lock chamber 102 is adjusted from, for example, 760 torr to any pressure less than or equal to 1×10⁻² torr (e.g., 5×10⁻⁴ torr).

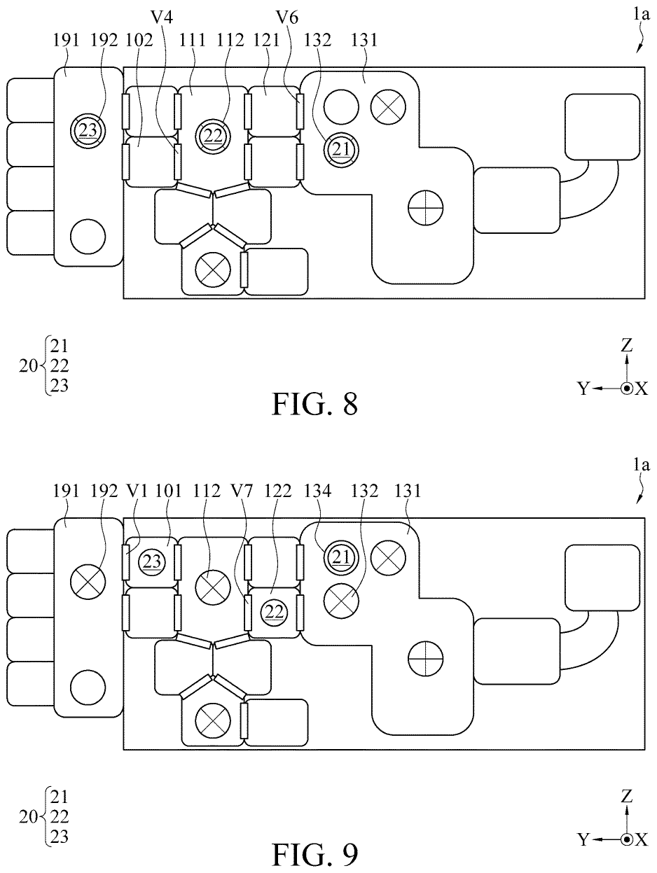

In FIG. 8, the valve V6 is opened, and the second vacuum-transfer robot 132 of the first process-transfer module 13 is actuated to pick the wafer 21 placed in the second load-lock chamber 121 to transfer the wafer 21 to the interior of the second vacuum-transfer chamber 131. The valve V6 is closed. The pressure P13 (as shown in FIG. 1D) of the second vacuum-transfer chamber 131 and the pressure P12 (as shown in FIG. 1D) of the second load-lock chamber 121 are both maintained, for example, within a range from 1×10⁻⁷ torr to 2×10⁻⁵ torr.

In FIG. 8, regardless of the transfer sequence of the wafer 21, the valve V4 is opened, and the first vacuum-transfer robot 112 is actuated to pick the wafer 22 placed in the first load-lock chamber 102 to transfer the wafer 22 to the interior of the first vacuum-transfer chamber 111. The valve V4 is closed. The pressure P11 (as shown in FIG. 1D) of the first vacuum-transfer chamber 111 and the pressure P10′ (as shown in FIG. 1D) of the first load-lock chamber 102 may be both maintained at, for example, any pressure less than or equal to 1×10⁻² torr (e.g., 5×10⁻⁴ torr).

In FIG. 8, regardless of the transfer sequence of the wafer 21, the equipment front end robot 192 is actuated to pick the wafer 23 placed in the front opening unified pod 181 to transfer the wafer 23 to the interior of the equipment front end chamber 191.

In FIG. 9, the second vacuum-transfer robot 132 is actuated to transfer the wafer 21 to the second vacuum-transfer aligner 134 to perform the alignment process corresponding to the second vacuum-transfer aligner 134.

In FIG. 9, regardless of the transfer sequence of the wafer 21, the valve V7 is opened, and the first vacuum-transfer robot 112 is actuated to transfer the wafer 22 to the interior of the second load-lock chamber 122. The valve V7 is closed. The pressure P12′ (as shown in FIG. 1D) of the second load-lock chamber 122 may start to be adjusted, and the pressure P12′ may be different from the pressure P11 (as shown in FIG. 1D) of the first vacuum-transfer chamber 111; for example, the pressure P12′ may be any pressure within a range from 1×10⁻⁷ torr to 1×10⁻² torr.

In FIG. 9, regardless of the transfer sequence of the wafer 21, the valve V1 is opened, and the equipment front end robot 192 is actuated to transfer the wafer 23 to the interior of the first load-lock chamber 101. The valve V1 is closed, and the pressure P10 (as shown in FIG. 1D) of the first load-lock chamber 101 is adjusted from, for example, 760 torr to any pressure less than or equal to 1×10⁻² torr (e.g., 5×10⁻⁴ torr).

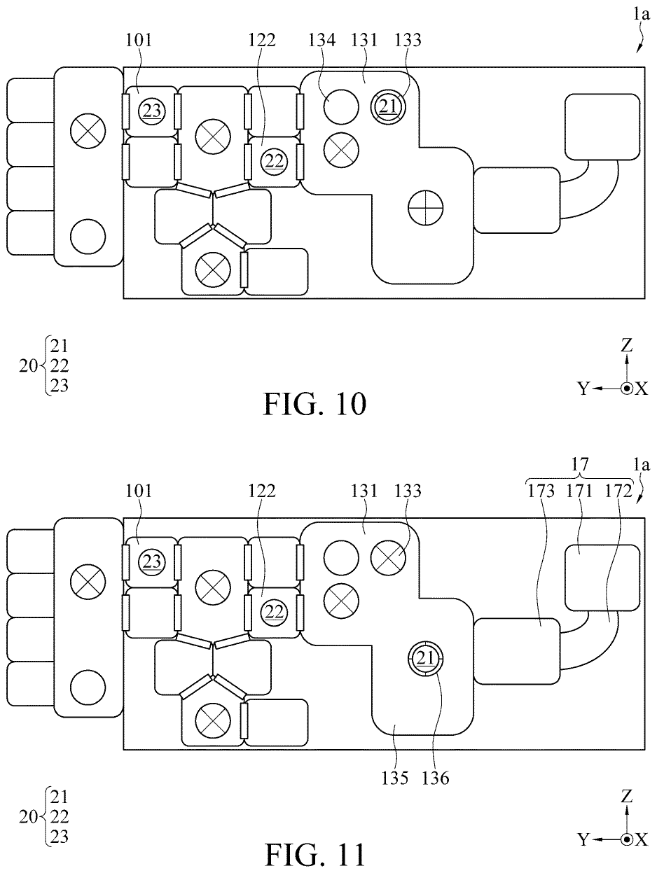

In FIG. 10, after the alignment process of the wafer 21 is completed, the second vacuum-transfer robot 133 of the first process-transfer module 13 is actuated to pick the wafer 21 placed in the second vacuum-transfer aligner 134.

In FIG. 11, the second vacuum-transfer robot 133 is actuated to transfer the wafer 21 to the first process-transfer robot 136 of the first process-transfer module 13, and the first process-transfer robot 136 is actuated to transfer the wafer 21 in the first process-transfer chamber 135 to perform the ion implantation process corresponding to the ion implantation assembly 17.

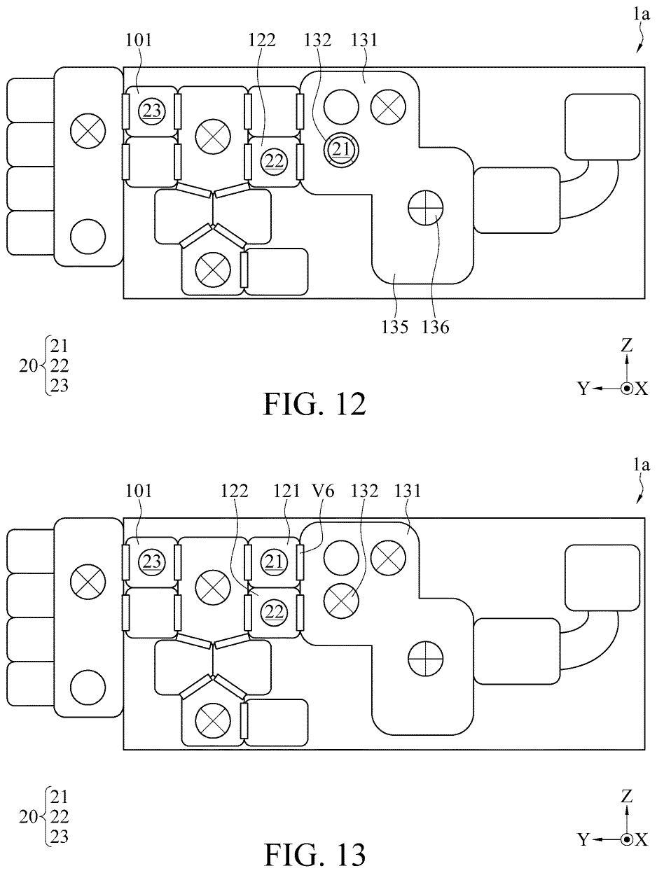

In FIG. 12, after the ion implantation process of the wafer 21 is completed, the second vacuum-transfer robot 132 is actuated to pick the wafer 21 from the first process-transfer robot 136 to transfer the wafer 21 to the interior of the second vacuum-transfer chamber 131.

In FIG. 13, the valve V6 is opened, and the second vacuum-transfer robot 132 is actuated to transfer the wafer 21 back to the interior of the second load-lock chamber 121. The valve V6 is closed. The pressure P12 (as shown in FIG. 1D) of the second load-lock chamber 121 may be independently adjusted so that the pressure P12 and the pressure P11 (as shown in FIG. 1D) of the first vacuum-transfer chamber 111 may be both maintained at, for example, any pressure less than or equal to 1×10⁻² torr.

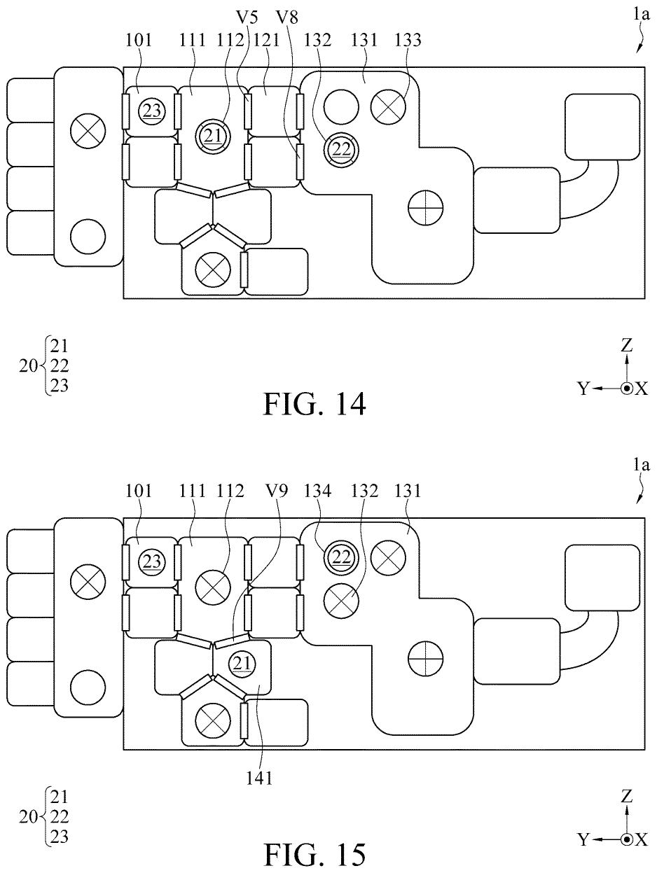

In FIG. 14, the valve V5 is opened, and the first vacuum-transfer robot 112 is actuated to pick the wafer 21 placed in the second load-lock chamber 121 to transfer the wafer 21 to the interior of the first vacuum-transfer chamber 111. The valve V5 is closed.

In FIG. 14, regardless of the transfer sequence of the wafer 21, the valve V8 is opened, and the second vacuum-transfer robot 132 is actuated to pick the wafer 22 placed in the second load-lock chamber 122 to transfer the wafer 22 to the interior of the second vacuum-transfer chamber 131. The valve V8 is closed. The pressure P13 (as shown in FIG. 1D) of the second vacuum-transfer chamber 131 may be maintained at, for example, any pressure within a range from 1×10⁻⁷ torr to 2×10⁻⁵ torr.

In FIG. 15, after the pressure P14 (as shown in FIG. 1D) of the third load-lock chamber 141 is adjusted to, for example, any pressure less than or equal to 1×10⁻² torr (e.g., 5×10⁻⁴ torr), the valve V9 is opened, and the first vacuum-transfer robot 112 is actuated to transfer the wafer 21 to the interior of the third load-lock chamber 141. The valve V9 is closed.

In FIG. 15, regardless of the transfer sequence of the wafer 21, the second vacuum-transfer robot 132 is actuated to transfer the wafer 22 to the second vacuum-transfer aligner 134 to perform the alignment process corresponding to the second vacuum-transfer aligner 134.

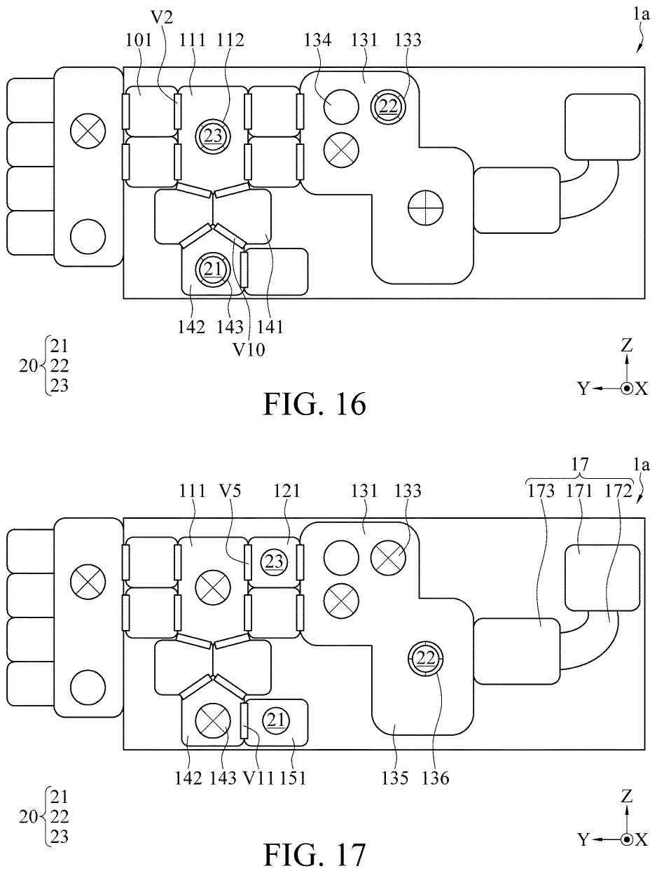

In FIG. 16, the valve V10 is opened, and the third vacuum-transfer robot 143 of the third load-lock module 14 is actuated to pick the wafer 21 placed in the third load-lock chamber 141 to transfer the wafer 21 to the interior of the third vacuum-transfer chamber 142. The valve V10 is closed. The pressure P14′ (as shown in FIG. 1D) of the third vacuum-transfer chamber 142 and the pressure P14 (as shown in FIG. 1D) of the third load-lock chamber 141 may be both maintained at, for example, any pressure less than or equal to 1×10⁻² torr (e.g., 5×10⁻⁴ torr).

In FIG. 16, regardless of the transfer sequence of the wafer 21, after the alignment process of the wafer 22 is completed, the second vacuum-transfer robot 133 is actuated to pick the wafer 22 placed in the second vacuum-transfer aligner 134.

In FIG. 16, regardless of the transfer sequence of the wafer 21, the valve V2 is opened, and the first vacuum-transfer robot 112 is actuated to transfer the wafer 23 placed in the first load-lock chamber 101 to transfer the wafer 23 to the interior of the first vacuum-transfer chamber 111. The valve V2 is closed. The pressure P11 (as shown in FIG. 1D) of the first vacuum-transfer chamber 111 and the pressure P10 (as shown in FIG. 1D) of the first load-lock chamber 101 may be maintained at, for example, any pressure less than or equal to 1×10⁻² torr (e.g., 5×10⁻⁴ torr).

In FIG. 17, the valve V11 is opened, and the third vacuum-transfer robot 143 is actuated to transfer the wafer 21 to the interior of the second process-transfer chamber 151. The valve V11 is closed. The pressure P15 (as shown in FIG. 1D) of the second process-transfer chamber 151 and the pressure P14′ (as shown in FIG. 1D) of the third vacuum-transfer chamber 142 may be maintained at, for example, any pressure less than or equal to 1×10⁻² torr (e.g., 5×10⁻⁴ torr). Next, the pressure P15 of the second process-transfer chamber 151 is further adjusted, for example, increased to 5 torr to perform the process corresponding to the second process-transfer module 15, for example, the plasma-treatment process, on the wafer 21.

In FIG. 17, regardless of the transfer sequence of the wafer 21, the second vacuum-transfer robot 133 is actuated to transfer the wafer 22 to the location of the first process-transfer robot 136, and the first process-transfer robot 136 is actuated to transfer the wafer 22 to the interior of the first process-transfer chamber 135 to perform the ion implantation process corresponding to the ion implantation assembly 17.

In FIG. 17, regardless of the transfer sequence of the wafer 21, the valve V5 is opened, and the first vacuum-transfer robot 112 is actuated to transfer the wafer 23 to the interior of the second load-lock chamber 121. The valve V5 is closed. The pressure P12 (as shown in FIG. 1D) of the second load-lock chamber 121 may start to be adjusted, and the pressure P12 may be different from the pressure P11 (as shown in FIG. 1D) of the first vacuum-transfer chamber 111; for example, the pressure P12 may be any pressure within a range from 1×10⁻⁷ torr to 1×10⁻² torr.

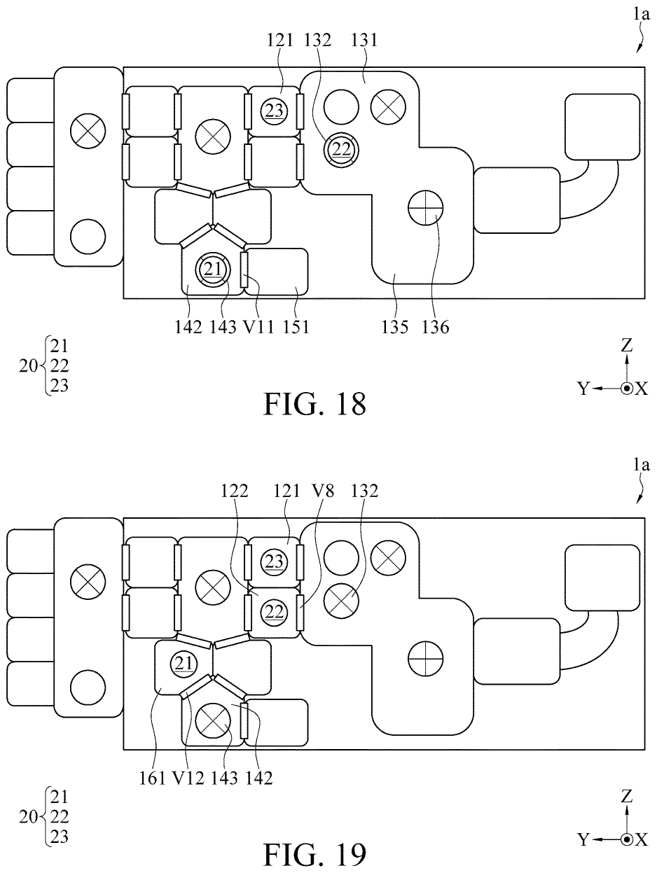

In FIG. 18, after the process of the wafer 21 performed in the second process-transfer module 15 (e.g., the plasma-treatment process) is completed, the pressure P15 (as shown in FIG. 1D) of the second process-transfer chamber 151 is adjusted to any pressure less than or equal to 1×10⁻² torr (e.g., 5×10⁻⁴ torr). The valve V11 is opened, and the third vacuum-transfer robot 143 is actuated to pick the wafer 21 placed in the second process-transfer chamber 151 to transfer the wafer 21 to the interior of the third vacuum-transfer chamber 142. The valve V11 is closed. The pressure P14′ (as shown in FIG. 1D) of the third vacuum-transfer chamber 142 and the pressure P15 (as shown in FIG. 1D) of the second process-transfer chamber 151 may be both maintained at, for example, any pressure less than or equal to 1×10⁻² torr (e.g., 5×10⁻⁴ torr).

In FIG. 18, regardless of the transfer sequence of the wafer 21, after the ion implantation process of the wafer 22 is completed, the second vacuum-transfer robot 132 is actuated to pick the wafer 22 from the first process-transfer robot 136 to transfer the wafer 22 to the interior of the second vacuum-transfer chamber 131.

In FIG. 19, the valve V12 is opened, and the third vacuum-transfer robot 143 is actuated to transfer the wafer 21 to the interior of the third process-transfer chamber 161. The valve V12 is closed. The pressure P16 (as shown in FIG. 1D) of the third process-transfer chamber 161 and the pressure P14′ (as shown in FIG. 1D) of the third vacuum-transfer chamber 142 may be both maintained at, for example, any pressure less than or equal to 1×10⁻² torr (e.g., 5×10⁻⁴ torr). Next, the pressure P14′ of the third vacuum-transfer chamber 142 is further adjusted (for example, adjusted to any pressure within a range from 5×10⁻⁴ torr to 5 torr) to perform the process corresponding to the third process-transfer module 16, for example, the post-treatment process, on the wafer 21.

In FIG. 19, regardless of the transfer sequence of the wafer 21, the valve V8 is opened, and the second vacuum-transfer robot 132 is actuated to transfer the wafer 22 back to the interior of the second load-lock chamber 122. The valve V8 is closed. The pressure P12′ (as shown in FIG. 1D) of the second load-lock chamber 122 may be independently adjusted so that the pressure P12′ and the pressure P11 (as shown in FIG. 1D) of the first vacuum-transfer chamber 111 may be both maintained at, for example, any pressure less than or equal to 1×10⁻² torr.

In FIG. 20, after the process of the wafer 21 performed in the third process-transfer module 16 (e.g., the etching process or the post-treatment process) is completed, the pressure P16 (as shown in FIG. 1D) of the third process-transfer chamber 161 is adjusted to any pressure less than or equal to 1×10⁻² torr to maintain the pressure P16 the same as the pressure P11 (as shown in FIG. 1D; e.g., any pressure less than or equal to 1×10⁻² torr) of the first vacuum-transfer chamber 111. The valve V13 is opened, and the first vacuum-transfer robot 112 is actuated to pick the wafer 21 placed in the third process-transfer chamber 161 to transfer the wafer 21 to the interior of the first vacuum-transfer chamber 111. The valve V13 is closed. The pressure P16 (as shown in FIG. 1D) of the third process-transfer chamber 161 and the pressure P11 (as shown in FIG. 1D) of the first vacuum-transfer chamber 111 may be maintained at, for example, any pressure less than or equal to 1×10⁻² torr.

In FIG. 20, regardless of the transfer sequence of the wafer 21, the valve V6 is opened, and the second vacuum-transfer robot 132 is actuated to pick the wafer 23 placed in the second load-lock chamber 121 to transfer the wafer 23 to the interior of the second vacuum-transfer chamber 131. The valve V6 is closed. The pressure P13 (as shown in FIG. 1D) of the second vacuum-transfer chamber 131 may be maintained, for example, within a range from 1×10⁻⁷ torr to 2×10⁻⁵ torr.

In FIG. 21, before the valve V4 is opened, the pressure P10′ (as shown in FIG. 1D) of the first load-lock chamber 102 is adjusted to ensure that the pressure P10′ is the same as the pressure P11 (as shown in FIG. 1D; for example, any pressure less than or equal to 1×10⁻² torr (e.g., 5×10⁻⁴ torr)) of the first vacuum-transfer chamber 111. The valve V4 is opened, and the first vacuum-transfer robot 112 is actuated to transfer the wafer 21 to the interior of the first load-lock chamber 102. The valve V4 is closed.

In FIG. 21, regardless of the transfer sequence of the wafer 21, the second vacuum-transfer robot 132 is actuated to transfer the wafer 23 to the second vacuum-transfer aligner 134 to perform the alignment process corresponding to the second vacuum-transfer aligner 134.

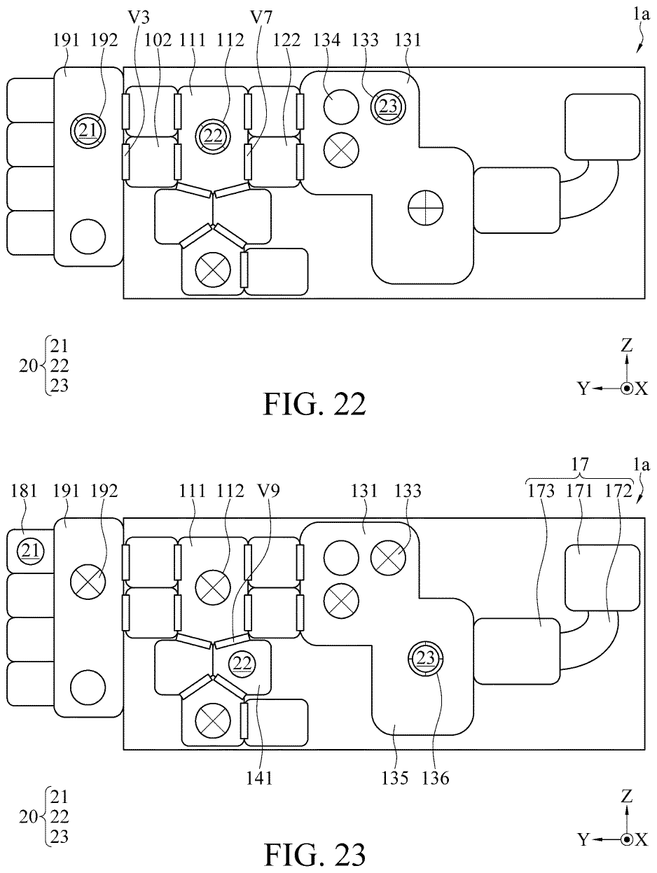

In FIG. 22, before the valve V3 is opened, the pressure P10′ (as shown in FIG. 1D) of the first load-lock chamber 102 is adjusted to ensure that the pressure P10′ is the same as the pressure P19 (as shown in FIG. 1D; for example, 760 torr) of the equipment front end chamber 191. The valve V3 is opened, and the equipment front end robot 192 is actuated to pick the wafer 21 placed in the first load-lock chamber 102 to transfer the wafer 21 to the interior of the equipment front end chamber 191. The valve V3 is closed. The pressure P19 of the equipment front end chamber 191 and the pressure P10′ of the first load-lock chamber 102 may be both maintained at, for example, 760 torr.

In FIG. 22, regardless of the transfer sequence of the wafer 21, the valve V7 is opened, and the first vacuum-transfer robot 112 is actuated to pick the wafer 22 placed in the second load-lock chamber 122 to transfer the wafer 22 to the interior of the first vacuum-transfer chamber 111.

In FIG. 22, regardless of the transfer sequence of the wafer 21, after the alignment process of the wafer 23 is completed, the second vacuum-transfer robot 133 is actuated to pick the wafer 23 placed in the second vacuum-transfer aligner 134.

In FIG. 23, the equipment front end robot 192 is actuated to transfer the wafer 21 to the interior of the front opening unified pod 181. At this moment, the processes for the wafer 21 (comprising the ion implantation process, the plasma-treatment process, and the post-treatment process) may be completed. Simultaneously, or before or after the processes for the wafer 21, in addition to the transfer of the wafers 22, 23, the multiple-chamber semiconductor serial constructing apparatus 1a may be further used to transfer other wafers to perform the corresponding processes on the other wafers, and the multiple-chamber semiconductor serial constructing apparatus 1a is not particularly limited to only transfer the wafers 21-23 at the same time.

In FIG. 23, regardless of the transfer sequence of the wafer 21, the valve V9 is opened, and the first vacuum-transfer robot 112 is actuated to transfer the wafer 22 to the interior of the third load-lock chamber 141. The valve V9 is closed, and the pressure P14 (as shown in FIG. 1D) of the third load-lock chamber 141 is adjusted to any pressure less than or equal to 1×10⁻² torr (e.g., 5×10⁻⁴ torr).

In FIG. 23, regardless of the transfer sequence of the wafer 21, the second vacuum-transfer robot 133 is actuated to transfer the wafer 23 to the first process-transfer robot 136, and the first process-transfer robot 136 is actuated to transfer the wafer 23 to the interior of the first process-transfer chamber 135 to perform the ion implantation process corresponding to the ion implantation assembly 17.

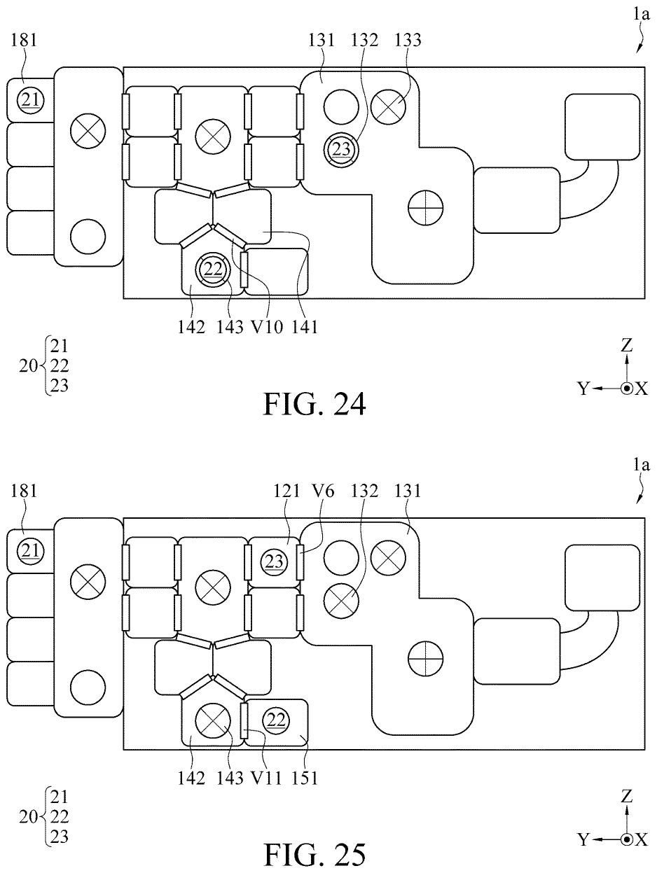

In FIG. 24, the valve V10 is opened, and the third vacuum-transfer robot 143 of the third load-lock module 14 is actuated to pick the wafer 22 placed in the third load-lock chamber 141 to transfer the wafer 22 to the third vacuum-transfer chamber 142. The valve V10 is closed. The pressure P14′ (as shown in FIG. 1D) of the third vacuum-transfer chamber 142 and the pressure P14 (as shown in FIG. 1D) of the third load-lock chamber 141 may be maintained at, for example, any pressure less than or equal to 1×10⁻² torr (e.g., 5×10⁻⁴ torr) at this moment.

In FIG. 24, regardless of the transfer sequence of the wafer 22, after the ion implantation process of the wafer 23 is completed, the second vacuum-transfer robot 132 is actuated to pick the wafer 23 from the first process-transfer robot 136 to transfer the wafer 23 to the interior of the second vacuum-transfer chamber 131.

In FIG. 25, the valve V11 is opened, and the third vacuum-transfer robot 143 is actuated to transfer the wafer 22 to the interior of the second process-transfer chamber 151. The valve V11 is closed. The pressure P15 (as shown in FIG. 1D) of the second process-transfer chamber 151 and the pressure P14′ (as shown in FIG. 1D) of the third vacuum-transfer chamber 142 may be maintained at, for example, any pressure less than or equal to 1×10⁻² torr (e.g., 5×10⁻⁴ torr). Next, the pressure P15 of the second process-transfer chamber 151 is further adjusted (for example, adjusted to 5 torr) to perform the process corresponding to the second process-transfer module 15, for example, the plasma-treatment process, on the wafer 22.

In FIG. 25, regardless of the transfer sequence of the wafer 22, the valve V6 is opened, and the second vacuum-transfer robot 132 is actuated to transfer the wafer 23 back to the interior of the second load-lock chamber 121. The valve V6 is closed. The pressure P12 (as shown in FIG. 1D) of the second load-lock chamber 121 may be independently adjusted so that the pressure P12 and the pressure P11 (as shown in FIG. 1D) of the first vacuum-transfer chamber 111 may be both maintained at, for example, any pressure less than or equal to 1×10⁻² torr.

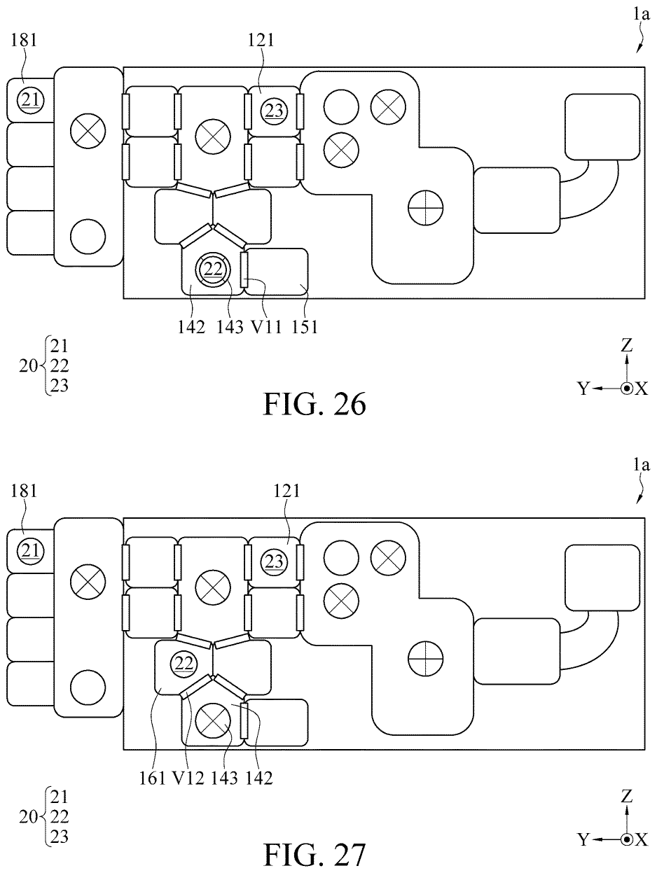

In FIG. 26, after the process of the wafer 22 performed in the second process-transfer module 15 (e.g., the plasma-treatment process) is completed, the valve V11 is opened, and the third vacuum-transfer robot 143 is actuated to pick the wafer 22 placed in the second process-transfer chamber 151 to transfer the wafer 22 to the interior of the third vacuum-transfer chamber 142. The valve V11 is closed. The pressure P14′ (as shown in FIG. 1D) of the third vacuum-transfer chamber 142 and the pressure P15 (as shown in FIG. 1D) of the second process-transfer chamber 151 may be maintained at, for example, any pressure less than or equal to 1×10⁻² torr (e.g., 5×10⁻⁴ torr) at this moment.

In FIG. 27, the valve V12 is opened, and the third vacuum-transfer robot 143 is actuated to transfer the wafer 22 to the interior of the third process-transfer chamber 161. The valve V12 is closed. The pressure P16 (as shown in FIG. 1D) of the third process-transfer chamber 161 and the pressure P14′ (as shown in FIG. 1D) of the third vacuum-transfer chamber 142 may be both maintained at, for example, any pressure less than or equal to 1×10⁻² torr (e.g., 5×10⁻⁴ torr) at this moment. Next, the pressure P14′ of the third vacuum-transfer chamber 142 is further adjusted to, for example, any pressure within a range from 5×10⁻⁴ torr to 5 torr to perform the process corresponding to the third process-transfer module 16, for example, the post-treatment process, on the wafer 22.

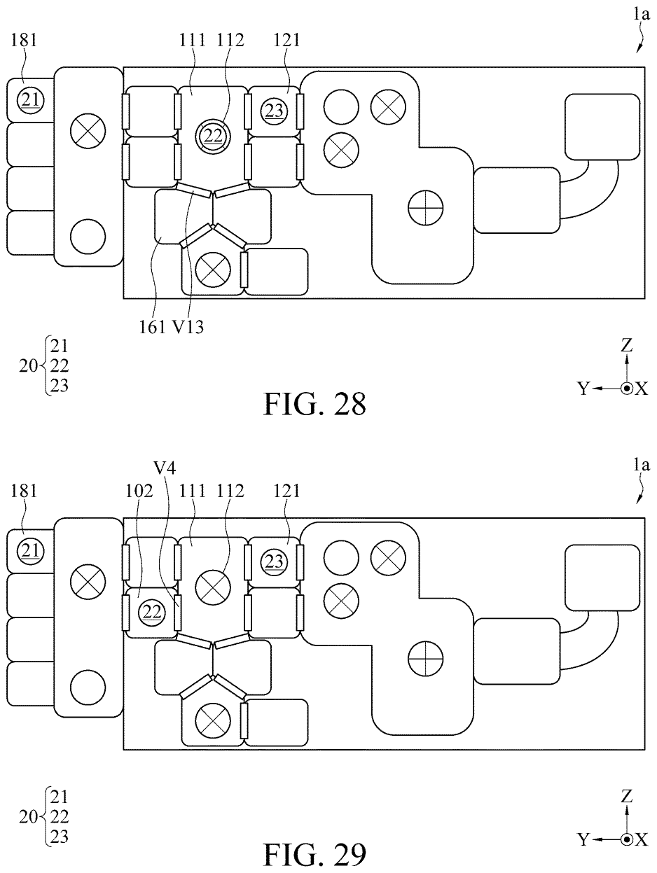

In FIG. 28, after the process of the wafer 22 performed in the third process-transfer module 16 (e.g., the post-treatment process) is completed, the pressure P16 (as shown in FIG. 1D) of the third process-transfer chamber 161 is adjusted to, for example, any pressure less than or equal to 1×10⁻² torr (e.g., 5×10⁻⁴ torr) to maintain the pressure P16 the same as the pressure P11 (as shown in FIG. 1D; for example, any pressure less than or equal to 1×10⁻² torr (e.g., 5×10⁻⁴ torr)) of the first vacuum-transfer chamber 111. The valve V13 is opened, and the first vacuum-transfer robot 112 is actuated to pick the wafer 22 placed in the third process-transfer chamber 161 to transfer the wafer 22 to the interior of the first vacuum-transfer chamber 111. The valve V13 is closed. The pressure P16 of the third process-transfer chamber 161 and the pressure P11 of the first vacuum-transfer chamber 111 may be both maintained at, for example, any pressure less than or equal to 1×10⁻² torr (e.g., 5×10⁻⁴ torr) at this moment.

In FIG. 29, before the valve V4 is opened, the pressure P10′ (as shown in FIG. 1D) of the first load-lock chamber 102 is adjusted to ensure that the pressure P10′ is the same as the pressure P11 (as shown in FIG. 1D; for example, any pressure less than or equal to 1×10⁻² torr (e.g., 5×10⁻⁴ torr)) of the first vacuum-transfer chamber 111. The valve V4 is opened, and the first vacuum-transfer robot 112 is actuated to transfer the wafer 22 to the interior of the first load-lock chamber 102. The valve V4 is closed.

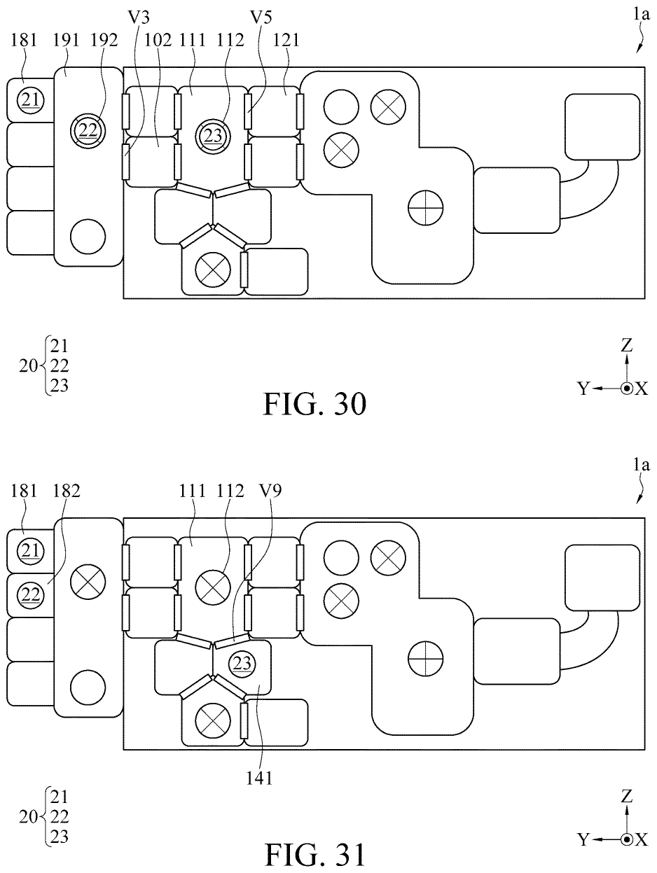

In FIG. 30, before the valve V3 is opened, the pressure P10′ (as shown in FIG. 1D) of the first load-lock chamber 102 is adjusted to ensure that the pressure P10′ is the same as the pressure P19 (as shown in FIG. 1D; for example, 760 torr) of the equipment front end chamber 191. The valve V3 is opened, and the equipment front end robot 192 is actuated to pick the wafer 22 placed in the first load-lock chamber 102 to transfer the wafer 22 to the interior of the equipment front end chamber 191. The valve V3 is closed. The pressure P19 of the equipment front end chamber 191 and the pressure P10′ of the first load-lock chamber 102 may be both maintained at, for example, 760 torr.

In FIG. 30, regardless of the transfer sequence of the wafer 22, the valve V5 is opened, and the first vacuum-transfer robot 112 is actuated to pick the wafer 23 placed in the second load-lock chamber 121 to transfer the wafer 23 to the interior of the first vacuum-transfer chamber 111.

In FIG. 31, the equipment front end robot 192 is actuated to transfer the wafer 22 to the interior of the front opening unified pod 182. At this moment, the processes for the wafer 22 (comprising the ion implantation process, the plasma-treatment process, and the post-treatment process, for example) may be completed. Simultaneously, or before or after the processes for the wafer 22, in addition to the transfer of the wafer 23, the multiple-chamber semiconductor serial constructing apparatus 1a may be further used to transfer other wafers to perform the corresponding processes on the other wafers, and the multiple-chamber semiconductor serial constructing apparatus 1a is not particularly limited to only transfer the wafers 22, 23 at the same time.

In FIG. 31, regardless of the transfer sequence of the wafer 22, the pressure P14 (as shown in FIG. 1D) of the third load-lock chamber 141 is adjusted to, for example, any pressure less than or equal to 1×10⁻² torr (e.g., 5×10⁻⁴ torr); the valve V9 is opened; and the first vacuum-transfer robot 112 is actuated to transfer the wafer 23 to the interior of the third load-lock chamber 141. The valve V9 is closed.

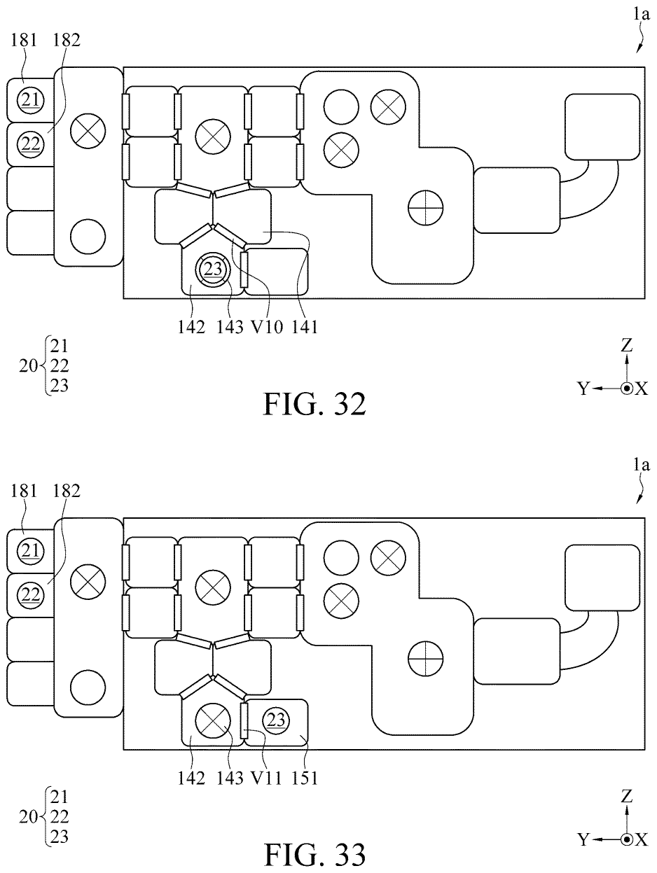

In FIG. 32, the pressure P14′ (as shown in FIG. 1D) of the third vacuum-transfer chamber 142 and the pressure P14 (as shown in FIG. 1D) of the third load-lock chamber 141 may be both maintained at, for example, any pressure less than or equal to 1×10⁻² torr (e.g., 5×10⁻⁴ torr). The valve V10 is opened, and the third vacuum-transfer robot 143 of the third load-lock module 14 is actuated to pick the wafer 23 placed in the third load-lock chamber 141 to transfer the wafer 23 to the interior of the third vacuum-transfer chamber 142. The valve V10 is closed.

In FIG. 33, the valve V11 is opened, and the third vacuum-transfer robot 143 is actuated to transfer the wafer 23 to the interior of the second process-transfer chamber 151. The valve V11 is closed. The pressure P15 (as shown in FIG. 1D) of the second process-transfer chamber 151 and the pressure P14′ (as shown in FIG. 1D) of the third vacuum-transfer chamber 142 may be both maintained at, for example, any pressure less than or equal to 1×10⁻² torr (e.g., 5×10⁻⁴ torr). Next, the pressure P15 of the second process-transfer chamber 151 is further adjusted (for example, adjusted to 5 torr) to perform the process corresponding to the second process-transfer module 15, for example, the plasma-treatment process, on the wafer 23.

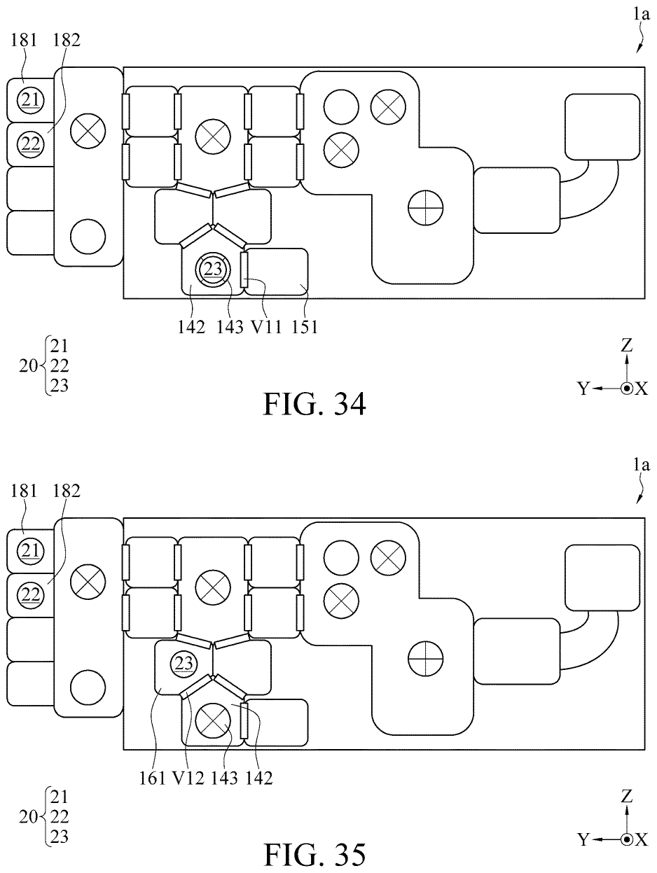

In FIG. 34, after the process of the wafer 23 performed in the second process-transfer module 15 (e.g., the plasma-treatment process) is completed, the pressure P15 (as shown in FIG. 1D) of the second process-transfer chamber 151 is adjusted to, for example, any pressure less than or equal to 1×10⁻² torr (e.g., 5×10⁻⁴ torr). The valve V11 is opened, and the third vacuum-transfer robot 143 is actuated to pick the wafer 23 placed in the second process-transfer chamber 151 to transfer the wafer 23 to the interior of the third vacuum-transfer chamber 142. The valve V11 is closed. The pressure P14′ (as shown in FIG. 1D) of the third vacuum-transfer chamber 142 and the pressure P15 of the second process-transfer chamber 151 may be both maintained at, for example, any pressure less than or equal to 1×10⁻² torr (e.g., 5×10⁻⁴ torr).

In FIG. 35, the valve V12 is opened, and the third vacuum-transfer robot 143 is actuated to transfer the wafer 23 to the interior of the third process-transfer chamber 161. The valve V12 is closed. The pressure P16 (as shown in FIG. 1D) of the third process-transfer chamber 161 and the pressure P14′ (as shown in FIG. 1D) of the third vacuum-transfer chamber 142 may be both maintained at, for example, any pressure less than or equal to 1×10⁻² torr (e.g., 5×10⁻⁴ torr). Next, the pressure P14′ of the third vacuum-transfer chamber 142 is further adjusted to, for example, any pressure within a range from 5×10⁻⁴ torr to 5 torr to perform the process corresponding to the third process-transfer module 16, for example, the post-treatment process, on the wafer 23.

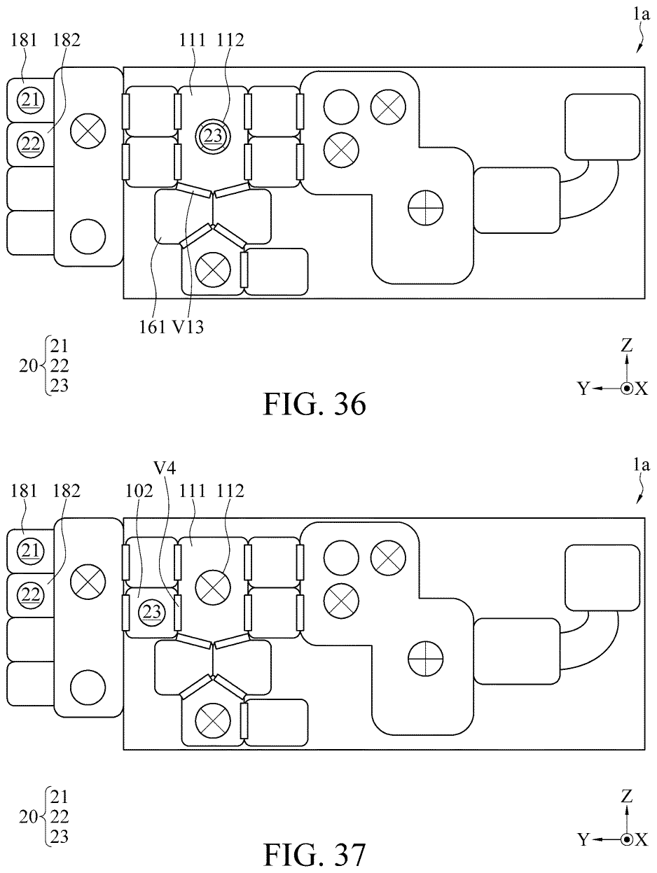

In FIG. 36, after the process of the wafer 23 performed in the third process-transfer module 16 (e.g., the post-treatment process) is completed, the pressure P16 (as shown in FIG. 1D) of the third process-transfer chamber 161 is adjusted to, for example, any pressure less than or equal to 1×10⁻² torr to maintain the pressure P16 the same as the pressure P11 (as shown in FIG. 1D; for example, any pressure less than or equal to 1×10⁻² torr) of the first vacuum-transfer chamber 111. The valve V13 is opened, and the first vacuum-transfer robot 112 is actuated to pick the wafer 23 placed in the third process-transfer chamber 161 to transfer the wafer 23 to the interior of the first vacuum-transfer chamber 111. The valve V13 is closed. The pressure P16 of the third process-transfer chamber 161 and the pressure P11 of the first vacuum-transfer chamber 111 may be maintained at, for example, any pressure less than or equal to 1×10⁻² torr.

In FIG. 37, before the valve V4 is opened, the pressure P10′ (as shown in FIG. 1D) of the first load-lock chamber 102 is adjusted to ensure that the pressure P10′ is the same as the pressure P11 (as shown in FIG. 1D; for example, any pressure less than or equal to 1×10⁻² torr (e.g., 5×10⁻⁴ torr)) of the first vacuum-transfer chamber 111. The valve V4 is opened, and the first vacuum-transfer robot 112 is actuated to transfer the wafer 23 to the interior of the first load-lock chamber 102. The valve V4 is closed.

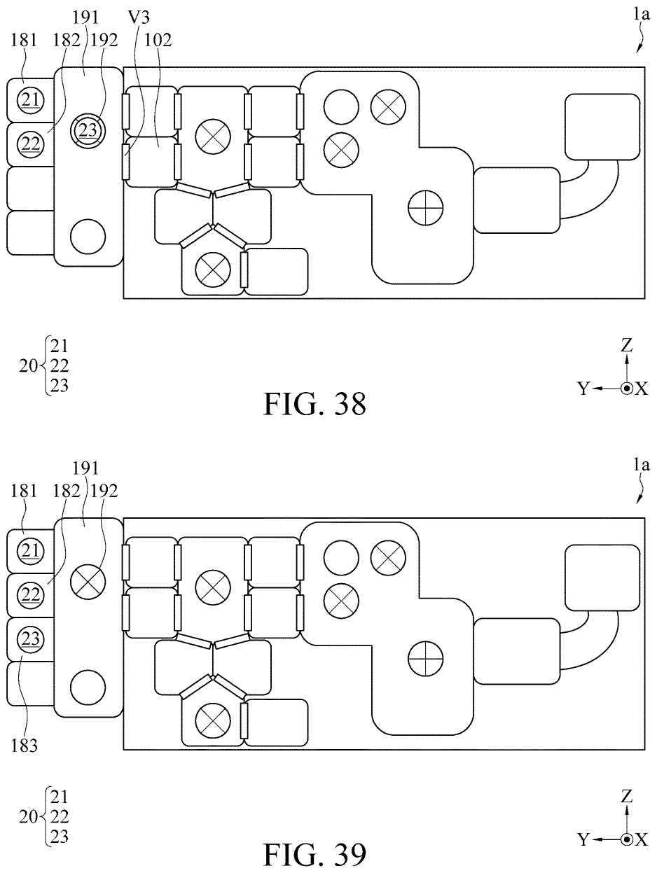

In FIG. 38, before the valve V3 is opened, the pressure P10′ (as shown in FIG. 1D) of the first load-lock chamber 102 is adjusted to ensure that the pressure P10′ is the same as the pressure P19 (as shown in FIG. 1D; for example, 760 torr) of the equipment front end chamber 191. The valve V3 is opened, and the equipment front end robot 192 is actuated to pick the wafer 23 placed in the first load-lock chamber 102 to transfer the wafer 23 to the interior of the equipment front end chamber 191. The valve V3 is closed. The pressure P19 of the equipment front end chamber 191 and the pressure P10′ of the first load-lock chamber 102 may be both maintained at, for example, 760 torr.

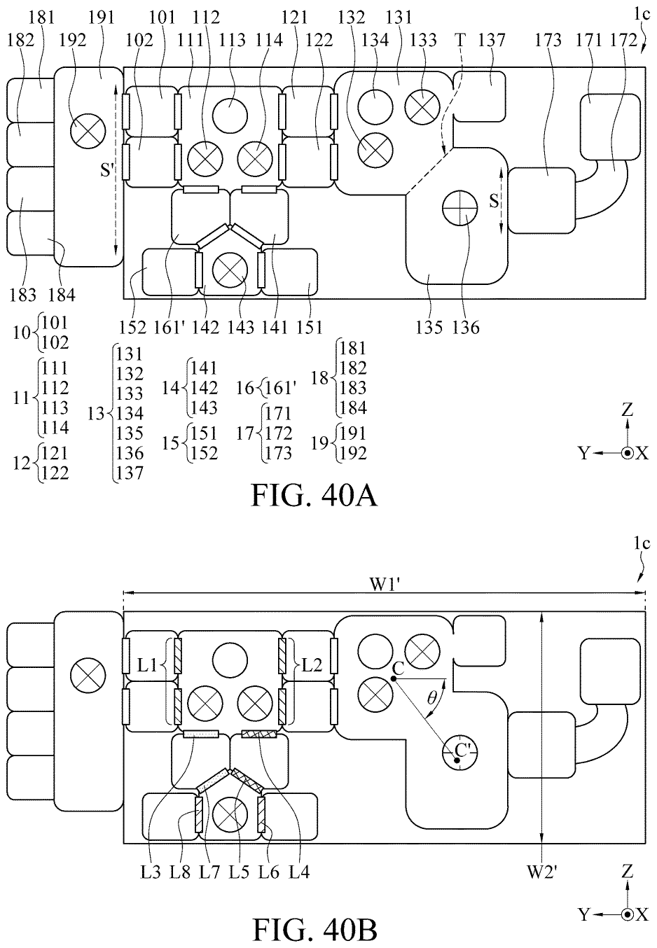

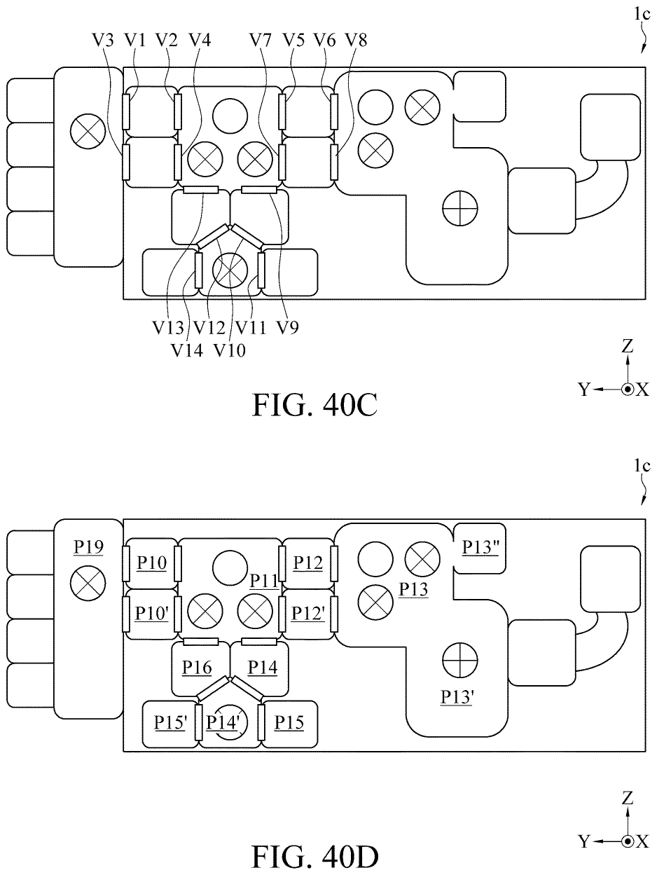

In FIG. 39, the equipment front end robot 192 is actuated to transfer the wafer 23 to the interior of the front opening unified pod 183. At this moment, the processes for the wafer 23 (comprising the ion implantation process, the plasma-treatment process, and the post-treatment process, for example) may be completed. Simultaneously, or before or after the processes for the wafer 23, the multiple-chamber semiconductor serial constructing apparatus 1a may be further used to transfer other wafers to perform the corresponding processes on the other wafers, and the multiple-chamber semiconductor serial constructing apparatus 1a is not particularly limited to only transfer the wafer 23 at the same time.

Accordingly, even though the pressure of each chamber needs to be changed during the transfer of the component(s) to be transferred 2 (e.g., the wafers 21-23), in some embodiments, only the pressure of some chambers having relatively smaller volumes (e.g., the aforementioned first load-lock chamber 101 and third load-lock chamber 141) needs to be regulated to reach a pressure balance between the pressure thereof and the pressure of the other chambers that are coupled with the chambers having relatively smaller volumes so as to perform the sequential processes, so that it is not necessary to spend time on reaching a pressure balance between the pressures of the chambers having relatively larger volumes. Therefore, in some embodiments, the entire process time can be efficiently reduced, thereby reducing the process cost and avoiding the component(s) to be transferred 2 being adversely affected by surface contaminants in the existing process.

Please refer to FIG. 1A and FIG. 40A. FIG. 40A illustrates a schematic view of a multiple-chamber semiconductor serial constructing apparatus 1c according to a third embodiment. Compared with the multiple-chamber semiconductor serial constructing apparatus 1a shown in FIG. 1A, the major differences of the multiple-chamber semiconductor serial constructing apparatus 1c are, for example, the first process-transfer module 13 of the multiple-chamber semiconductor serial constructing apparatus 1c further comprises a heating chamber 137 coupled with the second vacuum-transfer chamber 131; the second process-transfer module 15 comprises two second process-transfer chambers 151, 152 coupled with two opposite sides of the third vacuum-transfer module 142 (i.e., the sixth side L6 and the eighth side L8 as shown in FIG. 40B); and the third process-transfer module 16 comprises a fourth load-lock chamber 161′ (i.e., replacing the third process-transfer chamber 161 as shown in FIG. 1A with the fourth load-lock chamber 161′ as shown in FIG. 40A). The heating chamber 137 is configured to perform at least one of the processes of heating, holding temperature, and cooling.

The process performed in the second process-transfer chamber 151 (or the second process-transfer chamber 152) may be adjusted according to various needs or according to the process performed in the second process-transfer chamber 152 (or the second process-transfer chamber 151); for example, the second process-transfer chamber 151 is configured to perform a plasma-treatment process, and the second process-transfer chamber 152 is configured to performed another plasma-treatment process; or for another example, the second process-transfer chamber 151 is configured to perform an etching process, and the second process-transfer chamber 152 is configured to performed another etching process; or for another example, the second process-transfer chamber 151 is configured to perform a plasma-treatment process, and the second process-transfer chamber 152 is configured to performed an etching process; or for another example, the second process-transfer chamber 151 is configured to perform an etching process, and the second process-transfer chamber 152 is configured to performed a plasma-treatment process. In other words, the second process-transfer chambers 151, 152 may be configured to perform the processes that are identical to or different from each other.

Embodiments of the first vacuum-transfer module 11, the first load-lock module 10, the second load-lock module 12, the first process-transfer module 13, the third load-lock module 14, the second process-transfer module 15, the third process-transfer module 16, and the ion implantation assembly 17 of the multiple-chamber semiconductor serial constructing apparatus 1c may be referred to the aforementioned embodiments regarding the multiple-chamber semiconductor serial constructing apparatus 1a, which is not further described in detail herein.

Therefore, in some embodiments, through the arrangement of the heating chamber 137 and the two second process-transfer chambers 151, 152, the component(s) to be transferred 2 that is transferred in the first process-transfer module 13 may further be selectively subjected to the heating process of the heating chamber 137 and the etching process and/or the post-treatment process of the second process-transfer chambers 151, 152, so that more processes with different types and sequences according to various requirements may be completed in the same one multiple-chamber semiconductor serial constructing apparatus 1c, and thus the existing and space-constrained multiple-chamber semiconductor serial constructing apparatus 1c can be used more sufficiently.

Please refer to FIG. 40B. FIG. 40B illustrates a schematic view of a multiple-chamber semiconductor serial constructing apparatus 1c according to a third embodiment. The third vacuum-transfer chamber 142 is configured as a pentagonal chamber, and the pentagonal chamber may be a chamber enclosed by, in sequence, the seventh side L7, the fifth side L5, the sixth side L6, another side (not additionally denoted), and the eighth side L8 that are adjacent to each other with the another side adjacent to the eighth side L8. At least four sides of the pentagonal chamber may be used to couple with the third vacuum-transfer chamber 142 and the chambers of other modules. For example, referring to FIG. 40C, FIG. 40C illustrates a schematic view of a multiple-chamber semiconductor serial constructing apparatus 1c according to a third embodiment; as shown in FIG. 40A to FIG. 40C, the third vacuum-transfer chamber 142 and the third load-lock chamber 141 may be selectively in communication with or not in communication with each other through the fifth side L5 and the valve V10; the third vacuum-transfer chamber 142 and the second process-transfer chamber 151 of the second process-transfer module 15 may be selectively in communication with or not in communication with each other through the sixth side L6 and the valve V11; the third vacuum-transfer chamber 142 and the second process-transfer chamber 152 of the second process-transfer module 15 may be selectively in communication with or not in communication with each other through the eighth side L8 and the valve V14; and the third vacuum-transfer chamber 142 and the third process-transfer module 16 (or its fourth load-lock chamber 161′) may be selectively in communication with or not in communication with each other through the seventh side L7 and the valve V12.

Please refer to FIG. 40 A and FIG. 40D. FIG. 40D illustrates a schematic view of a multiple-chamber semiconductor serial constructing apparatus 1c according to a third embodiment. In some embodiments, as shown in FIG. 40A and FIG. 40D, according to various process requirements, the pressures P15, P15′ of the second process-transfer chambers 151, 152 may be independently maintained at a certain pressure or within the tolerable range thereof (e.g., within ±5% of the certain pressure); for example, the pressures P15, P15′ of the second process-transfer chambers 151, 152 may independently be any pressure within a range from 5×10⁻⁴ torr to 5 torr.

Please refer to FIG. 40A and FIG. 40D. The heating chamber 137 is normally in communication with the second vacuum-transfer chamber 131. In some embodiments, as shown in FIG. 40A and FIG. 40D, according to various process requirements, the pressure P13″ of the heating chamber 137 may be maintained at a certain pressure or within the tolerable range thereof (e.g., within ±5% of the certain pressure), for example, maintained at any pressure within a range from 1×10⁻⁷ torr to 2×10⁻⁵ torr. In some embodiments, the pressure P13″ of the heating chamber 137 is normally the same as the pressures P13, P13′ of the second vacuum-transfer chamber 131 and the first process-transfer chamber 135; for example, all are maintained at any pressure within a range from 1×10⁻⁷ torr to 2×10⁻⁵ torr.

In some embodiments, as shown in FIG. 40A, in addition to the first vacuum-transfer robot 112, the first vacuum-transfer module 11 further comprises a first vacuum-transfer aligner 113 and another first vacuum-transfer robot 114; the first vacuum-transfer robots 112, 114 are disposed in the first vacuum-transfer chamber 111 and respectively adjacent to the first load-lock module 10 and the second load-lock module 12; each of the first vacuum-transfer robots 112, 114 is configured to transfer one or more components to be transferred 2 (e.g., the wafers 21-23 as shown in FIG. 44 to FIG. 46, which will be described in detail later) among the first vacuum-transfer chamber 111 and the other chambers coupled with the first vacuum-transfer chamber 111; the first vacuum-transfer aligner 113 is disposed in the first vacuum-transfer chamber 111 and between the two first vacuum-transfer robots 112, 114 to hold the component(s) to be transferred 2 that is transferred by the first vacuum-transfer robots 112, 114 and to further perform the alignment process on the component(s) to be transferred 2.

In some embodiments, as shown in FIG. 40A, the first vacuum-transfer robots 112, 114 are independently configured to transfer the component(s) to be transferred 2 (e.g., the wafers 21-23 as shown in FIG. 44 to FIG. 46) to the first vacuum-transfer aligner 113, or to pick the component(s) to be transferred 2 placed in the first vacuum-transfer aligner 113, to further transfer the component(s) to be transferred 2 to at least one of the first load-lock module 10, the second load-lock module 12, the third load-lock module 14, and the third process-transfer module 16.

For example, as shown in FIG. 40A and FIG. 40D, the first vacuum-transfer robot 112 may be used to transfer the component(s) to be transferred 2 (e.g., the wafers 21-23 as shown in FIG. 44 to FIG. 46) from the first load-lock chambers 101, 102 to the interior of the first vacuum-transfer chamber 111 (e.g., transferred onto the first vacuum-transfer aligner 113 of the first vacuum-transfer chamber 111), from the first vacuum-transfer chamber 111 to the interior of the first load-lock chambers 101, 102, from the fourth load-lock chamber 161′ to the interior of the first vacuum-transfer chamber 111, or from the first vacuum-transfer chamber 111 to the interior of the fourth load-lock chamber 161′.

For another example, as shown in FIG. 40A and FIG. 40D, the first vacuum-transfer robot 114 may be used to transfer the component(s) to be transferred 2 (e.g., the wafers 21-23 as shown in FIG. 44 to FIG. 46) from the first vacuum-transfer aligner 113 of the first vacuum-transfer chamber 111 to the interiors of the second load-lock chambers 121, 122 (or from the second load-lock chambers 121, 122 to the interior of the first vacuum-transfer chamber 111), or from the first vacuum-transfer chamber 111 to the interior of the third load-lock chamber 141 (or from the third load-lock chamber 141 to the interior of the first vacuum-transfer chamber 111).

Accordingly, in some embodiments, the multiple-chamber semiconductor serial constructing apparatus 1c may perform at least one of the ion implantation process, the plasma-treatment process, and the etching process. For example, the multiple-chamber semiconductor serial constructing apparatus 1c may perform one kind of process, e.g., one or more ion implantation processes (referred to as process A); the multiple-chamber semiconductor serial constructing apparatus 1c may perform one kind of process, e.g., one or more plasma-treatment processes (referred to as process B); the multiple-chamber semiconductor serial constructing apparatus 1c may perform one kind of process, e.g., one or more etching processes (referred to as process C); the multiple-chamber semiconductor serial constructing apparatus 1c may perform two kinds of processes, e.g., one or more ion implantation processes and one or more plasma-treatment processes (referred to as processes A+B in sequence, or processes B+A in sequence); the multiple-chamber semiconductor serial constructing apparatus 1c may perform two kinds of processes, e.g., one or more ion implantation processes and one or more etching processes (referred to as processes A+C in sequence, or processes C+A in sequence); the multiple-chamber semiconductor serial constructing apparatus 1c may perform three kinds of processes, e.g., one or more ion implantation processes, one or more plasma-treatment processes, and one or more etching processes (referred to as processes A+B+C in sequence, or processes C+B+A in sequence, for example); and the processes A, B, and C may be performed by any times and any sequence in accordance with different process requirements; for example, at least one kind of the processes can be repeatedly performed, for example, processes B+A+B in sequence.

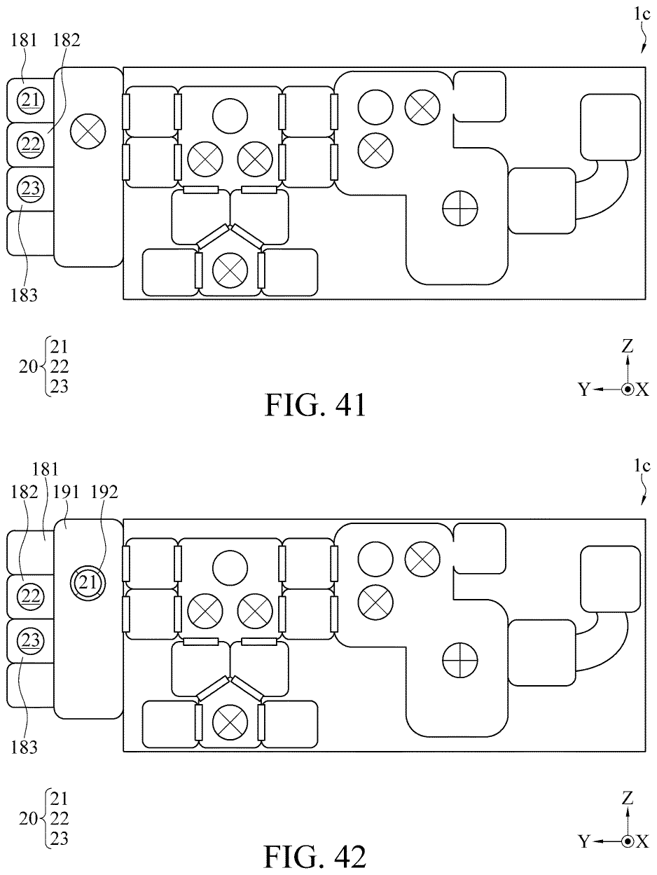

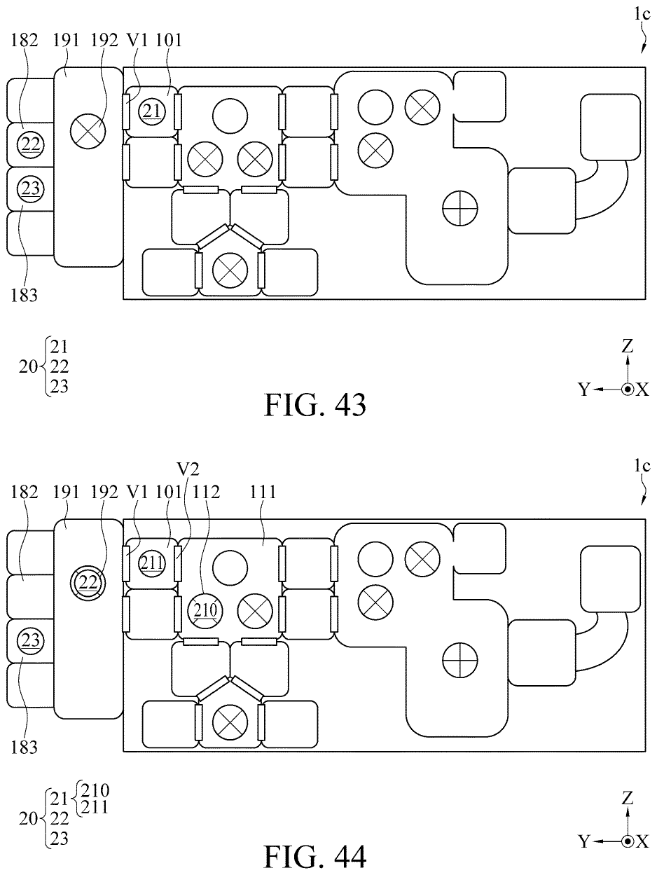

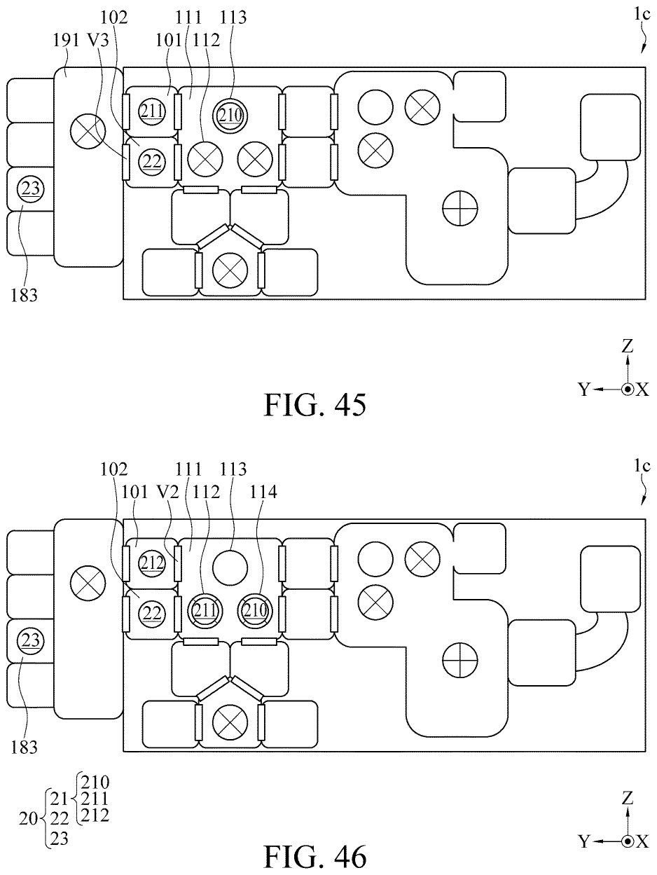

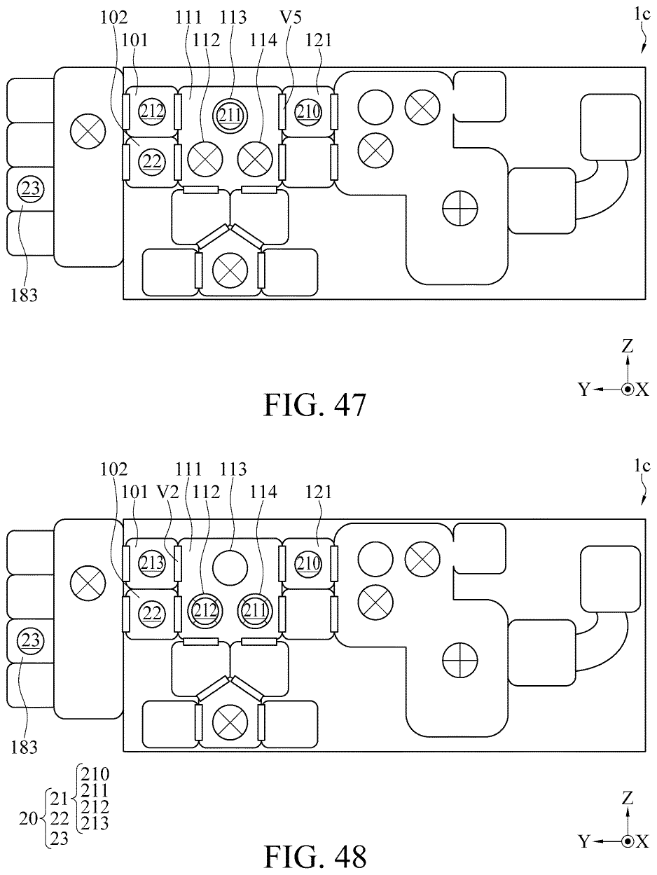

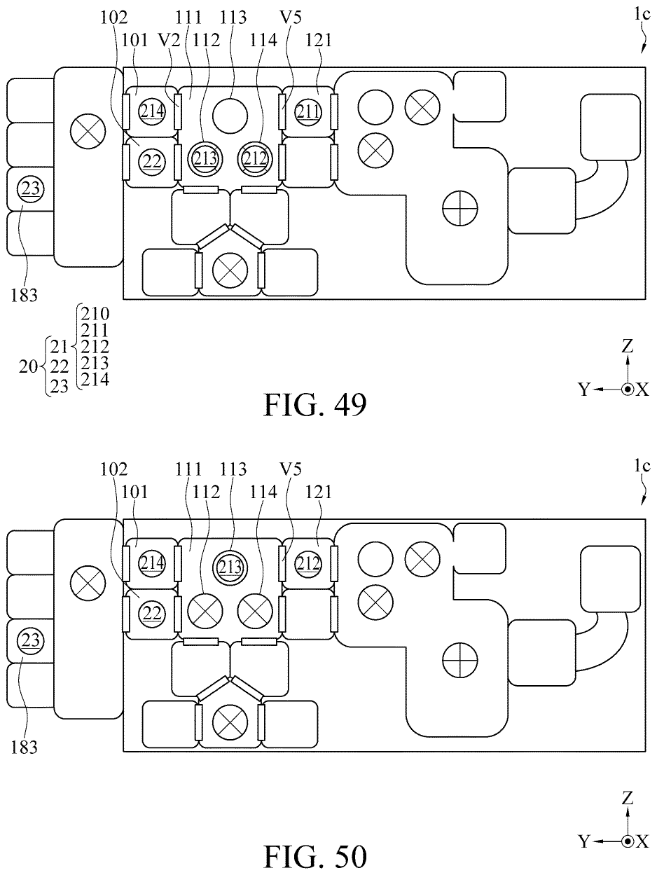

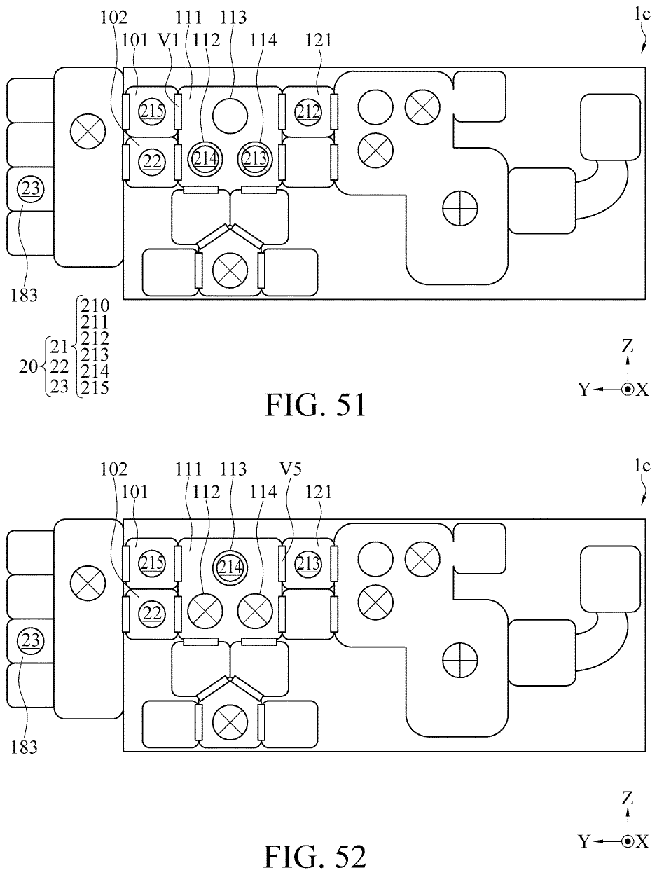

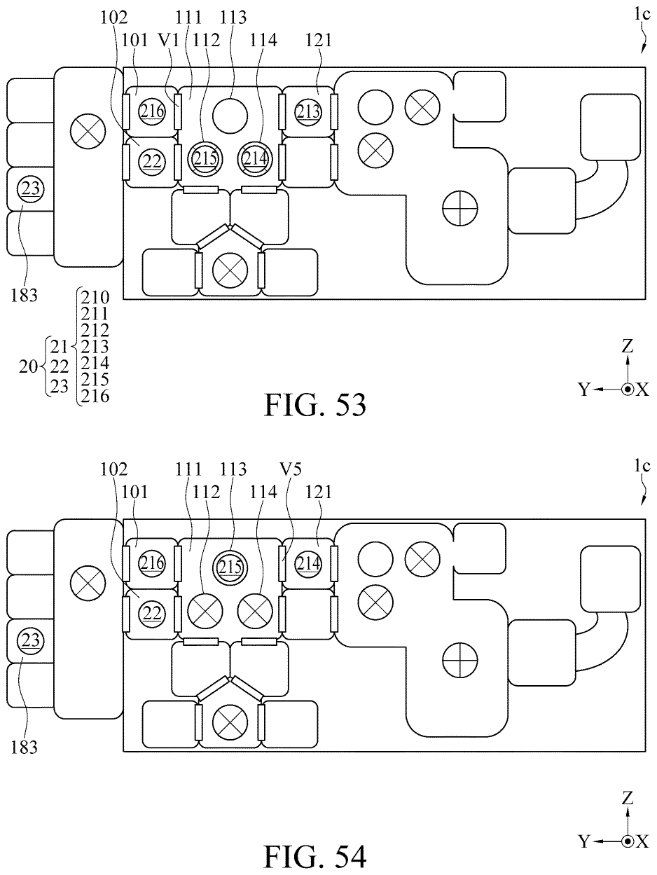

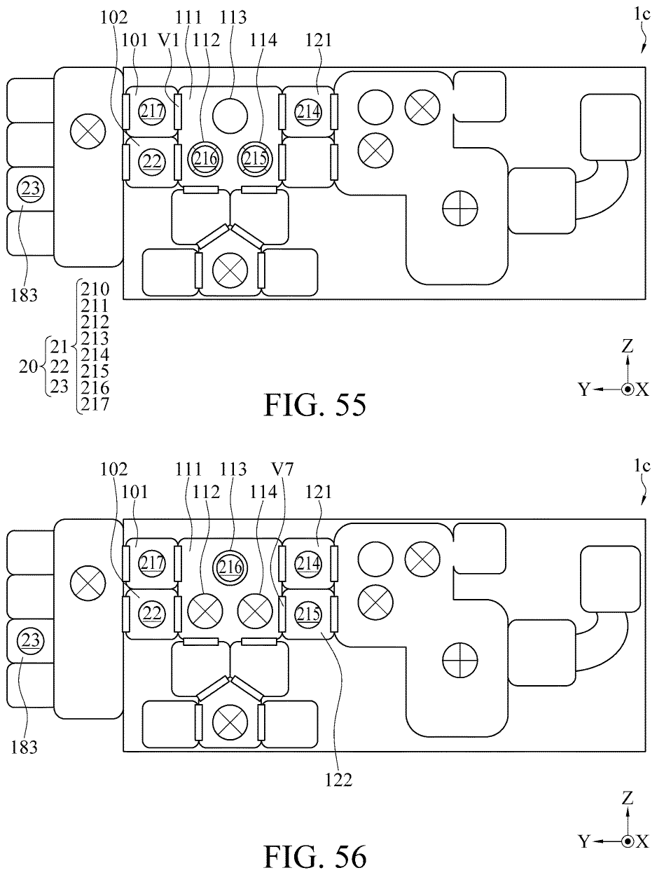

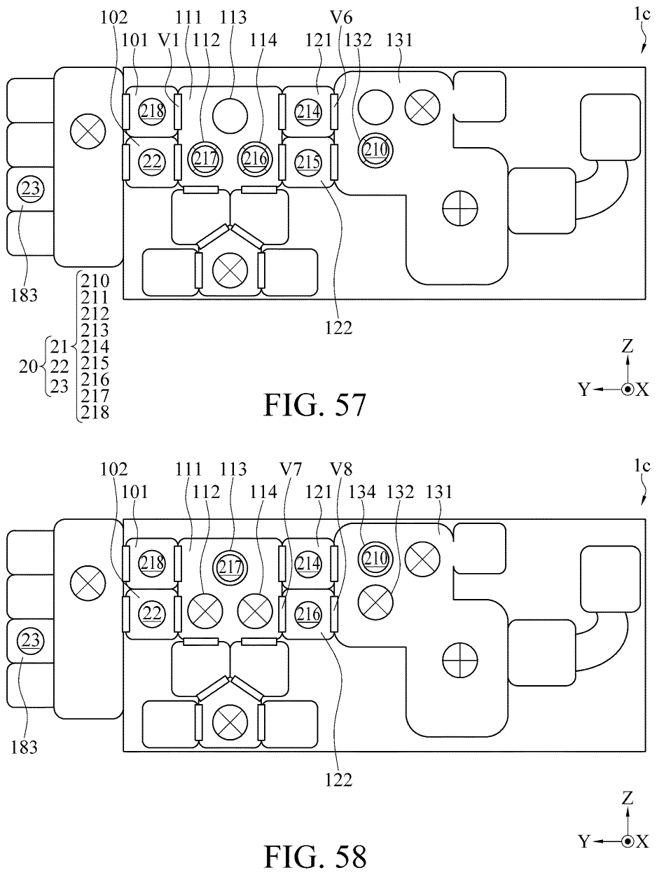

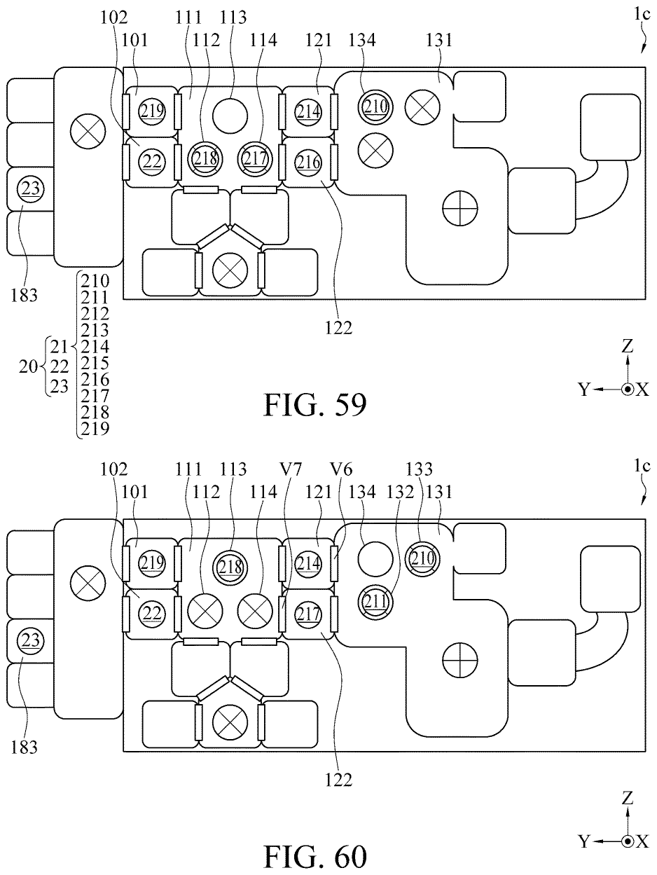

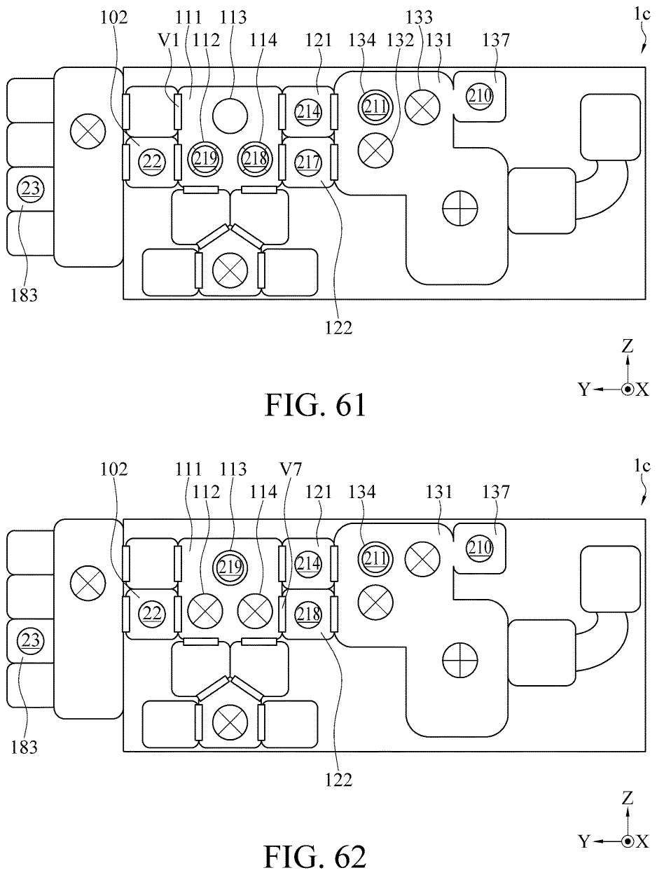

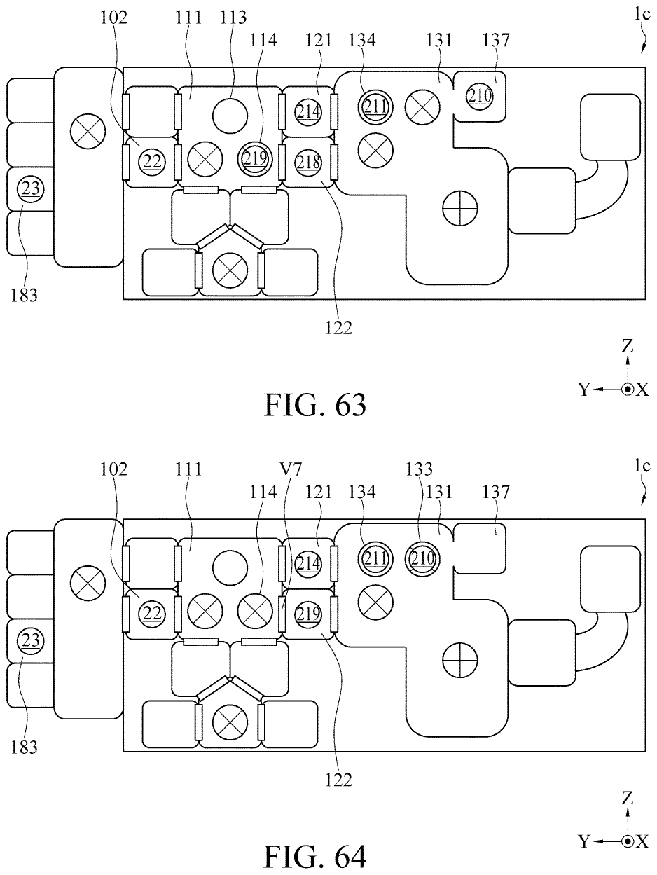

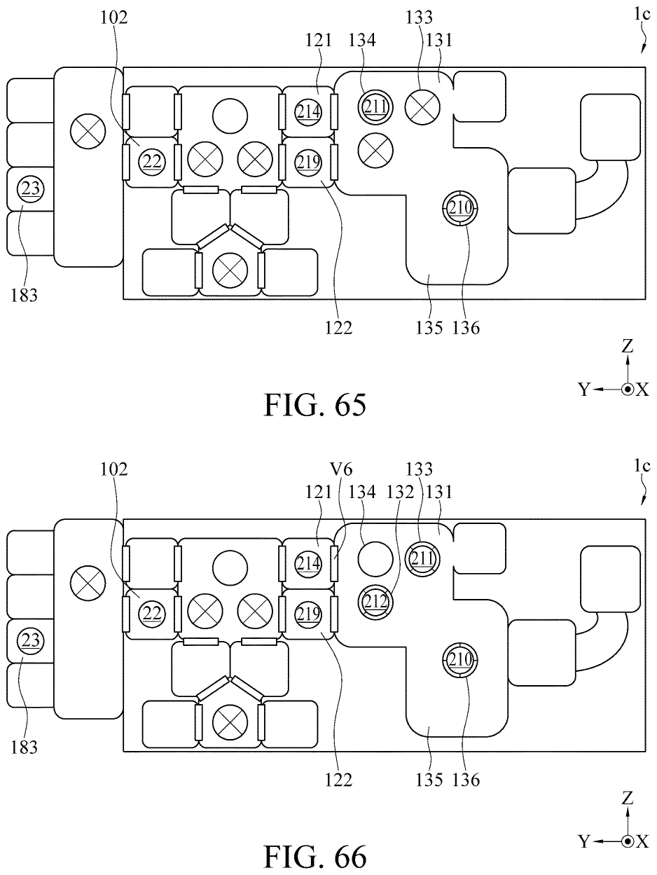

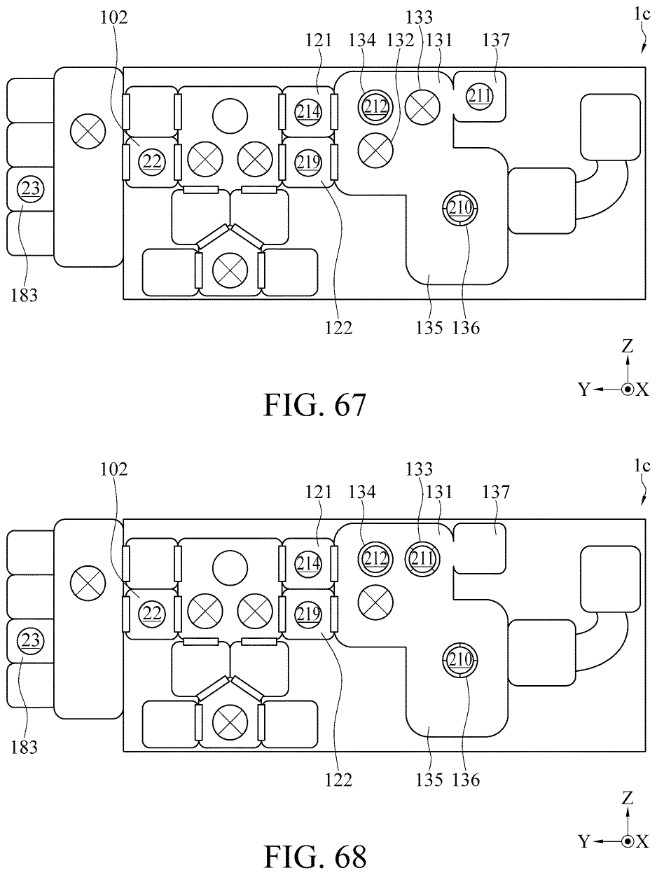

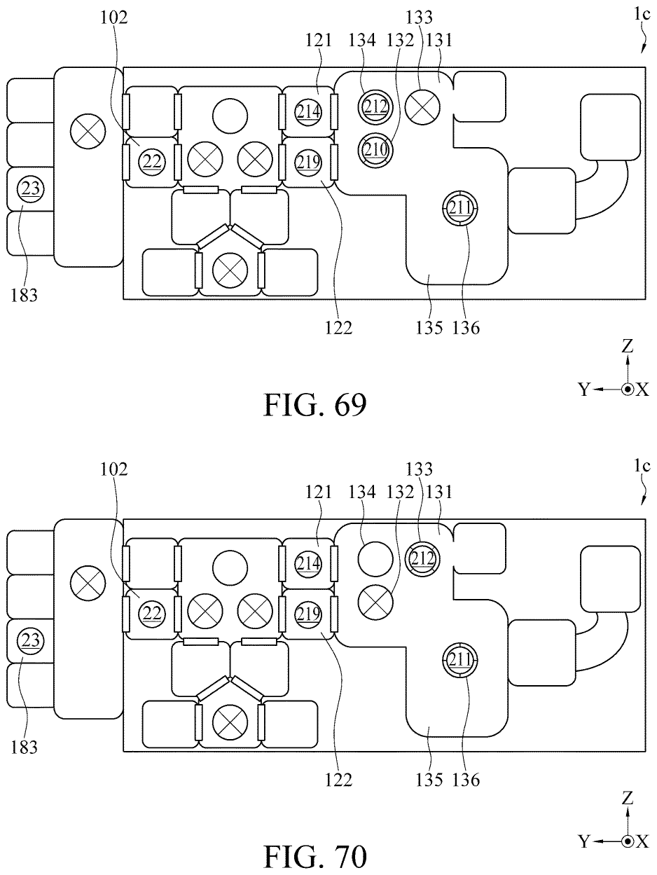

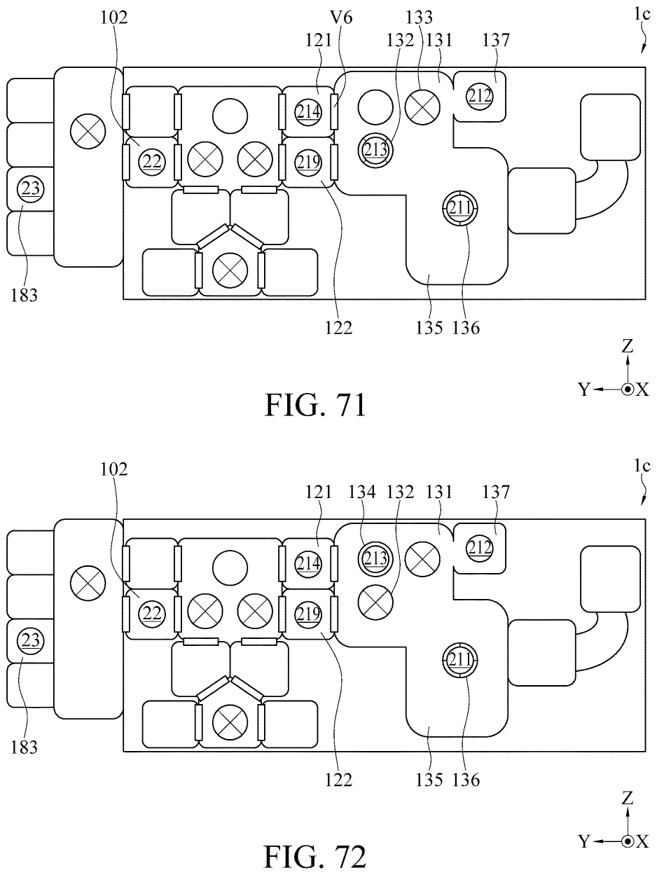

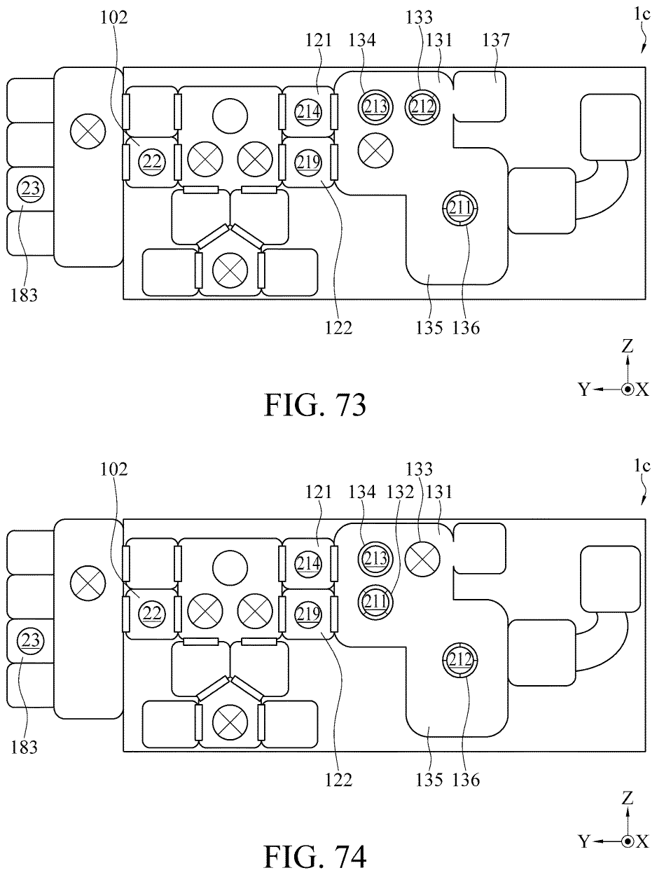

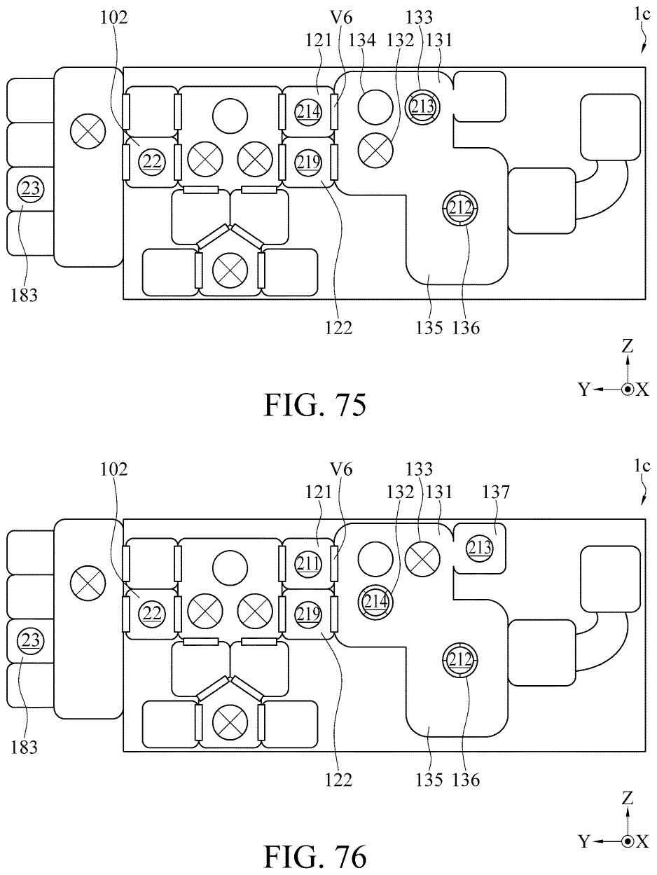

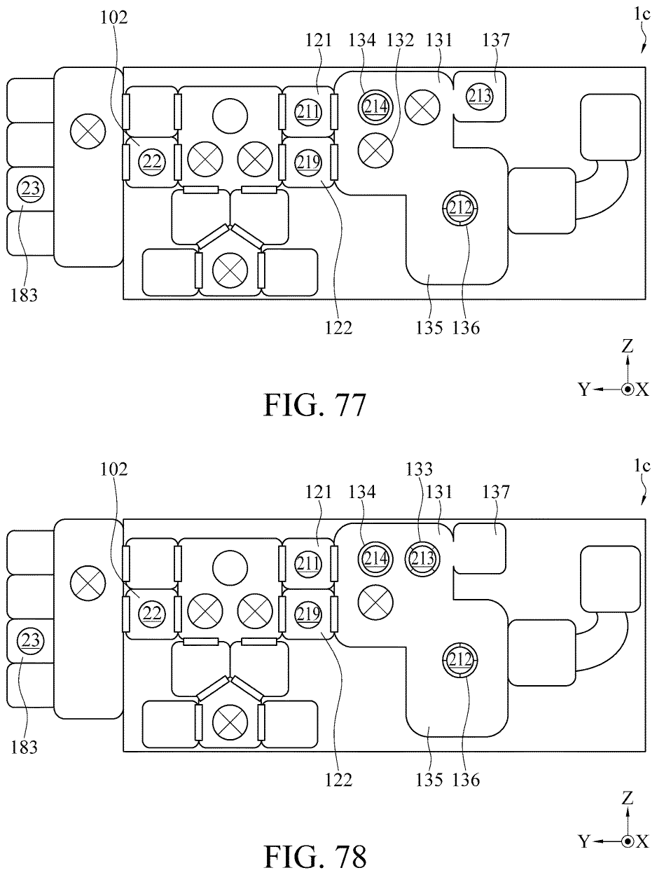

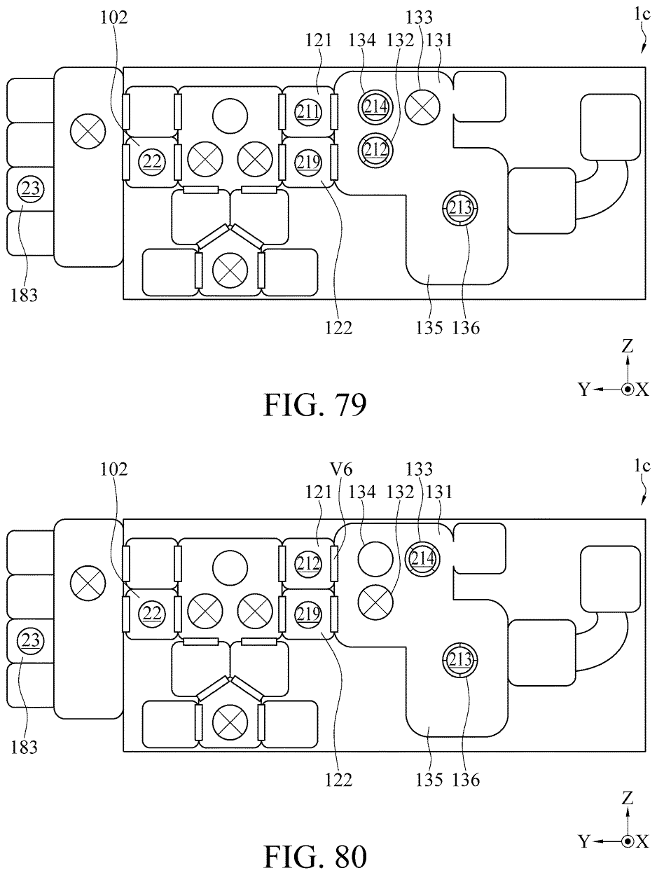

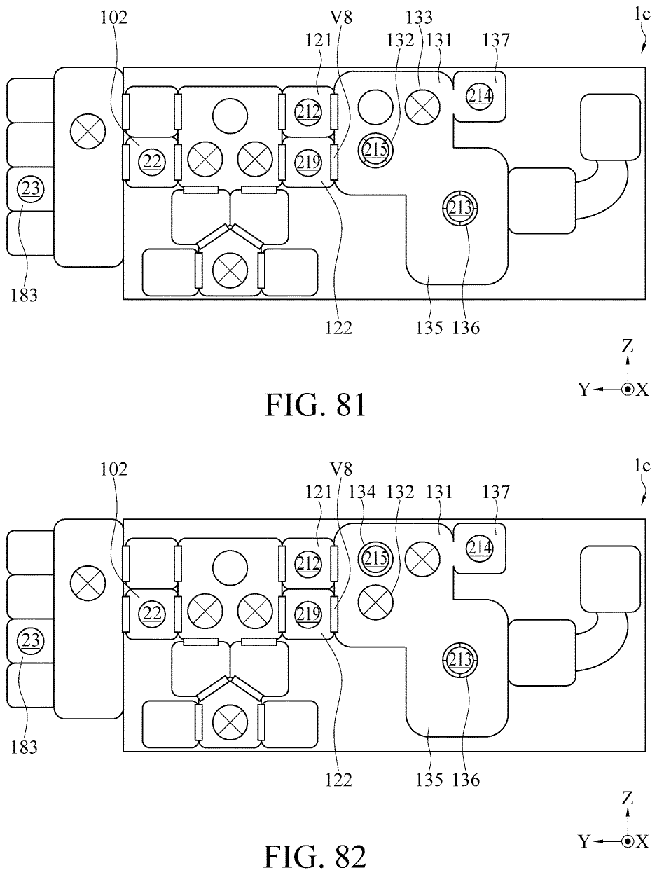

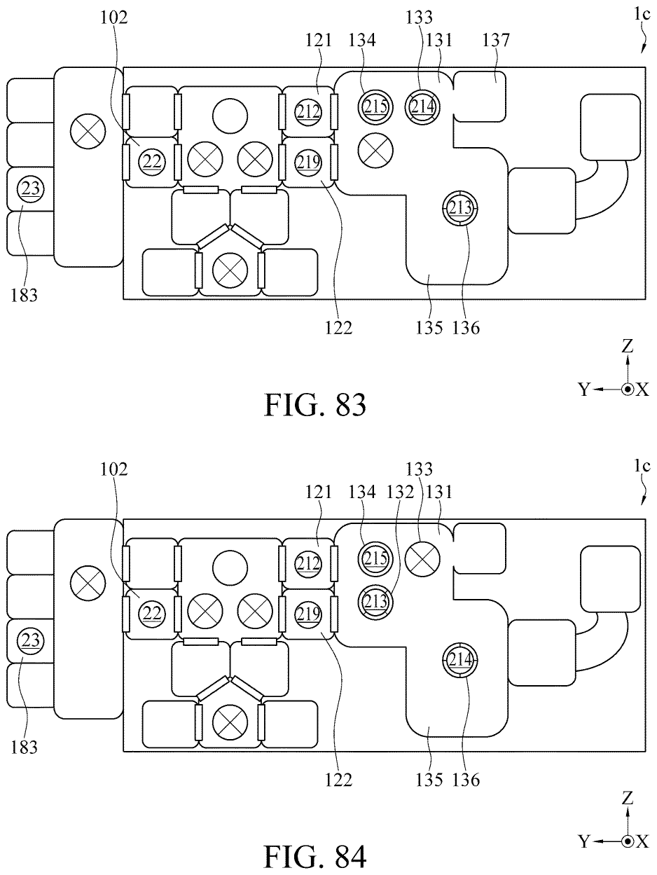

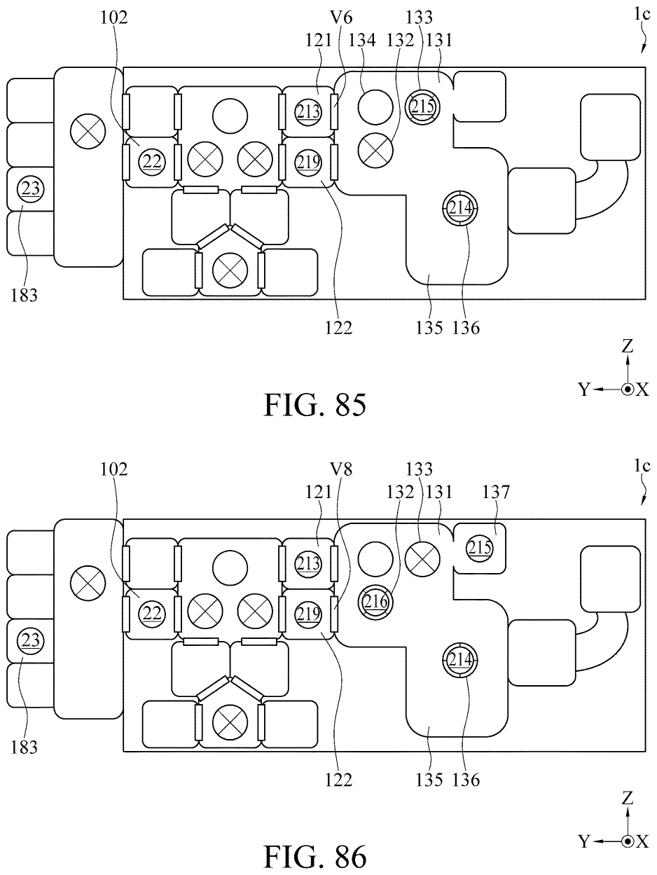

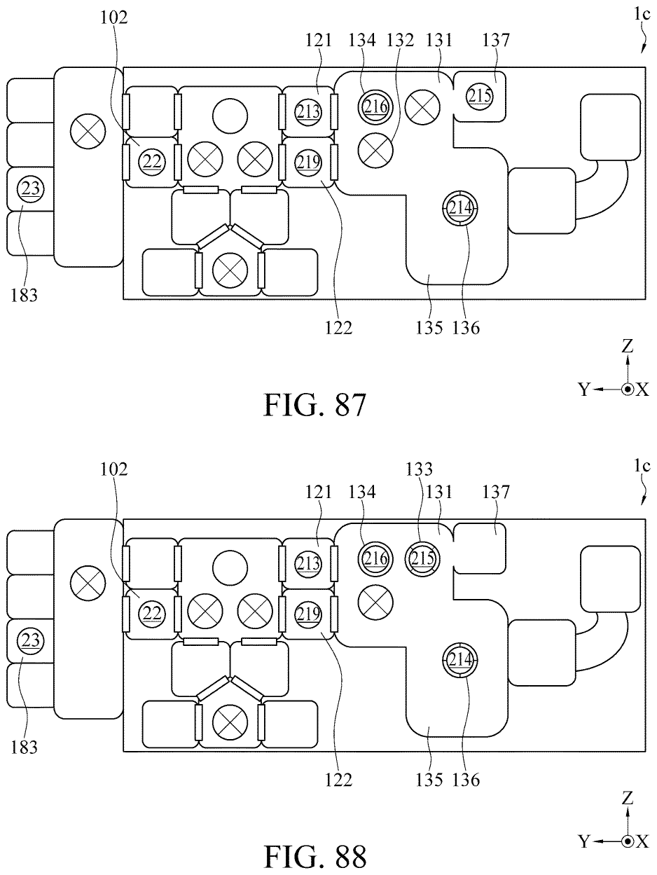

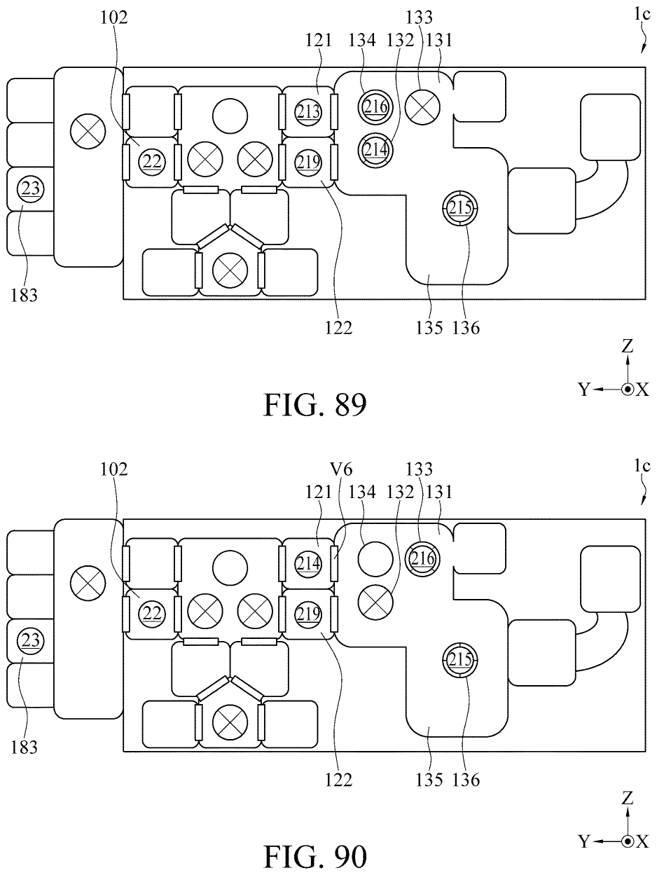

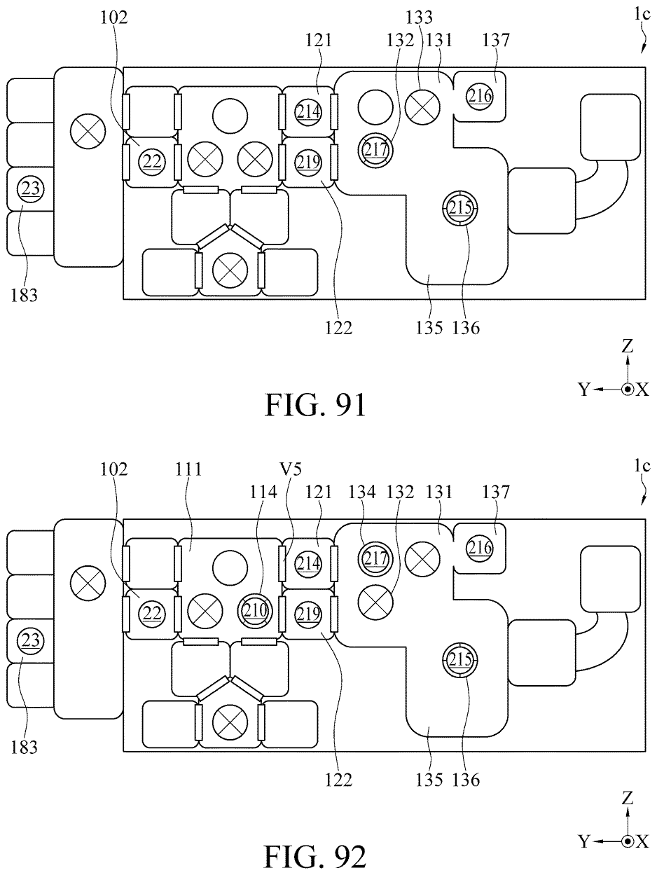

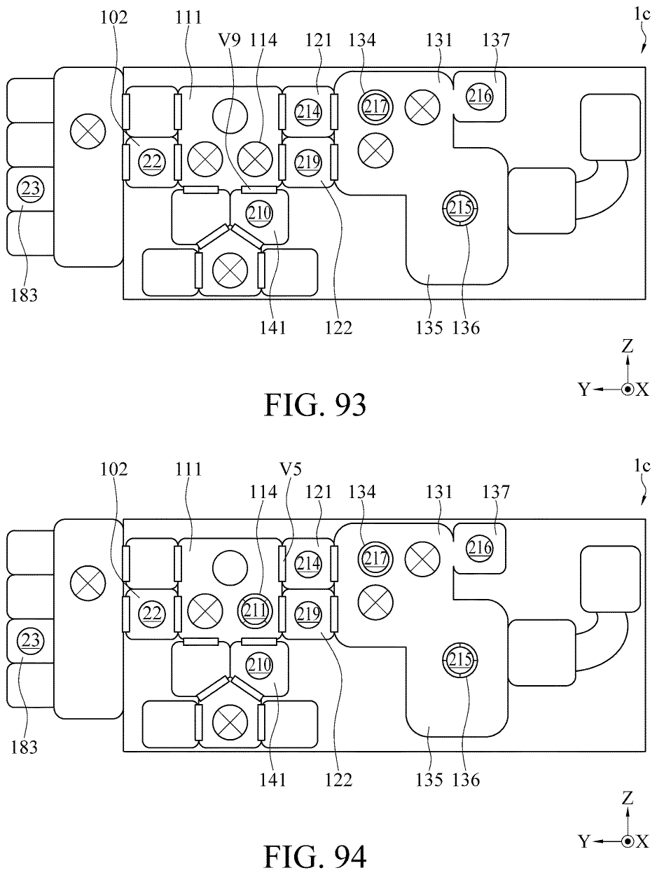

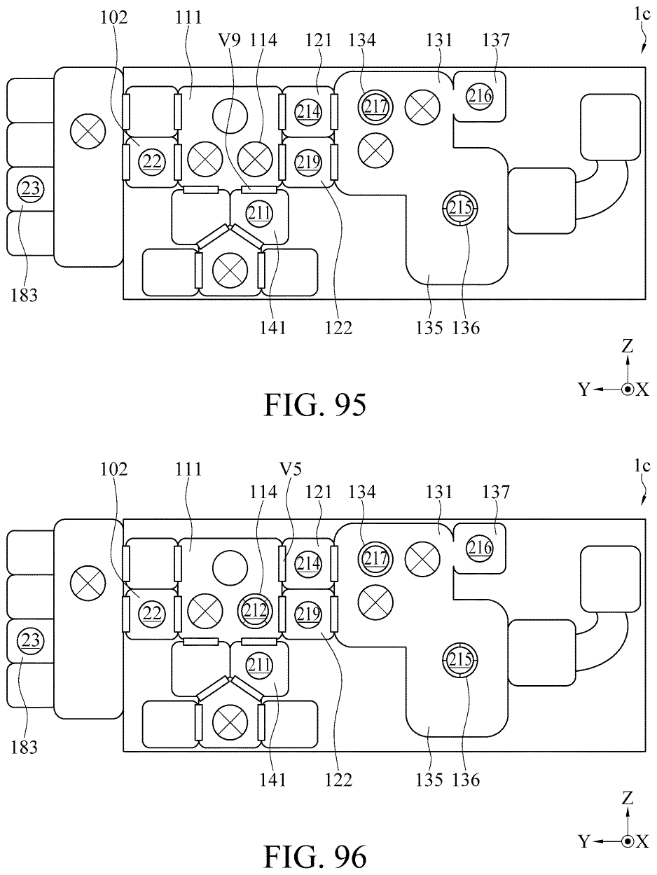

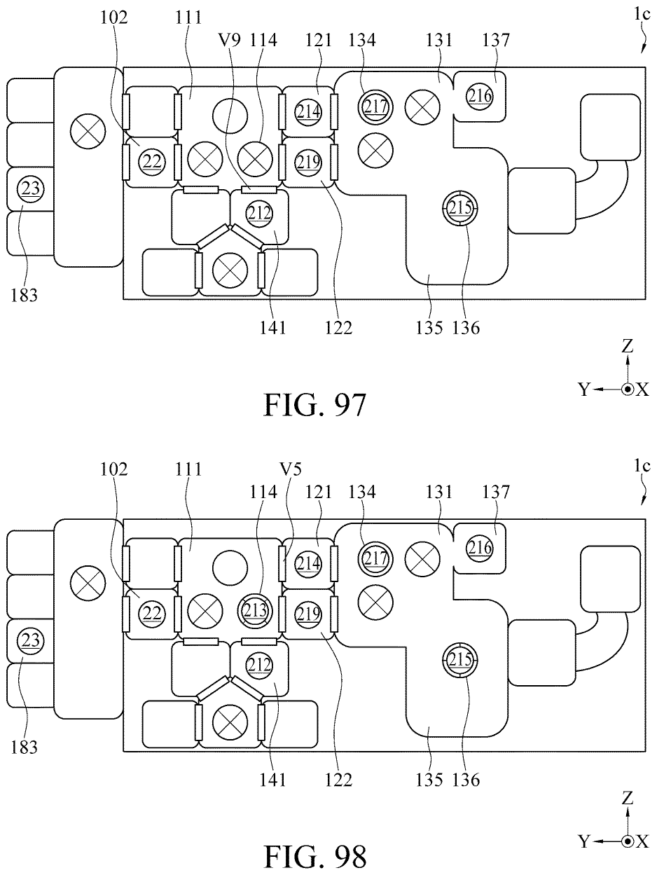

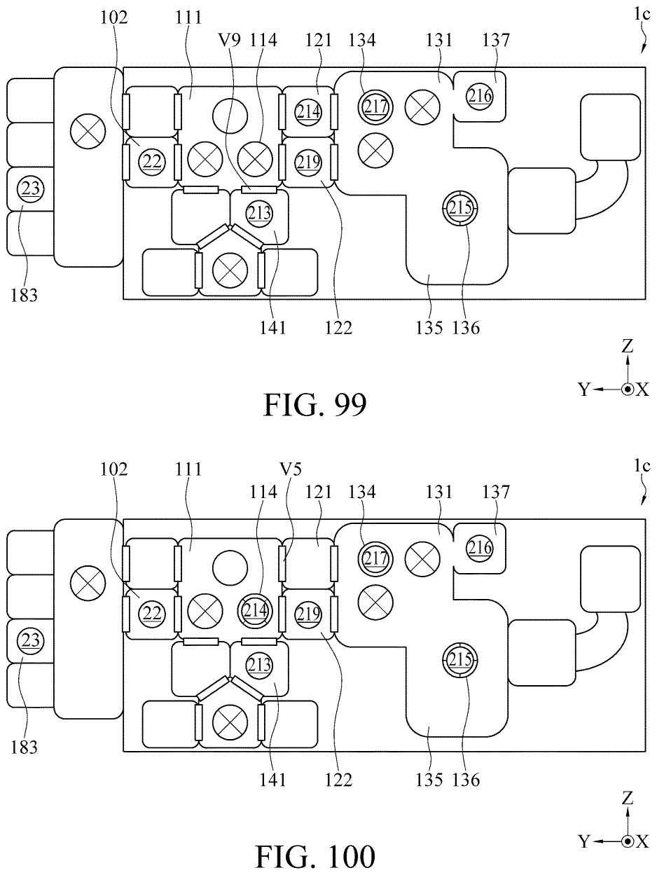

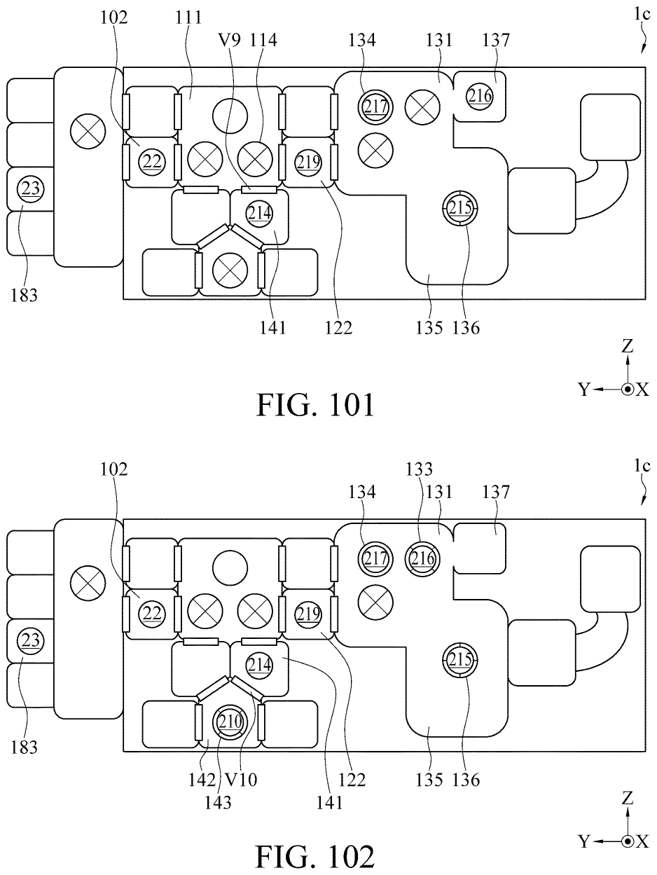

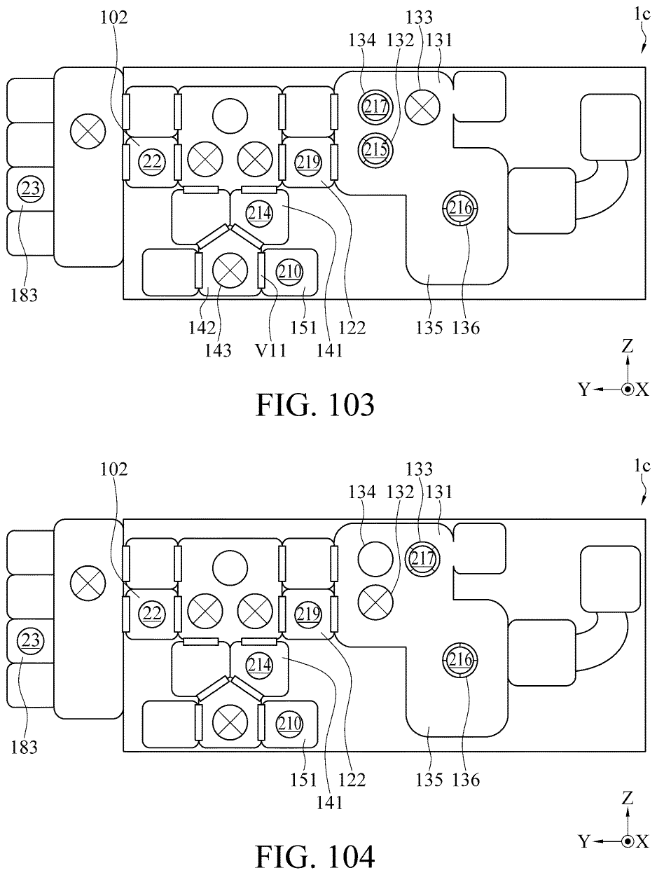

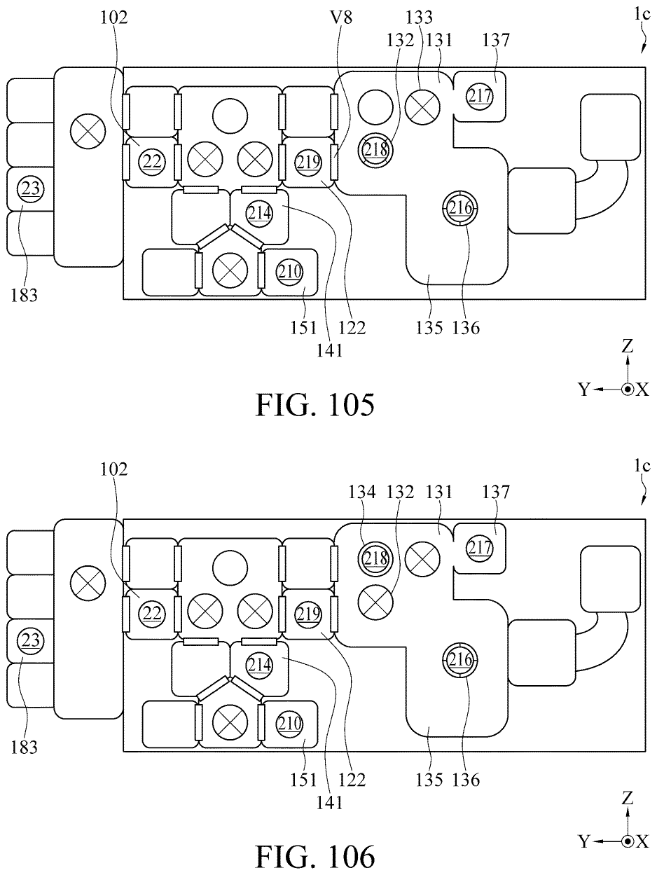

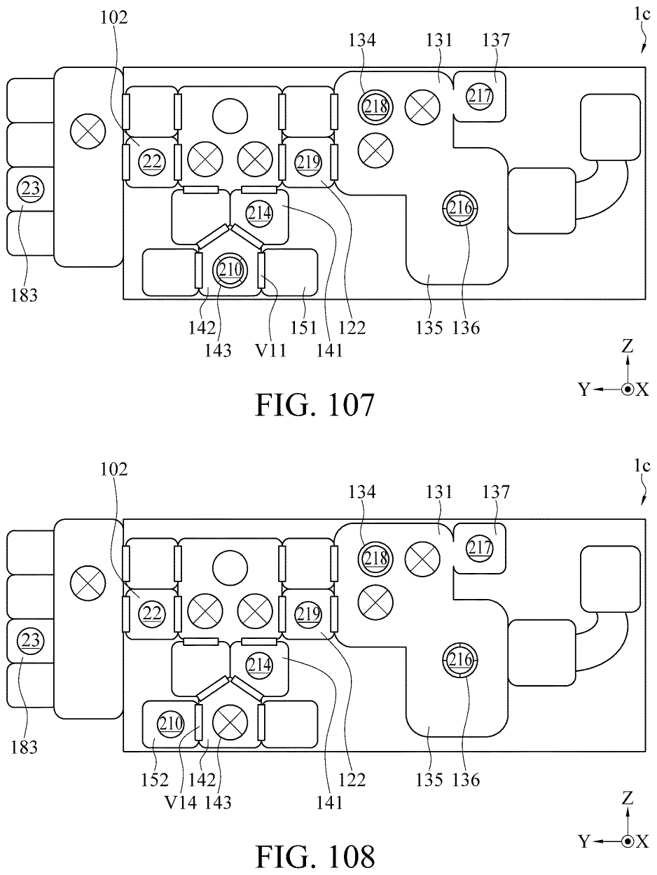

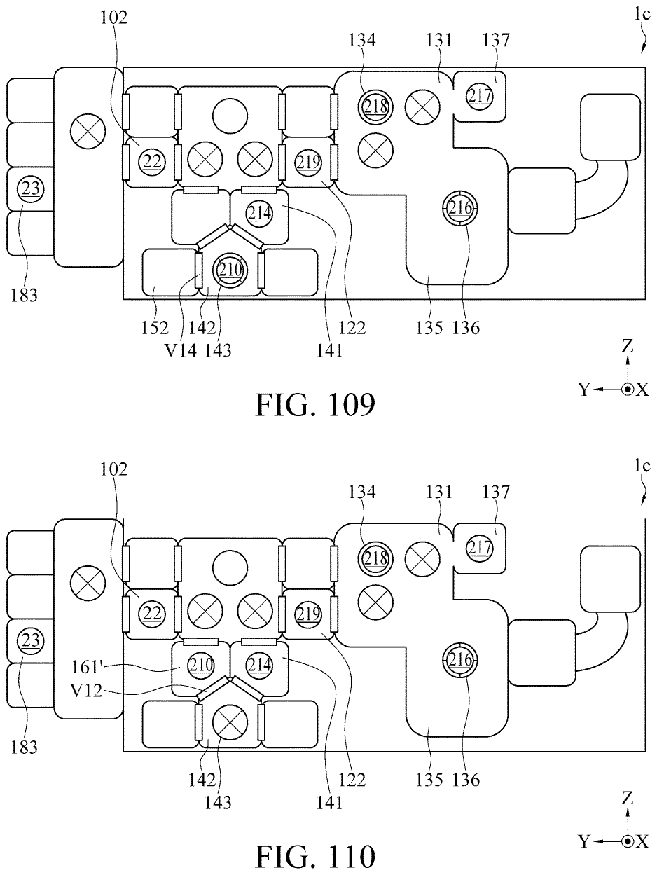

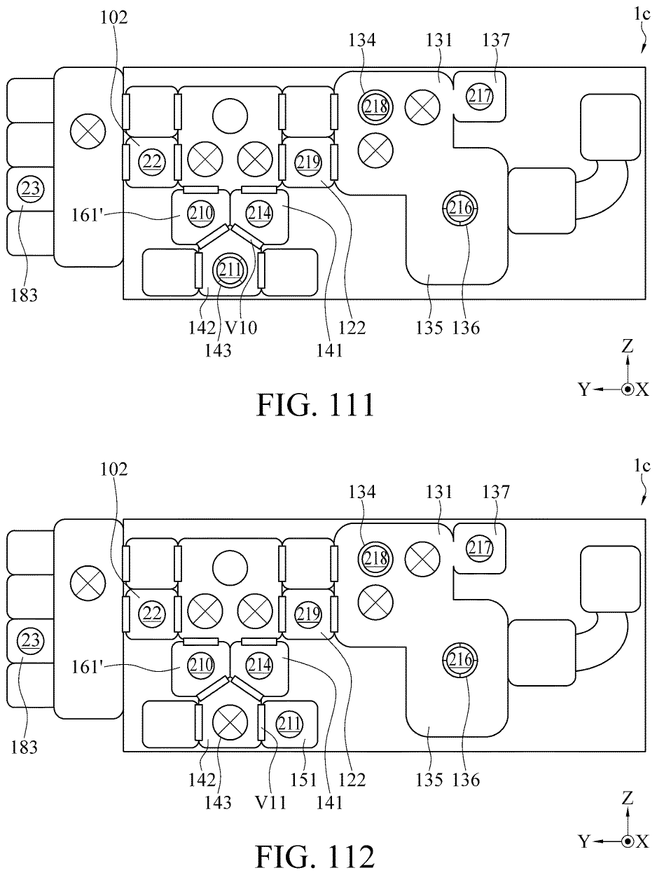

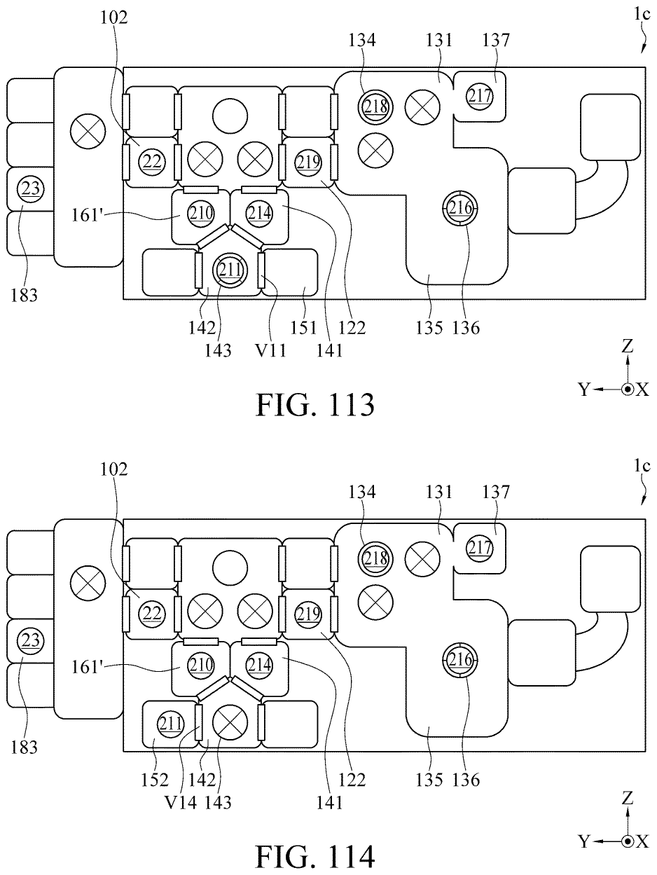

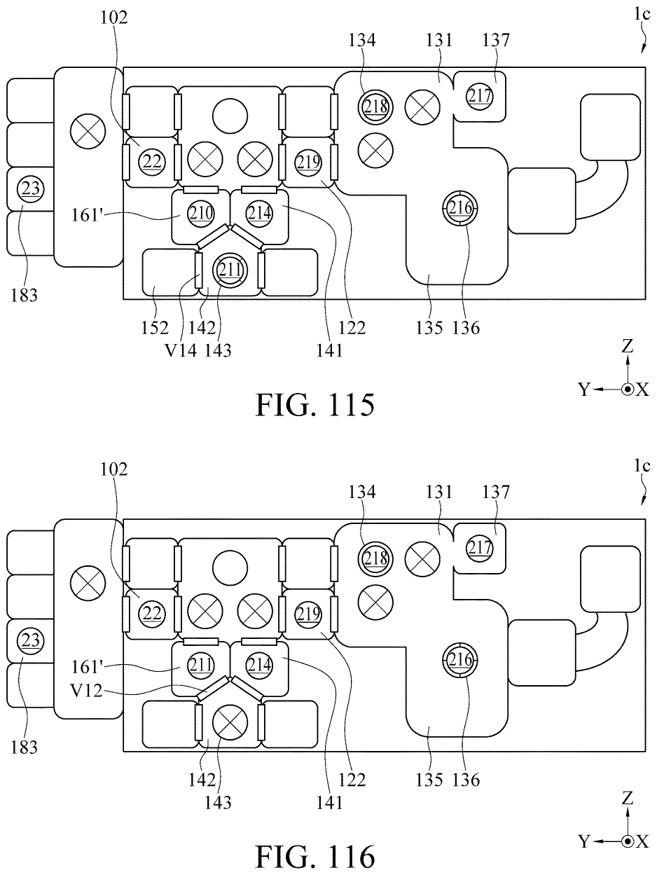

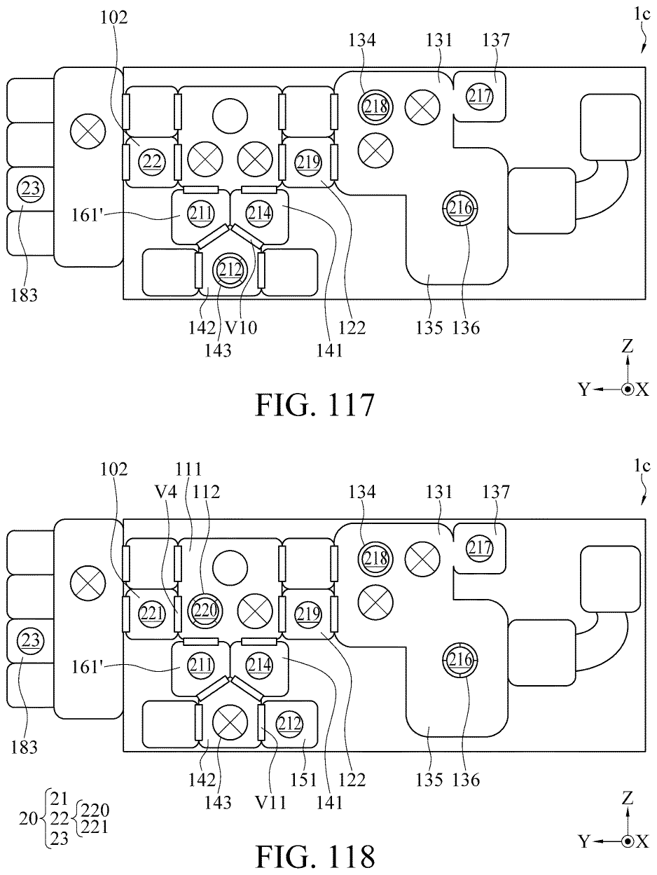

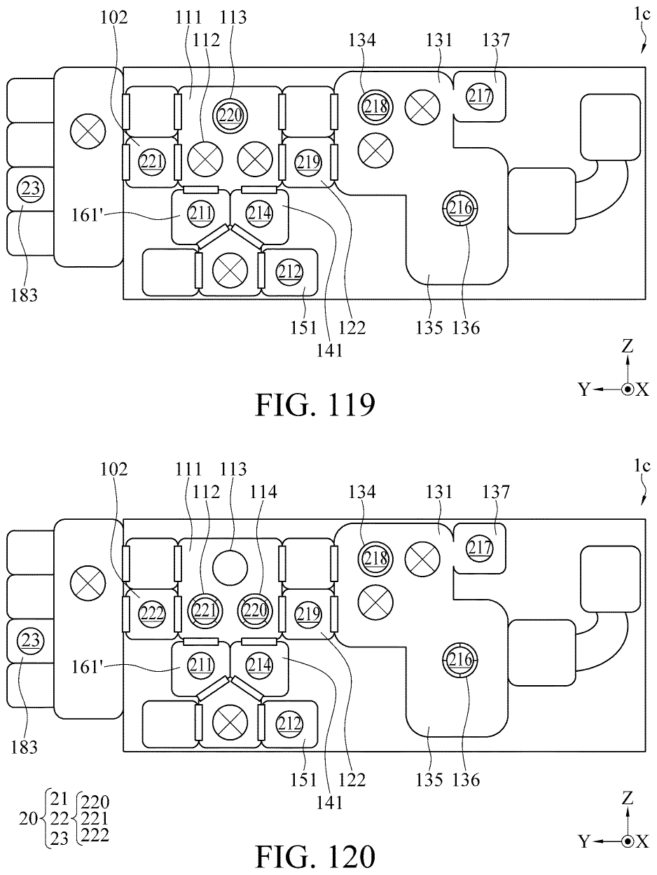

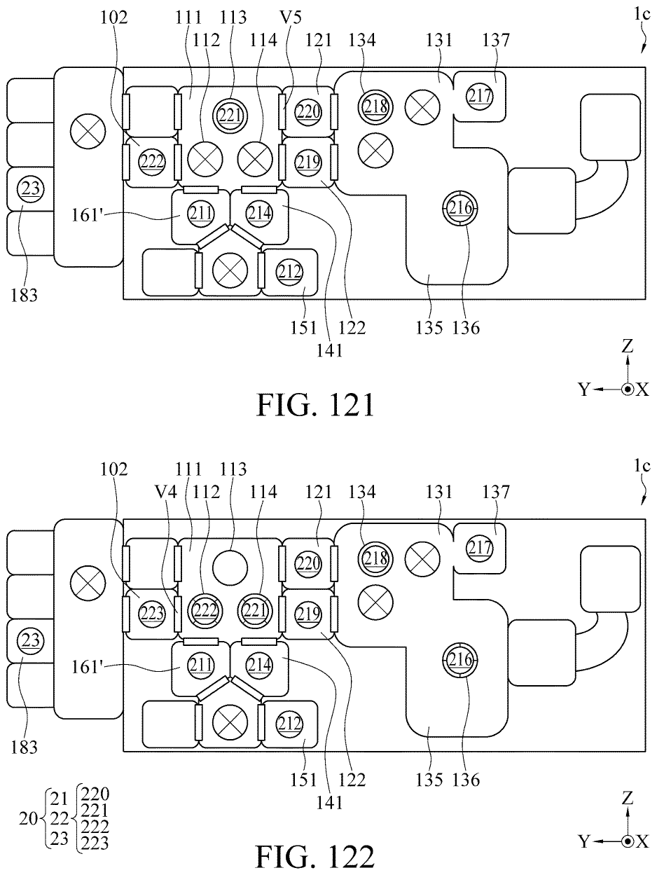

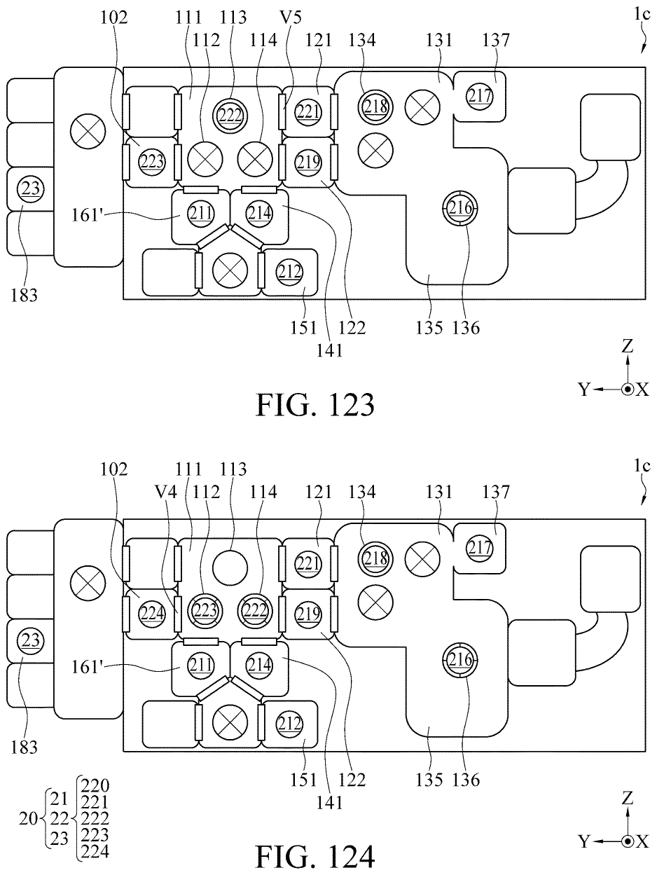

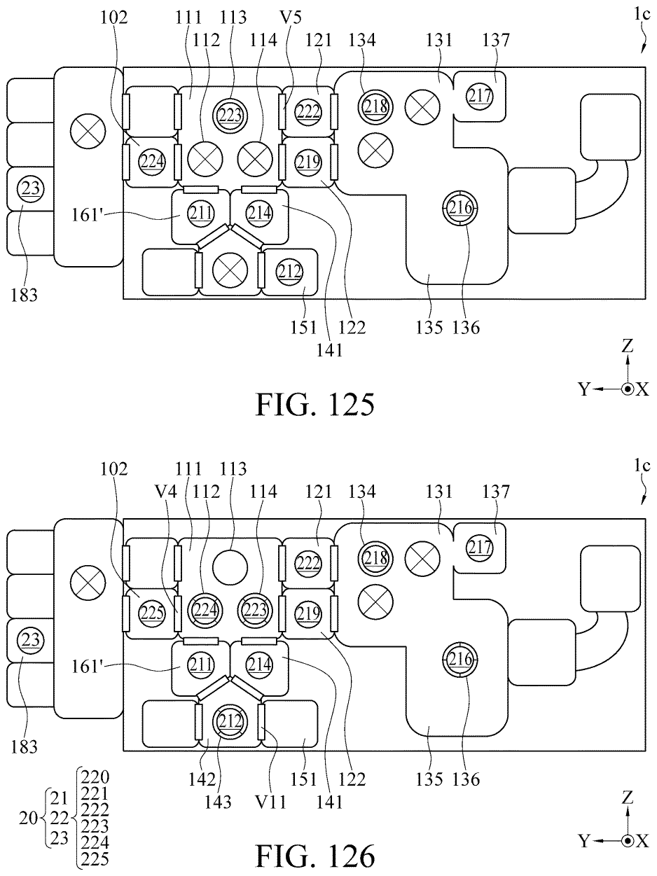

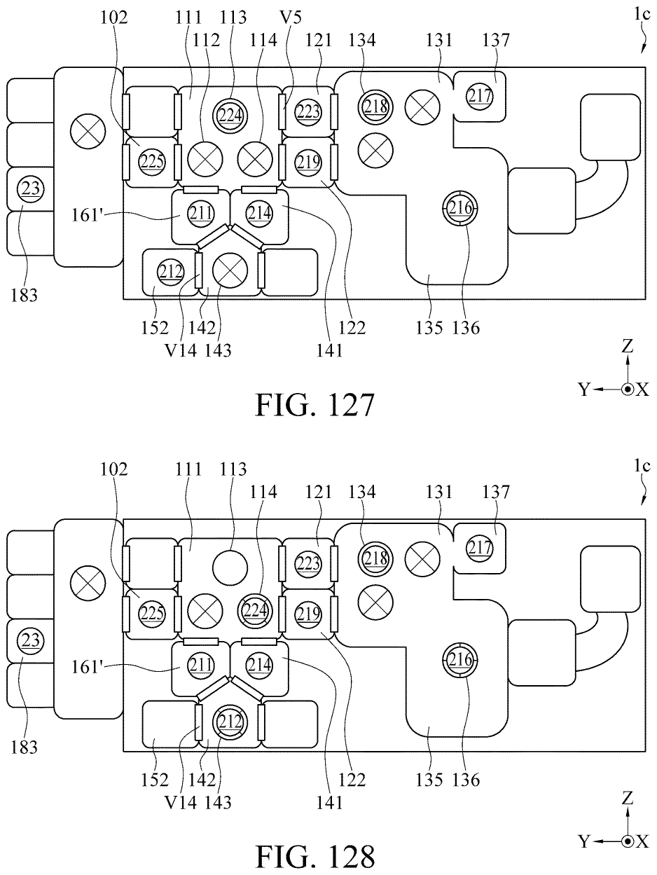

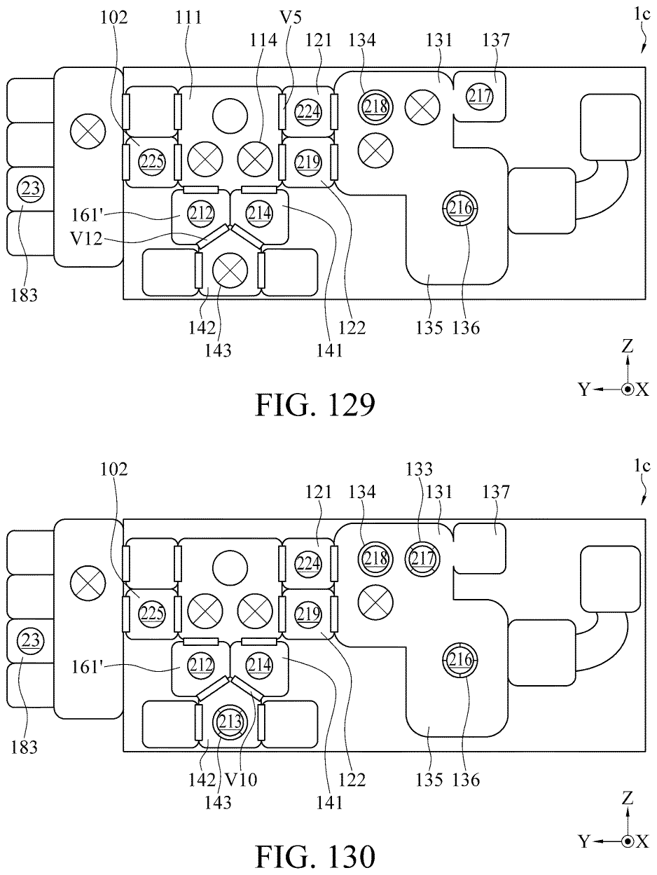

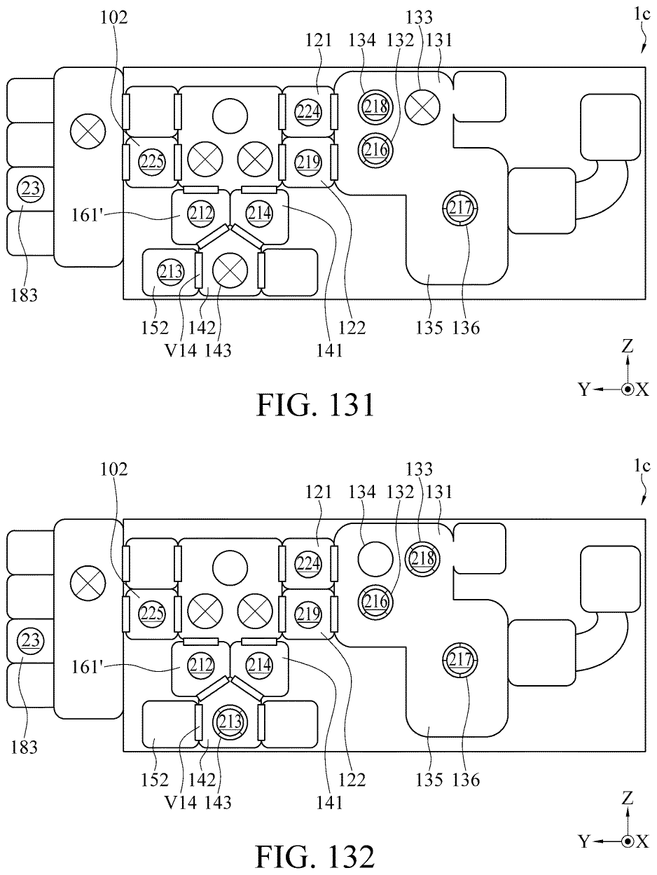

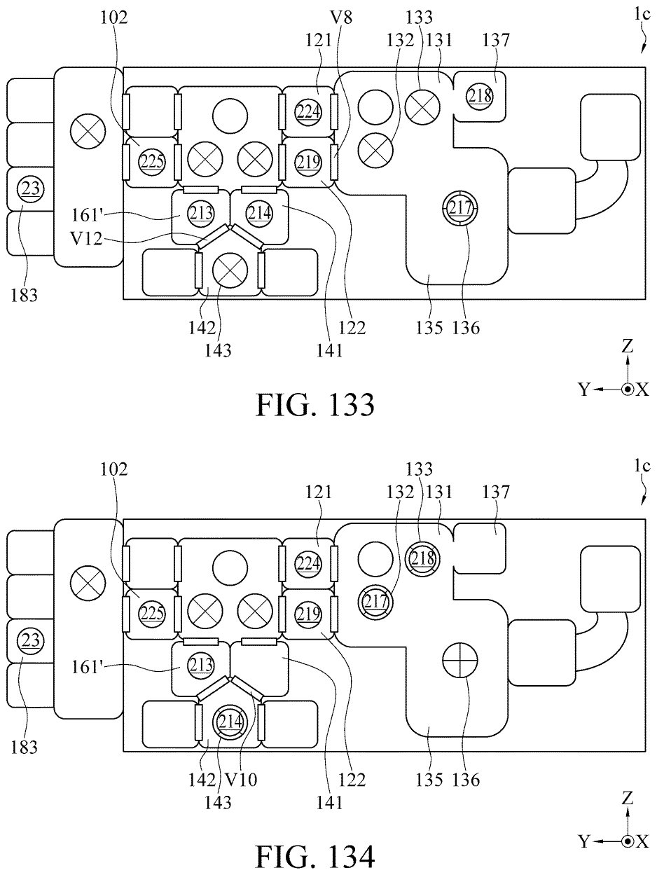

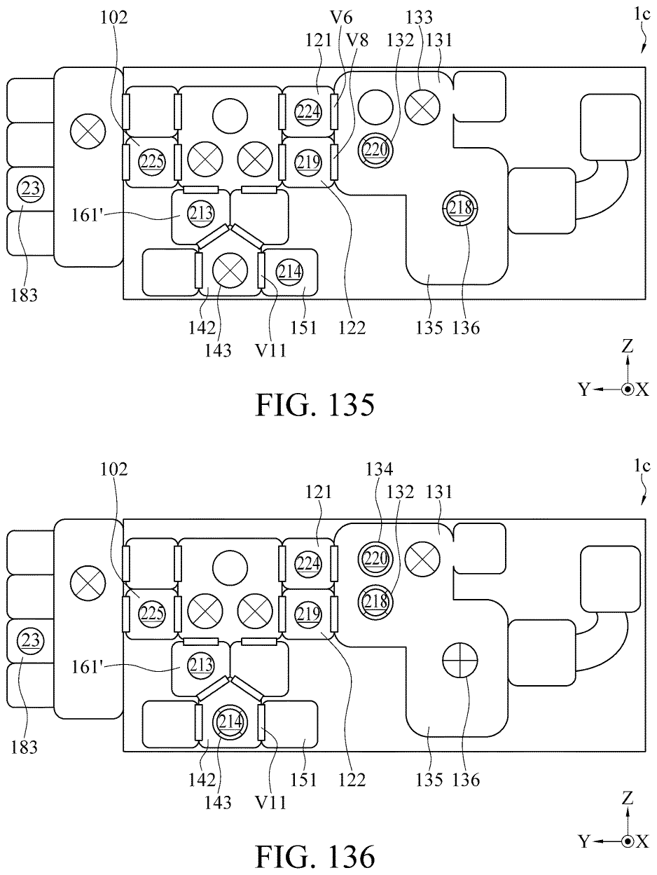

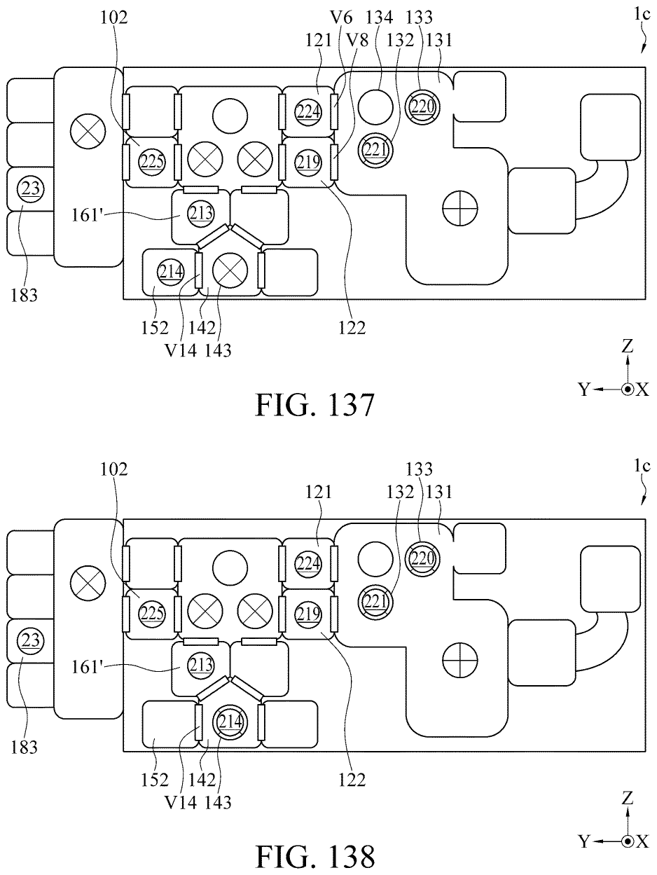

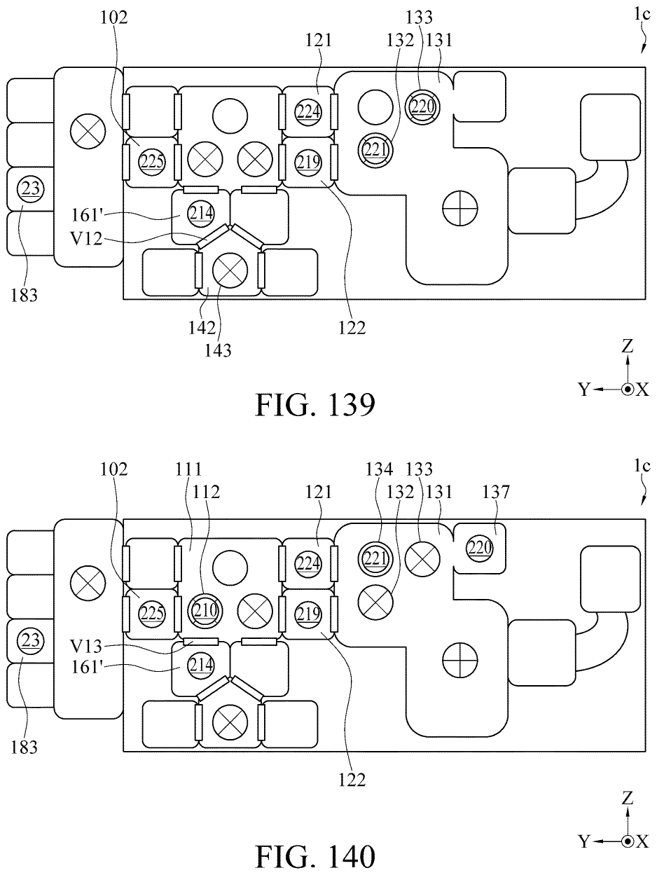

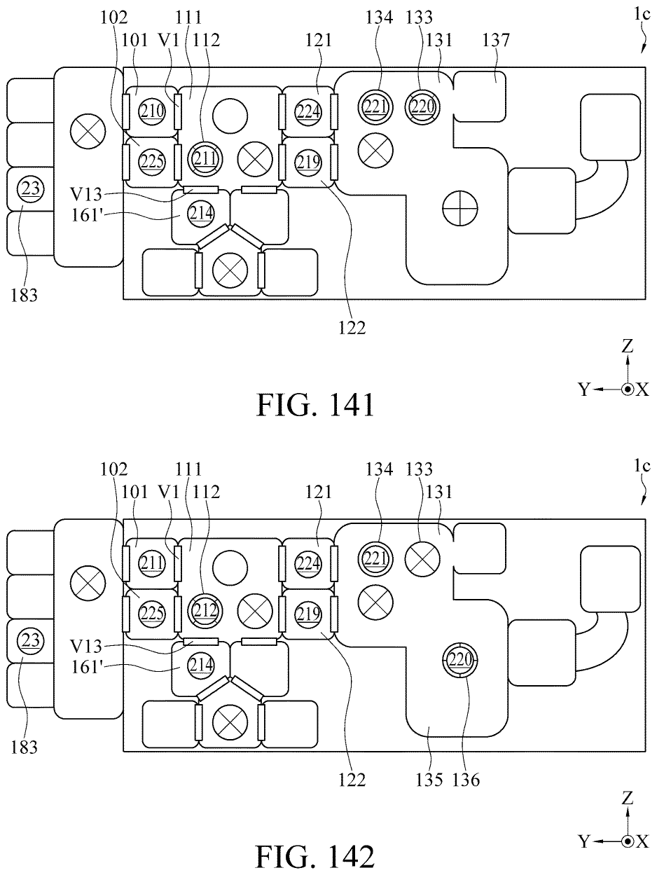

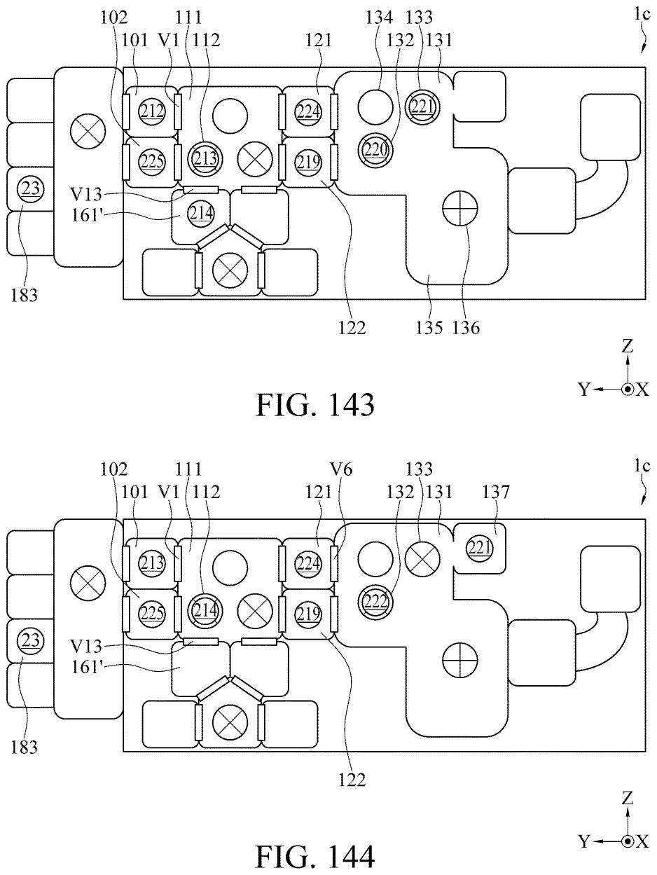

Please refer to FIG. 40A. The equipment front end robot 192 is configured to movably disposed in the equipment front end chamber 191 in accordance with different process requirements, for example, the equipment front end robot 192 is configured to move along a route S′ (e.g., a straight route that is parallel to the axis Z as shown in FIG. 40A) in the equipment front end chamber 191, to transfer the wafers 21-23 (as shown in FIG. 41) to the corresponding first load-lock chamber 101 or 102 through the equipment front end robot 192, or to transfer the wafers 21-23 from the first load-lock chamber 101 or 102 to the corresponding front opening unified pods 181-184.

Please refer to FIG. 1B and FIG. 40B. In some embodiments, even though the multiple-chamber semiconductor serial constructing apparatus 1c further has a heating chamber 137 and another second process-transfer chamber 152, compared with the multiple-chamber semiconductor serial constructing apparatus 1a as shown in FIG. 1B, the width W2′ of the multiple-chamber semiconductor serial constructing apparatus 1c as shown in FIG. 40B may be maintained at the same as the width W2 of the multiple-chamber semiconductor serial constructing apparatus 1a as shown in FIG. 1B; and the length W1′ of the multiple-chamber semiconductor serial constructing apparatus 1c as shown in FIG. 40B is slightly greater than the length W1 of the multiple-chamber semiconductor serial constructing apparatus 1a as shown in FIG. 1B. For example, the length W1 of the multiple-chamber semiconductor serial constructing apparatus 1a as shown in FIG. 1B is about 598 cm, and the length W1′ of the multiple-chamber semiconductor serial constructing apparatus 1c as shown in FIG. 40B is within a range from 768 cm to 798 cm. Hence, in some embodiments, even though the heating chamber 137 and another second process-transfer chamber 152 are further arranged, the length W1′ of the multiple-chamber semiconductor serial constructing apparatus 1c may be only increased by a difference within a range from 170 cm to 200 cm, without necessarily increasing the length W1′ of the multiple-chamber semiconductor serial constructing apparatus 1c apparently.

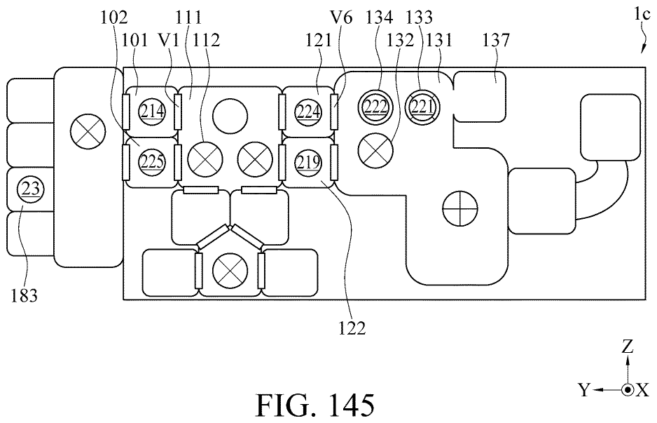

The following exemplarily describes specific embodiments of some processes performed by the multiple-chamber semiconductor serial constructing apparatus 1c through FIG. 41 to FIG. 145; however, various parameter conditions (e.g., pressure) and transfer sequences may be adjusted according to actual requirements. Accordingly, it is noted that the instant disclosure encompassed by the present application is not particularly limited to these embodiments.

Additionally, it is noted that the components to be transferred 2 are exemplarily illustrated herein by the wafers 21-23; however, the number of wafers 21-23 may be increased or decreased according to actual requirements, which is not particularly limited thereto. For ease of identification, each of the wafers 21-23 is labeled according to the order in which it enters the first load-lock module 10, such that a smaller numeral refers to the corresponding wafer entering the first load-lock module 10 earlier.

Moreover, in FIG. 41 to FIG. 145, each of the valves V1-V14 is normally maintained at a closed state, and each of the valves V1-V14 is independently opened only when needed. Therefore, unless specifically described herein, the valves V1-V14 should be understood to be at a closed state; and in such closed state, two independent spaces coupled with each other through any of the valves V1-V14 are not in communication with each other. The valves V1-V14 may be any suitable valves having a function of controlling whether to establish the communication and a function of controlling a flow rate of gas passing therethrough, which is not particularly limited herein.

In FIG. 41, a plurality of components to be transferred 2 (illustrated as the wafers 21-23) are respectively accommodated in the front opening unified pods 181-183. (It should be noted that, although three wafers 21-23 are illustrated herein, the instant disclosure is not limited thereto; for example, another wafer accommodated in the front opening unified pod 184 (which may be referred to as shown in FIG. 1A) may also be included; and each of the wafers 21-23 may respectively represent a wafer set comprising 1, 5, 10, 25 or more wafers.)

In FIG. 41 to FIG. 145, each of the wafers 21-23 represents 10 wafers, and each of the wafers 21-23 may be divided into two wafer sets with each wafer set comprising five wafers. By taking the wafer 21 as an example, the wafer 21 may, for example, comprise 10 wafers, and each five of the wafers are divided as one wafer set; hence, the wafer 21 may comprise a first wafer set (comprising the wafers 210-214 (as shown in FIG. 49); five wafers in total) and a second wafer set (comprising the wafers 215-219 (as shown in FIG. 59); five wafers in total). The same may be applied to the wafer 22 to comprise, for example, a third wafer set (comprises the wafers 220-224 (as shown in FIG. 124); five wafers in total) and a fourth wafer set (comprising the wafers 225-229 (as shown in FIG. 126, where the numerals 226-229 are not additionally denoted); five wafers in total).

In FIG. 42, the equipment front end robot 192 of the equipment front end module 19 is actuated to pick the wafer 21 placed in the front opening unified pod 181 to transfer the wafer 21 to the interior of the equipment front end chamber 191.

In FIG. 43, the valve V1 is opened, and the equipment front end robot 192 is actuated to transfer the wafer 21 to the interior of the first load-lock chamber 101. The valve V1 is closed, and the pressure P10 (as shown in FIG. 40D) of the first load-lock chamber 101 is adjusted from, for example, 760 torr to any pressure less than or equal to 1×10⁻² torr (e.g., within a range from 5×10⁻⁴ torr to 1×10⁻² torr).

In FIG. 44, the valve V2 is opened, and the pressure P11 (as shown in FIG. 40D) of the first vacuum-transfer chamber 111 and the pressure P10 (as shown in FIG. 40D) of the first load-lock chamber 101 may be both maintained at, for example, any pressure less than or equal to 1×10⁻² torr (e.g., within a range from 5×10⁻⁴ torr to 1×10⁻² torr). The first vacuum-transfer robot 112 of the first vacuum-transfer module 11 is actuated to pick the wafer 210 placed in the first load-lock chamber 101 to transfer the wafer 210 to the interior of the first vacuum-transfer chamber 111.

In FIG. 45, after the alignment process of the wafer 210 is completed, the first vacuum-transfer robot 112 is actuated to transfer the wafer 210 to the first vacuum-transfer aligner 113 to perform the alignment process corresponding to the first vacuum-transfer aligner 113 on the wafer 210.

In FIG. 46, the first vacuum-transfer robot 114 of the first vacuum-transfer module 11 is actuated to pick the wafer 210 placed in the first vacuum-transfer aligner 113. Regardless of the transfer sequence of the wafer 210 (i.e., simultaneously therewith, or before or after the same), the first vacuum-transfer robot 112 is actuated to pick the wafer 211 placed in the first load-lock chamber 101 to transfer the wafer 211 to the interior of the first vacuum-transfer chamber 111.

In FIG. 47, the valve V5 is opened, and the pressure P12 (as shown in FIG. 40D) of the second load-lock chamber 121 is maintained at, for example, any pressure less than or equal to 1×10⁻² torr (e.g., within a range from 5×10⁻⁴ torr to 1×10⁻² torr). The first vacuum-transfer robot 114 is actuated to transfer the wafer 210 to the interior of the second load-lock chamber 121 of the second load-lock module 12. The first vacuum-transfer robot 112 is actuated to transfer the wafer 211 to the first vacuum-transfer aligner 113 to perform the alignment process corresponding to the first vacuum-transfer aligner 113 on the wafer 211.

In FIG. 48, after the alignment process of the wafer 211 is completed, the first vacuum-transfer robot 114 is actuated to pick the wafer 211 placed in the first vacuum-transfer aligner 113; and regardless of the transfer sequence of the wafer 211, the first vacuum-transfer robot 112 is actuated to pick the wafer 212 placed in the first load-lock chamber 101 to transfer the wafer 212 to the interior of the first vacuum-transfer chamber 111.

Next, the first vacuum-transfer robot 114 is actuated to transfer the wafer 211 to the interior of the second load-lock chamber 121. Regardless of the transfer sequence of the wafer 211, the first vacuum-transfer robot 112 is actuated to transfer the wafer 212 to the first vacuum-transfer aligner 113 to perform the alignment process corresponding to the first vacuum-transfer aligner 113 on the wafer 212.

In FIG. 49, after the alignment process of the wafer 212 is completed, the first vacuum-transfer robot 114 is actuated to pick the wafer 212 placed in the first vacuum-transfer aligner 113. Regardless of the transfer sequence of the wafer 212, the first vacuum-transfer robot 112 is actuated to pick the wafer 213 placed in the first load-lock chamber 101 to transfer the wafer 213 to the interior of the first vacuum-transfer chamber 111.

In FIG. 50, the first vacuum-transfer robot 114 is actuated to transfer the wafer 212 to the interior of the second load-lock chamber 121. Regardless of the transfer sequence of the wafer 212, the first vacuum-transfer robot 112 is actuated to transfer the wafer 213 to the first vacuum-transfer aligner 113 to perform the alignment process corresponding to the first vacuum-transfer aligner 113 on the wafer 213.

In FIG. 51, after the alignment process of the wafer 213 is completed, the first vacuum-transfer robot 114 is actuated to pick the wafer 213 placed in the first vacuum-transfer aligner 113; and regardless of the transfer sequence of the wafer 213, the first vacuum-transfer robot 112 is actuated to pick the wafer 214 placed in the first load-lock chamber 101 to transfer the wafer 214 to the interior of the first vacuum-transfer chamber 111. At this moment, the first wafer set (comprising the wafers 210-214) have all been transferred from the first load-lock chamber 101 to the interior of the first vacuum-transfer chamber 111 or the interior of the second load-lock chamber 121.

In FIG. 52, the first vacuum-transfer robot 114 is actuated to transfer the wafer 213 to the interior of the second load-lock chamber 121. Regardless of the transfer sequence of the wafer 213, the first vacuum-transfer robot 112 is actuated to transfer the wafer 214 to the first vacuum-transfer aligner 113 to perform the alignment process corresponding to the first vacuum-transfer aligner 113 on the wafer 214.

In FIG. 53, after the alignment process of the wafer 214 is completed, the first vacuum-transfer robot 114 is actuated to pick the wafer 214 placed in the first vacuum-transfer aligner 113. Regardless of the transfer sequence of the wafer 214, the first vacuum-transfer robot 112 is actuated to pick the wafer 215 placed in the first load-lock chamber 101 to transfer the wafer 215 to the interior of the first vacuum-transfer chamber 111.

In FIG. 54, the first vacuum-transfer robot 114 is actuated to transfer the wafer 214 to the interior of the second load-lock chamber 121. The valve V5 is closed, and the pressure P12 (as shown in FIG. 40D) of the second load-lock chamber 121 is maintained at, for example, any pressure within a range from 1×10⁻⁷ torr to 1×10⁻² torr. Referring to the steps of the first wafer set (comprising the wafers 210-214) that is transferred from the first load-lock chamber 101 to the interior of the second load-lock chamber 121, as shown in FIG. 55 to FIG. 64, the second wafer set (comprising the wafers 215-219) may also be transferred to the interior of the second load-lock chamber 122 through the first vacuum-transfer robot 112, the first vacuum-transfer aligner 113, the first vacuum-transfer robot 114, and the valves V2, V7, which is thus not further described in detail herein. After the second wafer set (e.g., the last-transferred wafer 219) is transferred to the interior of the second load-lock chamber 122, the valve V7 (as shown in FIG. 64) is closed, and the pressure P12′ (as shown in FIG. 40D) of the second load-lock chamber 122 is maintained at, for example, any pressure within a range from 1×10⁻⁷ torr to 1×10⁻² Torr.

In FIG. 57, regardless of the transfer sequence of the wafers 216, 217, the valve V6 is opened, and the second vacuum-transfer robot 132 is actuated to pick the wafer 210 placed in the second load-lock chamber 121 to transfer the wafer 210 to the interior of the second vacuum-transfer chamber 131. The pressure P12 (as shown in FIG. 40D) of the second load-lock chamber 121 and the pressure P13 (as shown in FIG. 40D) of the second vacuum-transfer chamber 131 (and the pressure P13′ (as shown in FIG. 40D) of the first process-transfer chamber 135 and the pressure P13″ (as shown in FIG. 40D) of the heating chamber 137) may be all maintained at, for example, any pressure within a range from 1×10⁷ torr to 2×10⁵ torr.

In FIG. 58, regardless of the transfer sequence of the wafers 216, 217, the second vacuum-transfer robot 132 is actuated to transfer the wafer 210 to the second vacuum-transfer aligner 134 to perform the alignment process corresponding to the second vacuum-transfer aligner 134 on the wafer 210.

In FIG. 60, regardless of the transfer sequence of the wafers 217, 218, the second vacuum-transfer robot 133 is actuated to pick the wafer 210 placed in the second vacuum-transfer aligner 134. Regardless of the transfer sequence of the wafers 217, 218, the second vacuum-transfer robot 132 is actuated to pick the wafer 211 placed in the second load-lock chamber 121 to transfer the wafer 211 to the interior of the second vacuum-transfer chamber 131.

In FIG. 61, regardless of the transfer sequence of the wafers 218, 219, the second vacuum-transfer robot 132 is actuated to transfer the wafer 211 to the second vacuum-transfer aligner 134 to perform the alignment process corresponding to the second vacuum-transfer aligner 134 on the wafer 211.

In FIG. 64, regardless of the transfer sequence of the wafer 219, the second vacuum-transfer robot 133 is actuated to pick the wafer 210 placed in the heating chamber 137.

In FIG. 65, the second vacuum-transfer robot 133 is actuated to transfer the wafer 210 to the location of the first process-transfer robot 136, and the first process-transfer robot 136 is actuated to transfer the wafer 210 to the interior of the first process-transfer chamber 135 to perform the ion implantation process corresponding to the ion implantation assembly 17 (as shown in FIG. 40A) on the wafer 210.

In FIG. 66, after the alignment process of the wafer 211 is completed, the second vacuum-transfer robot 133 is actuated to pick the wafer 211 placed in the second vacuum-transfer aligner 134. Regardless of the transfer sequence of the wafer 211, the second vacuum-transfer robot 132 is actuated to pick the wafer 212 placed in the second load-lock chamber 121 to transfer the wafer 212 to the interior of the second vacuum-transfer chamber 131.

In FIG. 67, the second vacuum-transfer robot 133 is actuated to transfer the wafer 211 to the heating chamber 137 to perform the heating process corresponding to the heating chamber 137 on the wafer 211. Regardless of the transfer sequence of the wafer 211, the second vacuum-transfer robot 132 is actuated to transfer the wafer 212 to the second vacuum-transfer aligner 134 to perform the alignment process corresponding to the second vacuum-transfer aligner 134 on the wafer 212.

In FIG. 68, after the heating process of the wafer 211 is completed, the second vacuum-transfer robot 133 is actuated to pick the wafer 211 placed in the heating chamber 137.

In FIG. 69, after the ion implantation process of the wafer 210 is completed, the second vacuum-transfer robot 132 is actuated to pick the wafer 210 placed in the first process-transfer robot 136. The second vacuum-transfer robot 133 is actuated to transfer the wafer 211 to the location of the first process-transfer robot 136, and the first process-transfer robot 136 is actuated to transfer the wafer 211 to the interior of the first process-transfer chamber 135 to perform the ion implantation process corresponding to the ion implantation assembly 17 (as shown in FIG. 40A) on the wafer 211.

In FIG. 70, after the alignment process of the wafer 212 is completed, the second vacuum-transfer robot 133 is actuated to pick the wafer 212 placed in the second vacuum-transfer aligner 134. Regardless of the transfer sequence of the wafer 212, the second vacuum-transfer robot 132 is actuated to transfer the wafer 210 (as shown in FIG. 69) to the second load-lock chamber 121.

In FIG. 71, the second vacuum-transfer robot 133 is actuated to transfer the wafer 212 to the heating chamber 137 to perform the heating process corresponding to the heating chamber 137 on the wafer 212. Regardless of the transfer sequence of the wafer 212, the second vacuum-transfer robot 132 is actuated to pick the wafer 213 placed in the second load-lock chamber 121 to transfer the wafer 213 to the interior of the second vacuum-transfer chamber 131.

In FIG. 72, the second vacuum-transfer robot 132 is actuated to transfer the wafer 213 to the second vacuum-transfer aligner 134 to perform the alignment process corresponding to the second vacuum-transfer aligner 134 on the wafer 213.

In FIG. 73, after the heating process of the wafer 212 is completed, the second vacuum-transfer robot 133 is actuated to pick the wafer 212 placed in the heating chamber 137.

In FIG. 74, after the ion implantation process of the wafer 211 is completed, the second vacuum-transfer robot 132 is actuated to pick the wafer 211 placed in the first process-transfer robot 136. The second vacuum-transfer robot 133 is actuated to transfer the wafer 212 to the location of the first process-transfer robot 136, and the first process-transfer robot 136 is actuated to transfer the wafer 212 to the interior of the first process-transfer chamber 135 to perform the ion implantation process corresponding to the ion implantation assembly 17 (as shown in FIG. 40A) on the wafer 212.

In FIG. 75, after the alignment process of the wafer 213 is completed, the second vacuum-transfer robot 133 is actuated to pick the wafer 213 placed in the second vacuum-transfer aligner 134. Regardless of the transfer sequence of the wafer 213 (i.e., simultaneously therewith, or before or after the same), the second vacuum-transfer robot 132 is actuated to transfer the wafer 211 (as shown in FIG. 74) to the second load-lock chamber 121.

In FIG. 76, the second vacuum-transfer robot 133 is actuated to transfer the wafer 213 to the heating chamber 137 to perform the heating process corresponding to the heating chamber 137 on the wafer 213. Regardless of the transfer sequence of the wafer 213, the second vacuum-transfer robot 132 is actuated to pick the wafer 214 placed in the second load-lock chamber 121 to transfer the wafer 214 to the interior of the second vacuum-transfer chamber 131.

In FIG. 77, the second vacuum-transfer robot 132 is actuated to transfer the wafer 214 to the second vacuum-transfer aligner 134 to perform the alignment process corresponding to the second vacuum-transfer aligner 134 on the wafer 214.

In FIG. 78, after the heating process of the wafer 213 is completed, the second vacuum-transfer robot 133 is actuated to pick the wafer 213 placed in the heating chamber 137.

In FIG. 79, after the ion implantation process of the wafer 212 is completed, the second vacuum-transfer robot 132 is actuated to pick the wafer 212 placed in the first process-transfer robot 136. The second vacuum-transfer robot 133 is actuated to transfer the wafer 213 to the location of the first process-transfer robot 136, and the first process-transfer robot 136 is actuated to transfer the wafer 213 to the interior of the first process-transfer chamber 135 to perform the ion implantation process corresponding to the ion implantation assembly 17 (as shown in FIG. 40A) on the wafer 213.

In FIG. 80, after the alignment process of the wafer 214 is completed, the second vacuum-transfer robot 133 is actuated to pick the wafer 214 placed in the second vacuum-transfer aligner 134. Regardless of the transfer sequence of the wafer 214, the second vacuum-transfer robot 132 is actuated to transfer the wafer 212 to the second load-lock chamber 121.

In FIG. 81, the second vacuum-transfer robot 133 is actuated to transfer the wafer 214 to the heating chamber 137 to perform the heating process corresponding to the heating chamber 137 on the wafer 214. Regardless of the transfer sequence of the wafer 214, the second vacuum-transfer robot 132 is actuated to pick the wafer 215 placed in the second load-lock chamber 122 to transfer the wafer 215 to the interior of the second vacuum-transfer chamber 131. Referring to the steps of the first wafer set (comprising the wafers 210-214) that is transferred from the second load-lock chamber 121 to the interiors of the second vacuum-transfer chamber 131, the second vacuum-transfer aligner 134, the heating chamber 137, and the first process-transfer chamber 135 and further back to the interior of the second load-lock chamber 121, as shown in FIG. 81 to FIG. 137, the second wafer set (comprising the wafers 215-219) may also be transferred from the second load-lock chamber 122 to the interiors of the second vacuum-transfer chamber 131, the second vacuum-transfer aligner 134, the heating chamber 137, and the first process-transfer chamber 135 and further back to the interior of the second load-lock chamber 122, which is thus not further described in detail herein. After the second wafer set (e.g., the last-transferred wafer 219) is transferred to the interior of the second load-lock chamber 122, the valve V8 (as shown in FIG. 137) is closed.

In FIG. 83, after the heating process of the wafer 214 is completed, the second vacuum-transfer robot 133 is actuated to pick the wafer 214 placed in the heating chamber 137.

In FIG. 84, after the ion implantation process of the wafer 213 is completed, the second vacuum-transfer robot 132 is actuated to pick the wafer 213 placed in the first process-transfer robot 136. The second vacuum-transfer robot 133 is actuated to transfer the wafer 214 to the location of the first process-transfer robot 136, and the first process-transfer robot 136 is actuated to transfer the wafer 214 to the interior of the first process-transfer chamber 135 to perform the ion implantation process corresponding to the ion implantation assembly 17 (as shown in FIG. 40A) on the wafer 214.

In FIG. 85, the second vacuum-transfer robot 132 is actuated to transfer the wafer 213 to the second load-lock chamber 121.

In FIG. 89, after the ion implantation process of the wafer 214 is completed, the second vacuum-transfer robot 132 is actuated to pick the wafer 214 placed in the first process-transfer robot 136.

In FIG. 90, the second vacuum-transfer robot 132 is actuated to transfer the wafer 214 to the second load-lock chamber 121. The valve V6 is closed, and the pressure P12 (as shown in FIG. 40D) of the second load-lock chamber 121 is adjusted to, for example, any pressure less than or equal to 1×10⁻² torr (e.g., within a range from 1×10⁻⁷ torr to 1×10⁻² torr).

In FIG. 92, after the pressure P12 (as shown in FIG. 40D) of the second load-lock chamber 121 is adjusted to, for example, any pressure less than or equal to 1×10⁻² torr, the valve V5 is opened, and the first vacuum-transfer robot 114 is actuated to pick the wafer 210 placed in the second load-lock chamber 121 to transfer the wafer 210 to the interior of the first vacuum-transfer chamber 111.

In FIG. 93, the pressure P14 (as shown in FIG. 40D) of the third load-lock chamber 141 is maintained at, for example, any pressure less than or equal to 1×10⁻² torr, the valve V9 is opened, and the first vacuum-transfer robot 114 is actuated to transfer the wafer 210 to the interior of the third load-lock chamber 141. Referring to the steps of the wafer 210 that is transferred from the second load-lock chamber 121 to the interiors of the first vacuum-transfer chamber 111 and the third load-lock chamber 141, as shown in FIG. 94 to FIG. 101, the wafers 211-214 may also be transferred from the second load-lock chamber 121 to the interiors of the first vacuum-transfer chamber 111 and the third load-lock chamber 141 through the first vacuum-transfer robot 114, which is not further described in detail herein. After the wafer 214, for example, is transferred to the interior of the third load-lock chamber 141, the valve V9 (as shown in FIG. 40C) is closed.

In FIG. 102, after the pressure P14′ (as shown in FIG. 40D) of the third vacuum-transfer chamber 142 is maintained at, for example, any pressure less than or equal to 1×10⁻² torr, the valve V10 is opened. The third vacuum-transfer robot 143 is actuated to pick the wafer 210 placed in the third load-lock chamber 141 to transfer the wafer 210 to the interior of the third vacuum-transfer chamber 142.

In FIG. 103, the valve V11 is opened, the third vacuum-transfer robot 143 is actuated to transfer the wafer 210 to the interior of the second process-transfer chamber 151, and the pressure P15 (as shown in FIG. 40D) of the second process-transfer chamber 151 is maintained at, for example, any pressure less than or equal to 1×10⁻² torr; the valve V11 is closed, and the pressure P15 of the second process-transfer chamber 151 is selectively within a range from 5×10⁻⁴ torr to 5 torr, for example, to perform the process corresponding to the second process-transfer chamber 151 on the wafer 210 (e.g., the pressure P15 is adjusted to 5×10⁻⁴ torr to perform the corresponding etching process). In some embodiments, after the wafer 210 is transferred to the interior of the second process-transfer chamber 151, preferably, the valve V11 is closed, thereby reducing or avoiding external contamination of the second process-transfer chamber 151 and the wafer 210 in the second process-transfer chamber 151.

In FIG. 107, after the process corresponding to the second process-transfer chamber 151 performed on the wafer 210 (e.g., the etching process) is completed and the pressure P15 (as shown in FIG. 40D) of the second process-transfer chamber 151 is adjusted to, for example, any pressure less than or equal to 1×10⁻² torr, the valve V11 is opened. The third vacuum-transfer robot 143 is actuated to pick the wafer 210 placed in the second process-transfer chamber 151 to transfer the wafer 210 to the interior of the third vacuum-transfer chamber 142. The valve V11 is closed.

In FIG. 108, the valve V14 is opened, and the third vacuum-transfer robot 143 is actuated to transfer the wafer 210 to the interior of the second process-transfer chamber 152; the valve V14 is closed, and the pressure P15′ (as shown in FIG. 40D) of the second process-transfer chamber 152 is selectively within a range from 5×10⁻⁴ torr to 5 torr, for example, to perform the process corresponding to the second process-transfer chamber 152 on the wafer 210 (e.g., the pressure P15′ is adjusted to 5 torr to perform the corresponding plasma-treatment process).

In FIG. 109, after the process corresponding to the second process-transfer chamber 152 performed on the wafer 210 (e.g., the plasma-treatment process) is completed and the pressure P15′ of the second process-transfer chamber 152 (as shown in FIG. 40D) is selectively within a range from 5×10⁻⁴ torr to 5 torr, the valve V14 is opened. The third vacuum-transfer robot 143 is actuated to pick the wafer 210 placed in the second process-transfer chamber 152 to transfer the wafer 210 to the interior of the third vacuum-transfer chamber 142. The valve V14 is closed.

In FIG. 110, after the pressure P16′ (as shown in FIG. 40D)of the fourth load-lock chamber 161′ is maintained at, for example, any pressure less than or equal to 5×10⁻⁴ torr, the valve V12 is opened. The third vacuum-transfer robot 143 is actuated to transfer the wafer 210 to the interior of the fourth load-lock chamber 161′ (for example, the corresponding post-treatment process may be further performed on the wafer 210, e.g., a cooling process); and the valve V12 is closed. Referring to the steps of the wafer 210 that is transferred from the third load-lock chamber 141 to the interiors of the third vacuum-transfer chamber 142, the second process-transfer chambers 151, 152, and the fourth load-lock chamber 161′, as shown in FIG. 111 to FIG. 139, the wafers 211-214 may also be transferred from the third load-lock chamber 141 to the interiors of the third vacuum-transfer chamber 142, the second process-transfer chambers 151, 152, and the fourth load-lock chamber 161′ through the third vacuum-transfer robot 143, which is not further described in detail herein. After the wafer 214 is transferred to the interior of the fourth load-lock chamber 161′, for example, the valve V12 (as shown in FIG. 40C) is closed. In addition, in accordance with different process requirements, certain wafer set may perform the preset semiconductor process only in the second process-transfer chamber 151 or 152 (as shown in FIG. 40C) based on the preset process, and then the certain wafer set is transferred to the interior of the fourth load-lock chamber 161′ (as shown in FIG. 40A) through the third vacuum-transfer robot 143 (as shown in FIG. 40A). Furthermore, after the entire first wafer set (comprising the wafers 210-214, as shown in FIG. 59 and FIG. 139) is transferred to the interior of the fourth load-lock chamber 161′, the valve V12 (as shown in FIG. 40C) is closed; at this moment, after the pressures P16′, P11, P10 (as shown in FIG. 40D) of the fourth load-lock chamber 161′, the first vacuum-transfer chamber 111, and the first load-lock chamber 101 become substantially the same (which may be within a range from 5×10⁻⁴ torr to 1×10⁻² torr, for example), the valves V13, V2 are opened to sequentially transfer the wafers 210-214 of the first wafer set to the first load-lock chamber 101 through the first vacuum-transfer robot 112. Through the first vacuum-transfer module 11, the first process-transfer module 13, the second process-transfer module 15, the third process-transfer module 16, and multiple load-lock chambers 10, 12, 14, the wafer transfer can be achieved more rapidly and effectively without breaking the vacuum, and simultaneously, different semiconductor processes can be performed in a single machine.

In FIG. 118, after the ion implantation process of the first wafer set (comprising the wafers 210-214) is completed and after the last transfer step of being transferred to the third load-lock chamber 141 is completed, the third wafer set (comprising the wafers 220-224) in the first load-lock chamber 102 may start to be transferred sequentially into the first vacuum-transfer module 11, so that the first vacuum-transfer robots 112, 114 may process together in order without causing mechanical interference. In some embodiments, before the third wafer set (comprising the wafers 220-224) is transferred to the first vacuum-transfer module 11, the valve V4 is opened in advance, and the pressure P11 (as shown in FIG. 40D) of the first vacuum-transfer chamber 111 and the pressure P10′ (as shown in FIG. 40D) of the first load-lock chamber 102 may be both maintained at, for example, within a range from 5×10⁻⁴ torr to 1×10⁻² torr. The first vacuum-transfer robot 112 is actuated to pick the wafer 220 placed in the first load-lock chamber 102 to transfer the wafer 220 to the interior of the first vacuum-transfer chamber 111. Referring to the steps of the first wafer set (comprising the wafers 210-214) that is transferred from the first load-lock chamber 101 to the interior of the second load-lock chamber 121, as shown in FIG. 118 to FIG. 129, the third wafer set (comprising the wafers 220-224) may also be transferred to the interior of the second load-lock chamber 121 through the first vacuum-transfer robot 112, the first vacuum-transfer aligner 113, the first vacuum-transfer robot 114, and the valves V4, V5, which is not further described in detail herein. After the third wafer set (e.g., the last-transferred wafer 224) is transferred to the interior of the second load-lock chamber 121, the valve V5 (as shown in FIG. 129) is closed, and the pressure P12 (as shown in FIG. 40D) of the second load-lock chamber 121 is maintained at, for example, any pressure within a range from 1×10⁻⁷ torr to 1×10⁻² torr.

It should be noted that, in FIG. 134 to FIG. 135, the wafer 219 may also be transferred by referring to the transfer steps of the wafers 215-218, which is thus not further described in detail herein, and the transfer of the wafer 220 (as shown in FIG. 135) of the third wafer set is directly described.

In FIG. 135, the valve V6 is opened, and the second vacuum-transfer robot 132 is actuated to pick the wafer 220 placed in the second load-lock chamber 121 to transfer the wafer 220 to the interior of the second vacuum-transfer wafer 131. Referring to the steps of the first wafer set (comprising the wafers 210-214) that is transferred from the second load-lock chamber 121 to the interiors of the second vacuum-transfer chamber 131, the second vacuum-transfer aligner 134, the heating chamber 137, and the first process-transfer chamber 135 and further back to the interior of the second load-lock chamber 121, as shown in FIG. 135 to FIG. 145, for example, the third wafer set (comprising the wafers 220-224, e.g., the wafers 220-221 as shown in FIG. 135 to FIG. 145) may also be transferred from the second load-lock chamber 121 to the interiors of the second vacuum-transfer chamber 131, the second vacuum-transfer aligner 134, the heating chamber 137, and the first process-transfer chamber 135 and further back to the interior of the second load-lock chamber 121 through the second vacuum-transfer robot 132, the second vacuum-transfer robot 133, and the first process-transfer robot 136, which is thus not further described in detail herein. After the third wafer set (e.g., the last-transferred wafer 224 as shown in FIG. 145) is transferred to the interior of the second load-lock chamber 121, the valve V6 (as shown in FIG. 145) is closed.

To FIG. 145, the first wafer set (comprising the wafers 210-214) is transferred back to the first load-lock chamber 101, and the detailed steps thereof have been described above. Referring to the steps of the first wafer set (comprising the wafers 210-214) that is transferred from the second load-lock chamber 121 to the first vacuum-transfer chamber 111 and the third load-lock chamber 141, the second wafer set (comprising the wafers 215-219) may also be transferred from the second load-lock chamber 122 to the first vacuum-transfer chamber 111 and the third load-lock chamber 141 through the first vacuum-transfer robot 114, which is not additionally illustrated by figures and not further described in detail herein. In some embodiments, after the first wafer set (comprising the wafers 210-214) is transferred to the first load-lock chamber 101 and the second wafer set (comprising the wafers 215-219) is transferred to the third load-lock chamber 141, the first vacuum-transfer robots 112, 114 may work together to transfer the fourth wafer set disposed in the first load-lock chamber 102 (comprising wafers 225-229, where the wafers 226-229 are not additionally denoted) from the first load-lock chamber 102, through the first vacuum-transfer aligner 113, to the interior of the second load-lock chamber 122 by referring to the transfer steps of the second wafer set (comprising the wafers 215-219), which is not additionally illustrated by figures and not further described in detail herein.

Accordingly, in some embodiments, the number of times and/or sequence in which each wafer is transferred through the respective chambers of the multiple-chamber semiconductor serial constructing apparatus may be adjusted in accordance with different requirements. Therefore, the same multiple-chamber semiconductor serial constructing apparatus can not only support various processes, but also requires only the pressure of several chambers having relatively smaller volumes (e.g., the aforementioned first load-lock chamber and third load-lock chamber) to be controlled, thereby reducing the time and cost required for each process to wait until a pressure balance is reached as much as possible, and further reducing the time and cost required for the entire process.

Although the present disclosure is disclosed in the foregoing embodiments as above, it is not intended to limit the instant disclosure. Any person who is familiar with the relevant art can make some changes and modifications without departing from the spirit and scope of the present disclosure. Therefore, the scope of the present disclosure shall be subject to the definition of the scope of patent application attached to the specification.

What is claimed is:

1. A multiple-chamber semiconductor serial constructing apparatus, comprising:
a first vacuum-transfer module having a first side, a second side, a third side, and a fourth side, wherein the first side and the second side are opposite to each other, the third side is adjacent to the first side and the fourth side, and the fourth side is adjacent to the second side and the third side;
a first load-lock module comprising two first load-lock chambers, the two first load-lock chambers adjacent to each other and coupled with the first side of the first vacuum-transfer module;
a second load-lock module comprising two second load-lock chambers, the two second load-lock chambers adjacent to each other and coupled with the second side of the first vacuum-transfer module;
a first process-transfer module comprising:
a second vacuum-transfer chamber coupled with the two second load-lock chambers; and
a first process-transfer chamber diagonally coupled with the second vacuum-transfer chamber and configured to be coupled with an ion implantation assembly;
a third load-lock module comprising:
a third load-lock chamber coupled with the fourth side of the first vacuum-transfer module; and
a third vacuum-transfer chamber coupled with the third load-lock chamber;
a second process-transfer module coupled with the third vacuum-transfer chamber; and
a third process-transfer module coupled with the third vacuum-transfer chamber and the third side of the first vacuum-transfer module.

2. The multiple-chamber semiconductor serial constructing apparatus according to claim 1, wherein the first vacuum-transfer module comprises:
a first vacuum-transfer chamber coupled with the two first load-lock chambers, the two second load-lock chambers, the third load-lock chamber, and the third process-transfer module; and
a first vacuum-transfer robot disposed in the first vacuum-transfer chamber and configured to transfer a component to be transferred.

3. The multiple-chamber semiconductor serial constructing apparatus according to claim 1, wherein the third load-lock module further comprises a third vacuum-transfer robot, and the third vacuum-transfer robot is disposed in the third vacuum-transfer chamber and configured to transfer a component to be transferred.

4. The multiple-chamber semiconductor serial constructing apparatus according to claim 1, wherein the first process-transfer module further comprises two second vacuum-transfer robots, the two second vacuum-transfer robots are disposed in the second vacuum-transfer chamber and adjacent to each other, and the two second vacuum-transfer robots are configured to transfer a component to be transferred.

5. The multiple-chamber semiconductor serial constructing apparatus according to claim 4, wherein the first process-transfer module further comprises a second vacuum-transfer aligner, the second vacuum-transfer aligner is disposed in the second vacuum-transfer chamber, far away from a connection between centers of the two second vacuum-transfer robots, and far away from the first process-transfer chamber, and the second vacuum-transfer aligner is configured to hold the component to be transferred.

6. The multiple-chamber semiconductor serial constructing apparatus according to claim 1, wherein the first process-transfer module further comprises a first process-transfer robot, the first process-transfer robot is movably disposed in the first process-transfer chamber, and the first process-transfer robot is configured to transfer a component to be transferred.

7. The multiple-chamber semiconductor serial constructing apparatus according to claim 1, wherein the second vacuum-transfer chamber and the first process-transfer chamber are in communication with each other to maintain a pressure of the second vacuum-transfer chamber the same as a pressure of the first process-transfer chamber.

8. The multiple-chamber semiconductor serial constructing apparatus according to claim 7, wherein the pressure of the second vacuum-transfer chamber and the pressure of the first process-transfer chamber are maintained within a range from 1×10⁻⁷ torr to 2×10⁻⁵ torr.

9. The multiple-chamber semiconductor serial constructing apparatus according to claim 1, further comprising an equipment-front-end module, the equipment-front-end module comprising an equipment-front-end chamber coupled with the two first load-lock chambers.

10. The multiple-chamber semiconductor serial constructing apparatus according to claim 9, wherein the equipment-front-end module further comprises an equipment-front-end robot, and the equipment-front-end robot is disposed in the equipment-front-end chamber and configured to transfer a component to be transferred.

11. The multiple-chamber semiconductor serial constructing apparatus according to claim 9, wherein the equipment-front-end module further comprises an equipment-front-end aligner, and the equipment-front-end aligner is disposed in the equipment-front-end chamber configured to hold a component to be transferred.

12. The multiple-chamber semiconductor serial constructing apparatus according to claim 9, wherein the equipment-front-end module further comprises an equipment-front-end aligner, the equipment-front-end aligner is disposed outside the equipment-front-end chamber and configured to hold a component to be transferred.

13. The multiple-chamber semiconductor serial constructing apparatus according to claim 9, further comprising a plurality of front opening unified pods (FOUPs), each of the plurality of FOUPs coupled with the equipment-front-end chamber and configured to hold a component to be transferred.

14. The multiple-chamber semiconductor serial constructing apparatus according to claim 9, wherein a pressure of the equipment-front-end chamber is configured to be maintained at 760 torr, a pressure of the first vacuum-transfer module is configured to be maintained at less than or equal to 1×10⁻² torr, and pressures of the two first load-lock chambers are configured to be independently maintained within a range from 5×10⁻⁴ torr to 760 torr.

15. The multiple-chamber semiconductor serial constructing apparatus according to claim 1, wherein a pressure of the first vacuum-transfer module is configured to be maintained at less than or equal to 1×10⁻² torr, pressures of the two second load-lock chambers are configured to be independently maintained within a range from 1×10⁻⁷ torr to 1×10⁻² torr, and a pressure of the second vacuum-transfer chamber and a pressure of the first process-transfer chamber are configured to be independently maintained within a range from 1×10⁻⁷ torr to 2×10⁻⁵ torr.

16. The multiple-chamber semiconductor serial constructing apparatus according to claim 1, wherein a pressure of the third load-lock chamber and a pressure of the third vacuum-transfer chamber are configured to be independently maintained at less than or equal to 1×10⁻² torr, and a pressure of the second process-transfer module and a pressure of the third process-transfer module are configured to be independently maintained within a range from 5×10⁻⁴ torr to 5 torr.

17. The multiple-chamber semiconductor serial constructing apparatus according to claim 1, wherein the ion implantation assembly comprises:
an ion implantation chamber coupled with the first process-transfer chamber;
a mass-spectrometry-analysis unit coupled with the ion implantation chamber; and
an ion-supply unit coupled with the mass-spectrometry-analysis unit.

18. The multiple-chamber semiconductor serial constructing apparatus according to claim 17, wherein the first process-transfer module further comprises a first process-transfer robot, the first process-transfer robot corresponds to the ion implantation chamber and is movably disposed in the first process-transfer module to selectively transfer a component to be transferred along a plurality of axes.

19. A multiple-chamber semiconductor serial constructing apparatus, comprising:
a first vacuum-transfer module having a first side, a second side, a third side, and a fourth side, wherein the first side and the second side are opposite to each other, the third side is adjacent to the first side and the fourth side, and the fourth side is adjacent to the second side and the third side;
a first load-lock module comprising two first load-lock chambers, the two first load-lock chambers adjacent to each other and coupled with the first side of the first vacuum-transfer module;
a second load-lock module comprising two second load-lock chambers, the two second load-lock chambers adjacent to each other and coupled with the second side of the first vacuum-transfer module;
a first process-transfer module comprising:
a second vacuum-transfer chamber coupled with the two second load-lock chambers;
a first process-transfer chamber diagonally coupled with the second vacuum-transfer chamber and configured to be coupled with an ion implantation assembly; and
a heating chamber coupled with the second vacuum-transfer chamber;
a third load-lock module comprising:
a third load-lock chamber coupled with the fourth side of the first vacuum-transfer module; and
a third vacuum-transfer chamber coupled with the third load-lock chamber;
a second process-transfer module comprising two second process-transfer chambers, the two second process-transfer chambers respectively coupled with two opposite sides of the third vacuum-transfer chamber; and
a third process-transfer module comprising a fourth load-lock chamber, the fourth load-lock chamber coupled with the third vacuum-transfer chamber and the third side of the first vacuum-transfer module.

20. The multiple-chamber semiconductor serial constructing apparatus according to claim 19, wherein the first vacuum-transfer module comprises:
a first vacuum-transfer chamber coupled with the two first load-lock chambers, the two second load-lock chambers, the third load-lock chamber, and the fourth load-lock chamber;
a first vacuum-transfer aligner disposed in the first vacuum-transfer chamber; and
two first vacuum-transfer robots disposed in the second vacuum-transfer chamber and respectively adjacent to the first load-lock module and the second load-lock module;
wherein the first vacuum-transfer aligner is disposed between the two first vacuum-transfer robots.

21. The multiple-chamber semiconductor serial constructing apparatus according to claim 19, wherein the first process-transfer module further comprises two second vacuum-transfer robots, the two second vacuum-transfer robots are disposed in the second vacuum-transfer chamber and adjacent to each other, and the two second vacuum-transfer robots are configured to transfer a component to be transferred.

22. The multiple-chamber semiconductor serial constructing apparatus according to claim 21, wherein the first process-transfer module further comprises a second vacuum-transfer aligner, the second vacuum-transfer aligner is disposed in the second vacuum-transfer chamber, far away from a connection between centers of the two second vacuum-transfer robots, and far away from the first process-transfer chamber, and the second vacuum-transfer aligner is configured to hold the component to be transferred.

23. The multiple-chamber semiconductor serial constructing apparatus according to claim 19, wherein the first process-transfer module further comprises a first process-transfer robot, and the first process-transfer robot is movably disposed in the first process-transfer chamber, and configured to transfer a component to be transferred.

24. The multiple-chamber semiconductor serial constructing apparatus according to claim 19, wherein the second vacuum-transfer chamber and the first process-transfer chamber are in communication with each other to maintain a pressure of the second vacuum-transfer chamber the same as a pressure of the first process-transfer chamber.

25. The multiple-chamber semiconductor serial constructing apparatus according to claim 24, wherein the pressure of the second vacuum-transfer chamber and the pressure of the first process-transfer chamber are maintained within a range from 1×10⁻⁷ torr to 2×10⁻⁵ torr.

26. The multiple-chamber semiconductor serial constructing apparatus according to claim 19, further comprising an equipment-front-end module, the equipment-front-end module comprising an equipment-front-end chamber coupled with the two first load-lock chambers.

27. The multiple-chamber semiconductor serial constructing apparatus according to claim 26, wherein the equipment-front-end module further comprises an equipment-front-end robot, and the equipment-front-end robot is disposed in the equipment-front-end chamber and configured to transfer a component to be transferred.

28. The multiple-chamber semiconductor serial constructing apparatus according to claim 26, wherein the equipment-front-end module further comprises an equipment-front-end aligner, and the equipment-front-end aligner is disposed in the equipment-front-end chamber and configured to hold a component to be transferred.

29. The multiple-chamber semiconductor serial constructing apparatus according to claim 26, wherein the equipment-front-end module further comprises an equipment-front-end aligner, and the an equipment-front-end aligner is disposed outside the equipment-front-end chamber and configured to hold a component to be transferred.

30. The multiple-chamber semiconductor serial constructing apparatus according to claim 26, further comprising a plurality of front opening unified pods (FOUPs), each of the plurality of FOUPs coupled with the equipment-front-end chamber and configured to hold a component to be transferred.

31. The multiple-chamber semiconductor serial constructing apparatus according to claim 26, wherein a pressure of the equipment-front-end chamber is configured to be maintained at 760 torr, pressures of each of the two first load-lock chambers are configured to be independently maintained within a range from 5×10⁻⁴ torr to 760 torr, and a pressure of the first vacuum-transfer module is configured to be maintained at less than or equal to 1×10⁻² torr.

32. The multiple-chamber semiconductor serial constructing apparatus according to claim 19, wherein a pressure of the first vacuum-transfer module is configured to be maintained at less than or equal to 1×10⁻² torr, pressures of the two second load-lock chambers are configured to be independently maintained within a range from 1×10⁻⁷ torr to 1×10⁻² torr, and a pressure of the second vacuum-transfer chamber, a pressure of the first process-transfer chamber, and a pressure of the heating chamber are configured to be maintained within a range from 1×10⁻⁷ torr to 2×10⁻⁵ torr.

33. The multiple-chamber semiconductor serial constructing apparatus according to claim 19, wherein a pressure of the third load-lock chamber and a pressure of the third vacuum-transfer chamber are configured to be maintained at less than or equal to 1×10⁻² torr, and pressures of the two second process-transfer chambers and a pressure of the fourth load-lock chamber are configured to be independently maintained within a range from 5×10⁻⁴ torr to 5 torr.

34. The multiple-chamber semiconductor serial constructing apparatus according to claim 19, wherein the ion implantation assembly comprises:
an ion implantation chamber coupled with the first process-transfer chamber;
a mass-spectrometry-analysis unit coupled with the ion implantation chamber; and
an ion-supply unit coupled with the mass-spectrometry-analysis unit.

35. The multiple-chamber semiconductor serial constructing apparatus according to claim 34, wherein the first process-transfer module further comprises a first process-transfer robot, the first process-transfer robot corresponds to the ion implantation chamber and is movably disposed in the first process-transfer module to selectively transfer a component to be transferred along a plurality of axes.
